(19) United States
(12) Patent Application Publication
(10) Pub. No.: US 2008/0182202 A1
(43) Pub. Date: Jul. 31, 2008

(54) Planographic printing plate material and resin used therein

(75) Inventor: Hidetoshi Ezure, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: KONICA MINOLTA MEDICAL & GRAPHIC, INC., Tokyo (JP)

(21) Appl. No.: 12/009,202

(22) Filed: Jan. 17, 2008

(30) Foreign Application Priority Data
Jan. 29, 2007 (JP) JP2007-017625

(51) Int. Cl. G03F 7/004

(52) U.S. Cl. 430/281.1

(57) ABSTRACT

Disclosed is a planographic printing plate material comprising a support and provided thereon, a light sensitive layer containing a resin comprising a residue of a bicyclic heterocyclic compound with a fused bicyclic ring, wherein the fused bicyclic ring contains two or more of —C(═O)— or two or more of —NH— in one ring thereof.

This application is based on Japanese Patent Application No. 2007-017625, filed on Jan. 29, 2007 in Japanese Patent Office, the entire content of which is hereby incorporated by reference.

### FIELD OF THE INVENTION

The present invention relates to a light sensitive planographic printing plate material for a computer-to-plate (hereinafter also referred to as CTP) system comprising a support and provided thereon, a light sensitive layer and to a resin used in the light sensitive layer, and particularly to a light sensitive planographic printing plate material (hereinafter also referred to as a planographic printing plate material) capable of being exposed employing a near infrared laser which provides excellent sensitivity, development latitude, scratch resistance and chemical resistance.

### BACKGROUND OF THE INVENTION

In recent years, printing image data are digitized and a so-called CTP system is widely used which comprises exposing a planographic printing plate material employing laser signals to which the digitized data are converted. Presently, laser technique is markedly developed, and a compact solid or semiconductor laser with high output power, which has an emission wavelength of from near-infrared to infrared regions, is available from the market. Such a laser is extremely useful as a light source for manufacturing a printing plate employing digitized data from a computer.

Recently, high speed exposure, i.e., shortening of exposure time and transporting time is required as delivery time is shortened. In printing, improvement of printing productivity is sought in which two or four planographic printing plate materials of large size are simultaneously exposed employing an exposure apparatus suitable for exposing the large size planographic printing plate material. However, the exposure apparatus suitable for the large size planographic printing plate material sometimes produces scratches on the surface of the planographic printing plate material during transporting. Improvement of the exposure system is sought, but is not still satisfactory. Accordingly, improvement of planographic printing plate material side is desired.

As an infrared laser sensitive planographic printing plate material, there is proposed a positive working planographic printing plate material comprising a recording layer containing an alkali soluble resin (A) having a phenolic hydroxyl group and such as a cresol novolak resin and an infrared absorbing dye (B) (see WO 97/39384). In this positive working planographic printing plate material, association structure of the cresol novolak resin is changed at exposed portions by heat generated from the infrared absorbing dye, whereby solubility difference (solubility speed difference) between the exposed and unexposed portions is produced. Employing the solubility difference, development of the exposed planographic printing plate material is carried out to form an image. However, the proposed planographic printing plate material is small in the solubility speed difference, and therefore has problems in that development latitude is narrow, and loss of development restraining property of a light sensitive layer at non-image portions is insufficient, resulting in poor sensitivity.

As a method for overcoming the narrow development latitude or poor sensitivity, there is proposed a method which employs a cresol novolak resin improving its intermolecular association, i.e., hydrogen bonding properties. For example, there is proposed a planographic printing plate material comprising a novolak resin with an amido group introduced by esterification reaction or with a quinonediazide group incorporated by esterification of sulfonic acid, whereby sensitivity and development latitude are improved (see Japanese Patent O.P.I. Publication Nos. 2002-210404 and 11-288089). However, incorporation of such a group somewhat improves sensitivity and development latitude, but the improvement is still insufficient. Further, when the exposure apparatus for a large size planographic printing plate material is used as described above, scratch resistance is insufficient.

Further, a novolak resin is proposed which has a substituent with a lone pair capable of forming a hydrogen bond (see Japanese Patent O.P.I. Publication No. 2004-526986). The hydrogen bond through which the substituent is associated with two other substituents causes intermolecular interaction, improving development latitude and sensitivity. However, a planographic printing plate material employing such a novolak resin does not provide satisfactory results when developed with a developer with a pH of not more than 13.0 or a fatigue developer. Further, when a large size of the planographic printing plate material is used in an exposure apparatus, it has problem in scratch resistance as described above.

### SUMMARY OF THE INVENTION

The present invention has been made in view of the above. An object of the invention is to provide a planographic printing plate material which provides excellent sensitivity and development latitude even when developed with a developer with a low pH or a fatigue developer with a low activity and provides excellent scratch resistance regarding high productivity. Another object of the invention is to provide a resin used in the planographic printing plate material.

### DETAILED DESCRIPTION OF THE INVENTION

The above object of the invention can be attained by any one of the followings.

1. A resin for a planographic printing plate material, the resin comprising a residue of a bicyclic heterocyclic compound with a fused bicyclic ring, wherein the fused bicyclic ring contains two or more of —C(═O)— or two or more of —NH— in one ring thereof.

2. The resin of item 1 above, wherein the fused bicyclic ring contains two or more of —C(═O)— and two or more of —NH— in one ring thereof.

3. The resin of item 1 or 2 above, wherein the fused bicyclic ring includes a six-membered ring containing in the ring two or more of —C(═O)—.

4. The resin of item 1 or 2 above, wherein the fused bicyclic ring includes a five-membered ring containing in the ring two or more of —NH—.

5. The resin of any one of items 1 through 3 above, wherein the bicyclic heterocyclic compound is theophylline or uric acid.

6. The resin of any one of items 1 through 5 above, wherein the fused bicyclic ring is capable of forming a hydrogen bond with two other fused bicyclic rings, simultaneously.

7. The resin of any one of items 1 through 6 above, wherein the resin is capable of forming a super molecule through hydrogen bonding.

8. The resin of any one of items 1 through 7 above, wherein the resin is one selected from a phenol resin, an acryl resin, and an acetal resin.

9. The resin of any one of items 1 through 8 above, wherein the resin is alkali soluble.

10. A planographic printing plate material comprising a support and provided thereon, a light sensitive layer containing the resin of any one of items 1 through 9.

11. The planographic printing plate material of item 1 above, wherein the light sensitive layer contains an acid decomposable compound represented by formula (ADC),

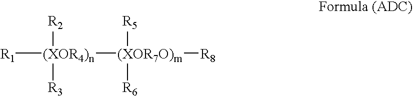

wherein n is an integer of 1 or more; m is an integer of 0 or more; X represents a carbon atom or a silicon atom; R₄ represents an ethyleneoxy group or a propyleneoxy group; R₂ and R₅ independently represent a hydrogen atom, an alkyl group or an aryl group; R₃ and R₆ independently represent an alkyl group or an aryl group, provided that R₂ and R₃ may combine with each other to form a ring or R₅ and R₆may combine with each other to form a ring; R₇ represents an alkylene group; R₁ represents a hydrogen atom, an alkyl group, an aryl group, an alkoxy group, an aryloxy group or a halogen atom; and R₈ represents a hydrogen atom, —XR₂R₃R₁ or —XR₅R₆R₁.

12. The planographic printing plate material of item 11 above, wherein the acid decomposable compound is an acetal.

13. The planographic printing plate material of item 10 above, wherein the light sensitive layer is comprised of a lower light sensitive layer and an upper light sensitive layer provided on the lower light sensitive layer, and wherein at least one of the lower and upper light sensitive layers contains the resin.

14. The planographic printing plate material of item 13 above, wherein the upper light sensitive layer contains an acryl resin having a fluoroalkyl group, and one of a compound represented by formula (APA) and a compound represented by formula (SAPA),

R¹—C(X)₂—(C═O)—R² Formula (APA)

wherein R¹ represents a hydrogen atom, a bromine atom, a chlorine atom, an alkyl group, an aryl group, an acyl group, an alkylsulfonyl group, an arylsulfonyl group, an iminosulfonyl group or a cyano group; R² represents a hydrogen atom or a monovalent organic substituent, provided that R¹ and R² may combine with each other to form a ring; and X represents a bromine atom or a chlorine atom.

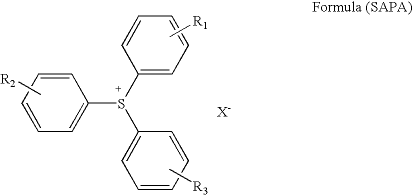

wherein R₁ through R₃ independently represent a hydrogen atom or a substituent, provided that R₁ through R₃ are not simultaneously hydrogens; and X⁻ represents an anion.

15. The planographic printing plate material of item 13 or 14 above, wherein the lower light sensitive layer contains an acryl resin having a sulfonamide group or a hydroxylphenyl group.

16. The planographic printing plate material of any one of items 13 through 15 above, wherein the lower light sensitive layer contains a compound represented by formula (ADC) or a compound represented by formula (APA).

17. The planographic printing plate material of any one of items 10 through 16 above, which is positive working, wherein the light sensitive layer contains an infrared absorbing dye.

The resin for a printing plate material in the invention is characterized in that it comprises a residue of a bicyclic heterocyclic compound, wherein the bicyclic heterocyclic compound has a fused bicyclic ring containing two or more of —C(═O)— or two or more of —NH— in one ring thereof. The planographic printing plate material of the invention comprises a support and provided thereon, a light sensitive layer containing a resin comprising a residue of a bicyclic heterocyclic compound, wherein the fused bicyclic heterocyclic compound has a fused bicyclic ring containing two or more of —C(═O)— or two or more of —NH— in one ring thereof. The resin for a printing plate material in the invention enhances interaction through a hydrogen bond between the resins or between the resin and coexisting additives, increases mechanical strength of image portions and reduces solubility in developer or chemicals used of image portions, resulting in improvement of scratch resistance, chemical resistance and printing durability.

The present invention will be detailed below.

### (Resin for Printing Plate Material)

The resin for a printing plate material (hereinafter also referred to as the resin in the invention) is characterized in that it comprises a residue (hereinafter also referred to as the compound residue in the invention) of a bicyclic heterocyclic compound (hereinafter also referred to as the bicyclic heterocyclic compound in the invention), wherein the bicyclic heterocyclic compound has a fused bicyclic ring containing two or more of —C(═O)— or two or more of —NH— in one ring thereof. It is preferred that the ring containing the —C(═O)— in the fused bicyclic ring is a six-membered ring or the ring containing the —NH— in the fused bicyclic ring is a five-membered ring.

Next, detailed explanation will be made.

The fused bicyclic ring may be of any ring structure, as long as it contains two or more of —C(═O)— and/or two or more of —NH— in one ring thereof. It is preferred in easiness of synthesis that the fused bicyclic ring is comprised preferably of two 6-membered rings, two 5-membered rings, or one 6-membered ring and one 5-membered ring.

It is preferred that the fused bicyclic ring contains two or more of —C(═O)— and one or more of —NH— in one ring thereof or contains one or more of —C(═O)— and two or more of —NH— in one ring thereof. It is more preferred that the fused bicyclic ring in the invention contains —NH— and two or more of —C(═O)— in one ring, and two or more of —C(═O)— or —NH— in the other ring. Such a fused bicyclic ring has three or more in total of hydrogen bond-forming groups —C(═O)— and —NH— in one ring or has hydrogen bond-forming groups —C(═O)— and —NH— in each of the two rings, which improves hydrogen bonding property between two fused bicyclic rings. In such a fused bicyclic ring, one fused bicyclic ring forms a hydrogen bond with each of other two fused bicyclic rings, exhibiting strong interaction between them. This strong interaction (hydrogen bonding) is released by exposure (heat), which can provide a planographic printing plate material exhibiting high sensitivity and development latitude even when developed with a fatigue developer with lowered activity. The above advantageous effects are markedly exhibited in a planographic printing plate material comprising two light sensitive layers with different functions, each of which contains one selected from the resin in the invention, an acid decomposable compound, an acid generating agent or a binder, which provides a planographic printing plate material with high quality.

Further, the above hydrogen bonding can form a super molecule.

Herein, “the super molecule” refers to an aggregated molecule in which plural molecules are combined through a bond other than a covalent bond, for example, a coordination bond or a hydrogen bond. An example thereof will be shown below.

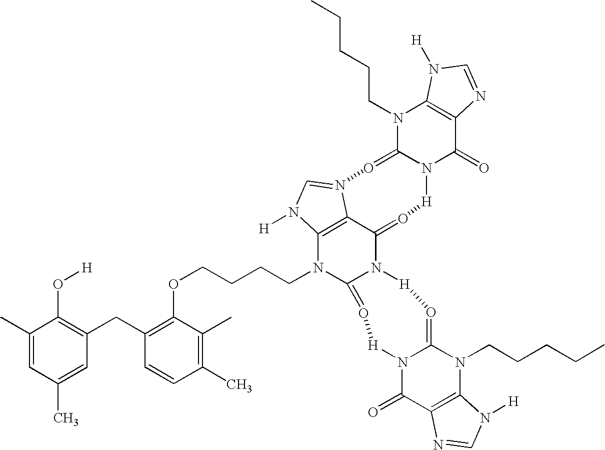

Examples of the bicyclic heterocyclic compound in the invention include xanthine, caffeine, lumazine, isatin, theobromine, theophylline, thioxanthine, and their derivatives. Among these, theophylline, uric acid or their derivatives are preferred in view of the number of hydrogen bond-forming groups, and uric acid or its derivative is especially preferred.

The bicyclic heterocyclic compound in the invention, although not specifically limited to the structure thereof, will be explained below, employing uric acid or its derivative.

Uric acid or its derivative is represented by the following formula:

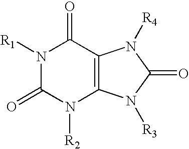

wherein R₁ through R₄ independently represent a hydrogen atom, a hydroxyl group, a carboxyl group, an amino group, a cyano group, —R₅-A, —R₅-A-R or a polymerizable group. A is a linkage group which can be omitted. The linkage group A represents a polar group such as a carboxylic acid ester group, a urea group, a urethane group, an amido group, an imido group, a sulfonamide group, a sulfonyl group, or a sulfonic acid ester group. R₅ represents an alkyl group, an allyl group, an alkenyl group, an aryl group or an alkylene oxide group having a carbon atom number of from 1 to 10. R is a reactive group which represents an isocyanate group, an epoxy group, an active methylene group, an amino group, a thiol group, a hydroxyl group, an oxetane group, a carbodiimido group, an oxazine group and a metal alkoxide group.

The polymerizable group is represented by formula

—(B)n-C

wherein C is a double bond-containing group. Examples thereof include —CH═CH₂, —C(CH₃)═CH₂, —OCH═CH₂, —OC(CH₃)═CH₂, —O—C(═O)(CH₃)═CH₂ and —O—C(═O)C(CH₃)═CH₂.

B is a linkage group which can be omitted. The linkage group B is represented by R₆-D. R₆ represents an alkyl group, an allyl group, an alkenyl group, an aryl group or an alkylene oxide group having a carbon atom number of from 1 to 5. R₆ may be branched and may have a hydroxyl group or a carboxyl group in the branched portion. D represents a polar group such as such as a carboxylic acid ester group, an amido group, a cyano group, a sulfonamide group, an imido group, a sulfonyl group or a sulfonic acid ester group.

The resin in the invention may have the compound residue in the invention in the main or side chain. The resin in the invention preferably has the compound residue in the invention in the side chain, in that interaction between two of the resin or between the resin and additives is easy to occur.

As a resin constituting the resin in the invention, there are a phenol resin, a vinyl resin, a urethane resin, a polyester resin, and an amide resin. Among these, a phenol resin and a vinyl resin are preferred. The phenol resin is preferably a novolak resin, and the vinyl resin is preferably an acryl resin or an acetal resin.

The resin in the invention can be prepared by polymerization of a monomer having the compound residue in the invention and a polymerizable group such as a double bond, i.e., by homopolymerization of the monomer or by copolymerization of the monomer with another monomer. Further, the resin in the invention can be also prepared by modification of a resin, for example, by incorporation of the compound residue in the invention into a resin. A method of the polymerization or modification described above is not specifically limited, and a well-known method can be used. The method will be explained below, employing uric acid.

A novolak resin having a uric acid residue can be prepared by linking a novolak resin with a uric acid derivative having a functional group through a compound having two or more of a functional group capable of binding the novolak resin with the uric acid derivative. Examples of the uric acid derivative having a functional group include the above uric acid derivative and a condensation product of 4-hydroxybenzaldehyde with uric acid. Examples of the compound having two or more of the functional group include a diisocyanate compound, a polyisocyanate compound, a dibasic acid chloride and a diglycidyl compound.

A vinyl resin having a uric acid residue can be prepared, for example, by reacting a vinyl monomer (a) having an aldehyde group with uric acid (b) or its derivative to obtain a vinyl monomer (c) having a uric acid residue as shown in the following reaction formula (I) and then copolymerizing the vinyl monomer (c) with another vinyl monomer (Copolymerization method A) or by reacting a vinyl monomer (a) having an aldehyde group with another monomer to obtain a vinyl resin having an aldehyde group and then reacting the vinyl resin with the uric acid (b) or its derivative (Modification method B).

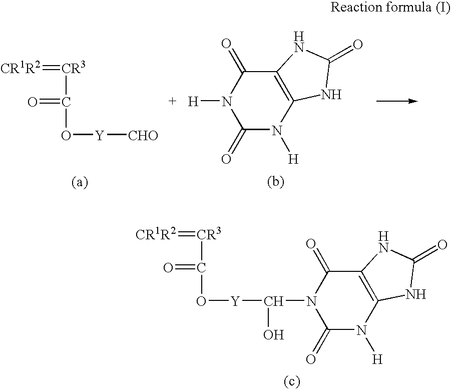

In the formula (I) above, R¹ and R² independently represent a hydrogen atom, a halogen atom, an alkyl group, an aryl group, a carboxyl group or a carboxylate group; R³ represents a hydrogen atom, a halogen atom, an alkyl group or an aryl group; and Y represents a divalent linkage group such as a substituted or unsubstituted alkylene group or a substituted or unsubstituted phenylene group.

The vinyl monomer (a) has in the molecule an aldehyde group and a polymerizable unsaturated bond. Examples thereof include a condensation product of hydroxybenzaldehydes with (meth)acrylic acid chloride, an adduct of hydroxybenzaldehydes with (meth)acryloyloxyethylisocyanate, and an adduct of glycidyl(meth)acrylate with carboxybenzaldehydes. Examples of the hydroxybenzaldehydes include 2-hydroxybenzaldehyde, 3-hydroxybenzaldehyde, 4-hydroxybenzaldehyde, 3-methoxy-2-hydroxybenzaldehyde, 4-methoxy-3-hydroxy-benzaldehyde, 3-methoxy-4-hydroxybenzaldehyde, 5-chloro-2-hydroxybenzaldehyde, and 3,5-di-tert-butyl-4-hydroxybenzaldehyde. In the invention, 4-hydroxybenzaldehyde is suitably used.

The vinyl resin having a uric acid residue can be also obtained employing acrolein or methacrolein instead of the vinyl monomer (a) in reaction formula (I) above. As the vinyl resin having a uric acid residue, there is mentioned a vinyl resin having a repeating unit represented by formula (VP),

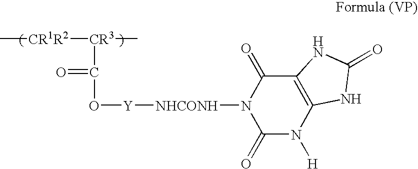

wherein R¹ and R² independently represent a hydrogen atom, a halogen atom, an alkyl group, an aryl group, a carboxyl group or a carboxylate group; R³ represents a hydrogen atom, a halogen atom, an alkyl group or an aryl group; and Y represents a divalent linkage group such as a substituted or unsubstituted alkylene group or a substituted or unsubstituted phenylene group.

The vinyl resin having a repeated unit represented by formula (VP) can be prepared for example by reacting a vinyl monomer (d) having an isocyanate group with 5-aminouric acid (e) to obtain a vinyl monomer (f) having a uric acid residue as shown in the following reaction formula (II) and then copolymerizing the vinyl monomer (f) with another vinyl monomer (Copolymerization method A) or by reacting a vinyl resin having an isocyanate group with 5-aminouric acid (e) (Modification method B).

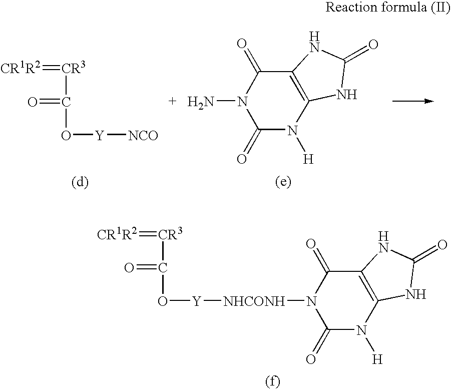

In the reaction formula (II) above, R¹, R², R³ and Y represent the same as those denoted above in R¹, R², R³ and Y of reaction formula (I).

The content of the compound residue in the invention in the resin in the invention is preferably from 3 to 80% by weight, and more preferably from 5 to 50% by weight. This content range is extremely effective in the invention. The resin in the invention may have a functional group other than the compound residue in the invention, as long as the functional group does not jeopardize the effects of the invention. The resin in the invention, which is used in a planographic printing plate material to be developed with an alkali solution, is preferably alkali-soluble, and therefore, it is preferred that the resin in the invention further has an acidic group such as a carboxyl group, a phenolic hydroxyl group, a sulfonic acid group, a phosphoric acid group, a sulfonamide group or an active imide group; or a substituent comprising the acidic group.

In the invention, the content of the resin in the invention in the light sensitive layer of the planographic printing plate material of the invention is preferably from 10 to 906 by weight, and more preferably from 30 to 80% by weight. The content range of the resin in the invention of from 10 to 90% by weight provides advantageous effects of the invention that improve sensitivity and development latitude without lowering scratch resistance.

When the light sensitive layer is comprised of a lower light sensitive layer and an upper light sensitive layer provided on the lower light sensitive layer, the resin in the invention may be contained in any of the upper and lower light sensitive layers. When the resin in the invention is used in the upper light sensitive layer, it is preferably a phenol resin or novolak resin having the fused bicyclic ring in the invention. A phenol resin or novolak resin is superior in mechanical strength, and advantageous in printing durability or scratch resistance. Further, when the resin in the invention is used in the upper light sensitive layer, the lower layer preferably contains an acryl resin having a sulfonamide group or a hydroxyphenyl group, which provides high solubility. When the resin of the invention is used in the lower light sensitive layer, it is preferably a vinyl resin, particularly an acryl resin or acetal resin having the fused bicyclic heterocyclic ring in the invention. A vinyl resin such as an acryl resin or acetal resin is superior in solubility to an alkali developer or in resistance to chemicals such as washing oil, and is advantageous in sensitivity, developing latitude or chemical resistance.

When there are two light sensitive layers, upper and lower light sensitive layers in the planographic printing plate material of the invention, the upper or lower light sensitive layer contains the resin in the invention in an amount of preferably not less than 40% by weight, and more preferably not less than 40% by weight, based on the weight of the layer containing the resin, in giving the above advantages in each layer.

The molecular weight of the resin in the invention can be optionally adjusted. The resin in the invention, when it is a phenol novolak resin, has a weight average molecular weight of preferably not less than 1,000, or a number average molecular weight of preferably not less than 200.

The novolak resin is preferred which has a weight average molecular weight of preferably not less than 1,500 to 300,000, a number average molecular weight of preferably 300 to 250,000, and a dispersion degree (a ratio weight average molecular weight/number average molecular weight) of from 1.1 to 10. The novolak resin is especially preferred which has a weight average molecular weight of preferably not less than 2,000 to 10,000, a number average molecular weight of preferably 500 to 10,000, and a dispersion degree (a ratio weight average molecular weight/number average molecular weight) of from 1.1 to 5. The above-described range makes it possible to adjust strength or alkali solubility of the novolak resin layer, chemical resistance and interaction between the resin and a light-to-heat conversion material, and is easy to obtain advantageous effects of the invention. The vinyl resin, particularly acryl resin or an acetal resin, has a weight average molecular weight of preferably not less than 2,000, more preferably 5,000 to 100,000, and still more preferably 10,000 to 50,000. The above-described range makes it possible to adjust strength or alkali solubility of vinyl resin layer, and chemical resistance, and is easy to obtain advantageous effects of the invention.

The resin in the invention may be used singly or as an admixture of two or more kinds thereof.

Besides the resin in the invention, an alkali soluble resin as described below can be used in combination.

### (Alkali Soluble Resin)

The alkali soluble resin in the invention refers to a resin which dissolves in an amount of not less than 0.1 g/liter in a 25° C. aqueous potassium hydroxide solution with a pH of 13.

As the alkali soluble resin, a phenolic hydroxyl group-containing resin, an acryl resin or an acetal resin is preferably used, in view of ink receptivity and alkali solubility.

The alkali soluble resin may be used singly or as an admixture of two or more kinds thereof.

When there are two light sensitive layers, upper and lower light sensitive layers, the alkali soluble resin used in the lower layer is preferably an acryl resin or an acetal resin in view of alkali solubility, and the alkali soluble resin used in the upper layer is preferably a phenolic hydroxyl group-containing resin, and more preferably a novolak resin, in view of ink receptivity.

### (Phenolic Hydroxyl Group-Containing Resin)

The phenolic hydroxyl group-containing resin can be prepared by condensation of various phenols with aldehydes.

Examples of the phenols include phenol, m-cresol, p-cresol, a mixed cresol (mixture of m- and p-cresols), a mixture of phenol and cresol (m-cresol, p-cresol or a mixture of m- and p-cresols), pyrogallol, acrylamide having a phenolic hydroxyl group, methacrylamide having a phenolic hydroxyl group, acrylate having a phenolic hydroxyl group, methacrylate having a phenolic hydroxyl group, and hydroxyl styrene.

Other examples of the phenols include substituted phenols such as iso-propylphenol, t-butylphenol, t-amylphenol, hexylphenol, cyclohexylphenol, 3-methyl-4-chloro-6-t-butylphenol, iso-propylcresol, t-butylcresol, and t-amylcresol. Preferred phenols are t-butylphenol and t-butylcresol. Examples of the aldehydes include aliphatic aldehydes such as formaldehyde, acetaldehyde, acrolein and crotonaldehyde; and aromatic aldehydes. Formaldehyde and acetaldehyde are preferred, and formaldehyde is especially preferred.

The preferred examples of the novolak resins include phenol-formaldehyde resin, m-cresol-formaldehyde resin, p-cresol-formaldehyde resin, m-/p-cresol (mixed cresol)-formaldehyde resin, and phenol-cresol (m-cresol, p-cresol, o-cresol, m-/p-cresol (mixed), m-/o-cresol (mixed) or o-/p-cresol (mixed))-formaldehyde resin. Especially preferred is m-/p-cresol (mixed cresol)-formaldehyde resin.

It is preferred that the novolak resin has a weight average molecular weight of not less than 1,000, and a number average molecular weight of not less than 200. It is more preferred that the novolak resin has a weight average molecular weight of from 1,500 to 300,000, a number average molecular weight of from 300 to 250,000, and a polydispersity (weight average molecular weight/number average molecular weight) of from 1.1 to 10. It is still more preferred that the novolak resin has a weight average molecular weight of from 2,000 to 10,000, a number average molecular weight of from 500 to 10,000, and a polydispersity (weight average molecular weight/number average molecular weight) of from 1.1 to 5. In the above molecular weight range, layer strength, alkali solubility, anti-chemical properties and interaction between the novolak resin and a light-to-heat conversion material of a layer containing the novolak resin can be suitably adjusted. The weight average molecular weight of novolak resin contained in the upper or lower layer can be also adjusted. Since the chemical resistance and layer strength is required to be high in the upper layer, the weight average molecular weight of novolak resin contained in the upper layer is preferably relatively high, and preferably from 2,000 to 10,000.

The molecular weight of the novolak resin is determined in terms of polystyrene employing monodisperse standard polystyrene according to GPC (gel permeation chromatography).

The novolak resin in the invention can be synthesized according to a method disclosed in for example, “Shi Jikken Kagaku Koza [19] Polymer Chemistry [1]”, published by Maruzen Shuppan, p. 300 (1993). That is, phenol or substituted phenols (for example, xylenol or cresol) is dissolved in a solvent, mixed with an aqueous formaldehyde solution, and reacted in the presence of an acid, in which dehydration condensation reaction occurs at the ortho or para position of the phenol or substituted phenols to form a novolak resin. The resulting novolak resin is dissolved in an organic solvent, then mixed with a non-polar solvent and allowed to stand for several hours. The novolak resin mixture forms two phases separated, and the lower phase is concentrated, whereby a novolak resin with a narrow molecular weight distribution is obtained.

The organic solvent used is acetone, methyl alcohol or ethyl alcohol. The non-polar solvent used is hexane or petroleum ether. Further, the synthetic method is not limited to the above. As is disclosed in for example, Japanese Patent O.P.I. Publication No. 2001-506294, the novolak resin is dissolved in a water-soluble organic polar solvent, and then mixed with water to obtain precipitates, whereby a fraction of the novolak resin can be obtained. Further, As a method to obtain a novolak resin with a narrow molecular weight distribution, there is a method in which a novolak resin obtained by dehydration condensation is dissolved in an organic solvent and the resulting solution is subjected to silica gel chromatography for molecular weight fractionation.

Dehydration condensation of phenol with formaldehyde or dehydration condensation of substituted phenols with formaldehyde at o- or p-position of the substituted phenols is carried out as follows:

Phenol or substituted phenols are dissolved in a solvent to obtain a solution having a phenol or substituted phenol concentration of from 60 to 90% by weight, and preferably from 60 to 90% by weight. Then, formaldehyde is added to the resulting solution so that the concentration ratio (by mole) of the formaldehyde to the phenol or substituted phenol is from 0.2 to 2.0, preferably from 0.4 to 1.4, and more preferably from 0.6 to 1.2, and further acid catalyst is added at a reaction temperature of from 10 to 150° C. so that the concentration ratio (by mole) of the acid catalyst to the phenol or substituted phenol is from 0.01 to 0.1, and preferably from 0.02 to 0.05. The resulting mixture is stirred for several hours while maintaining that temperature range. The reaction temperature is preferably from 70 to 150° C., and more preferably from 90 to 140° C.

The novolak resin can be used singly or as a mixture of two or more kinds thereof. A combination of two or more kinds of novolak resin makes it possible to effectively provide various properties such as layer strength, alkali solubility, anti-chemical properties and interaction between the novolak resin and a light-to-heat conversion material. When two or more kinds of novolak resin are used in the image recording layer, the weight average molecular weight or m/p ratio difference between them is preferably great. For example, the weight average molecular weight difference between the two or more kinds of novolak resins is preferably not less than 1000, and more preferably not less than 2000, and the m/p ratio difference between the two or more kinds of novolak resins is preferably not less than 0.2, and more preferably not less than 0.3.

The content of the phenolic hydroxyl group-containing resin in the upper light sensitive layer is preferably from 30 to 99% by weight, more preferably from 45 to 95% by weight, and still more preferably from 60 to 90% by weight, in view of chemical resistance and printing durability.

### (Acryl Resin)

The acryl resin used in the invention is preferably a copolymer containing a constituent unit derived from other monomers in addition to a constituent unit derived from (meth)acrylates. Examples of the other monomers include (meth)acrylamides, vinyl esters, styrenes, (meth)acrylic acid, acrylonitrile, maleic anhydride, maleic imide, and lactones.

Examples of the acrylates include methyl acrylate, ethyl acrylate, (n- or i-)propyl acrylate, (n-, i- or sec- or tert-)butyl acrylate, amyl acrylate, 2-ethylhexyl acrylate, dodecyl acrylate, 2-chloroethyl acrylate, 2-hydroxyethyl acrylate, 2-hydroxypropyl acrylate, 5-hydroxypentyl acrylate, cyclohexyl acrylate, allyl acrylate, trimethylpropane monoacrylate, pentaerythritol monoacrylate, glycidyl acrylate, benzyl acrylate, chlorobenzyl acrylate, 2-(p-hydroxypheny)ethyl acrylate, furfuryl acrylate, tetrahydrofurfuryl acrylate, phenyl acrylate, chlorophenyl acrylate, and sulfamoylphenyl acrylate.

Examples of the methacrylates include methyl methacrylate, ethyl methacrylate, (n- or i-)propyl methacrylate, (n-, i- or sec- or tert-)butyl methacrylate, amyl methacrylate, 2-ethylhexyl methacrylate, dodecyl methacrylate, 2-chloroethyl methacrylate, 2-hydroxyethyl methacrylate, 2-hydroxypropyl methacrylate, 5-hydroxypentyl methacrylate, cyclohexyl methacrylate, allyl methacrylate, trimethylpropane monomethacrylate, pentaerythritol monomethacrylate, glycidyl methacrylate, benzyl methacrylate, chlorobenzyl methacrylate, 2-(p-hydroxypheny)ethyl methacrylate, furfuryl methacrylate, tetrahydrofurfuryl methacrylate, phenyl methacrylate, chlorophenyl methacrylate, and sulfamoylphenyl methacrylate.

Examples of acrylamides include acrylamide, N-methyl acrylamide, N-ethyl acrylamide, N-propyl acrylamide, N-butyl acrylamide, N-benzyl acrylamide, N-hydroxyethyl acrylamide, N-phenyl acrylamide, N-tolyl acrylamide, N-(p-hydroxyphenyl)acrylamide, N-(sulfamoylphenyl) acrylamide, N-(phenylsulfonyl)acrylamide, N-(tolylsulfonyl)acrylamide, N,N-dimethyl acrylamide, N-methyl-N-phenyl acrylamide, N-hydroxyethyl-N-methyl acrylamide, and N-(p-toluenrsulfonyl)acrylamide.

Examples of methacrylamides include methacrylamide, N-methyl methacrylamide, N-ethyl methacrylamide, N-propyl methacrylamide, N-butyl methacrylamide, N-benzyl methacrylamide, N-hydroxyethyl methacrylamide, N-phenyl methacrylamide, N-tolyl methacrylamide, N-(p-hydroxyphenyl)methacrylamide, N-(sulfamoylphenyl)methacrylamide, N-(phenylsulfonyl)methacrylamide, N-(tolylsulfonyl)methacrylamide, N,N-dimethyl methacrylamide, N-methyl-N-phenyl methacrylamide, N-hydroxyethyl-N-methyl methacrylamide, and N-(p-toluenrsulfonyl)methacrylamide.

Examples of lactones include pantoyl lactone(meth)acrylate, α-(meth)acryloyl-γ-butyrolactone, and β-(meth)acryloyl-γ-butyrolactone.

Examples of maleic imides include meleimide, N-acryloyl acrylamide, N-acetyl methacrylamide, N-propyl methacrylamide, and N-(p-chlorobenzoyl)methacrylamide.

Examples of vinyl ester include vinyl acetate, vinyl butyrate, and vinyl benzoate.

Examples of styrenes include styrene, methylstyrene, dimethylstyrene, trimethylstyrene, ethylstyrene, propylstyrene, cyclohexylstyrene, chloromethylstyrene, trifluoromethylstyrene, ethoxystyrene, acetoxystyrene, methoxystyrene, dimethoxystyrene, chlorostyrene, dichlorostyrene, bromostyrene, iodostyrene, fluorostyrene, and carboxystyrene.

Examples of acrylonitriles include acrylonitrile and methacrylonitrile.

Examples of a vinyl monomer having a ureido group include an acrylate derivative such as 1-(N′-(4-hydroxyphenyl)ureido)methyl acrylate, 1-(N′-(3-hydroxyphenyl)ureido)methyl acrylate, 1-(N′-(2-hydroxyphenyl)ureido)methyl acrylate, 1-(N′-(3-hydroxy-4-methylphenyl)ureido)methyl acrylate, 1-(N′-(2-hydroxy-5-methylphenyl)ureido)methyl acrylate, 1-(N′-(5-hydroxynaphthyl)ureido)methyl acrylate, 1-(N′-(2-hydroxy-5-phenylphenyl)ureido)methyl acrylate, 2-(N′-(4-hydroxyphenyl)ureido)ethyl acrylate, 2-(N′-(3-hydroxyphenyl)ureido)ethyl acrylate, 2-(N′-(2-hydroxyphenyl)ureido)ethyl acrylate, 2-(N′-(3-hydroxy-4-methylphenyl)ureido)ethyl acrylate, 2-(N′-(2-hydroxy-5-methylphenyl)ureido)ethyl acrylate, 2-(N′-(5-hydroxy-naphthylphenyl)ureido)ethyl acrylate, 2-(N′-(2-hydroxy-5-phenylphenyl)ureido)ethyl acrylate, 4-(N′-(4-hydroxyphenyl)ureido)butyl acrylate, 4-(N′-(3-hydroxyphenyl)ureido)butyl acrylate, 4-(N′-(2-hydroxyphenyl)ureido)butyl acrylate, 4-(N′-(3-hydroxy-4-methylphenyl)ureido)butyl acrylate, 4-(N′-(2-hydroxy-5-methylphenyl)ureido)butyl acrylate, 4-(N′-(5-hydroxynaphthyl)ureido)butyl acrylate or 4-(N′-(4-hydroxy-5-phenylphenyl)ureido)butyl acrylate; and a methacrylate derivative such as 1-(N′-(4-hydroxyphenyl)ureido)methyl methacrylate, 1-(N′-(3-hydroxyphenyl)ureido)methyl methacrylate, 1-(N′-(2-hydroxyphenyl)ureido)methyl methacrylate, 1-(N′-(3-hydroxy-4-methylphenyl)ureido)methyl methacrylate, 1-(N′-(2-hydroxy-5-methylphenyl)ureido)methyl methacrylate, 1-(N′-(5-hydroxynaphthyl)ureido)methyl methacrylate, 1-(N′-(2-hydroxy-5-phenylphenyl)ureido)methyl methacrylate, 2-(N′-(4-hydroxyphenyl)ureido)ethyl methacrylate, 2-(N′-(3-hydroxyphenyl)ureido)ethyl methacrylate, 2-(N′-(2-hydroxyphenyl)ureido)ethyl methacrylate, 2-(N′-(3-hydroxy-4-methylphenyl)ureido)ethyl methacrylate, 2-(N′-(2-hydroxy-5-methylphenyl)ureido)ethyl methacrylate, 2-(N′-(5-hydroxy-naphthylphenyl)ureido)ethyl methacrylate, 2-(N′-(2-hydroxy-5-phenylphenyl)ureido)ethyl methacrylate, 4-(N′-(4-hydroxyphenyl)ureido)butyl methacrylate, 4-(N′-(3-hydroxyphenyl)ureido)butyl methacrylate, 4-(N′-(2-hydroxyphenyl)ureido)butyl methacrylate, 4-(N′-(3-hydroxy-4-methylphenyl)ureido)butyl methacrylate, 4-(N′-(2-hydroxy-5-methylphenyl)ureido)butyl methacrylate, 4-(N′-(5-hydroxynaphthyl)ureido)butyl methacrylate or 4-(N′-(4-hydroxy-5-phenylphenyl)ureido)butyl methacrylate.

Among these monomers, acrylates or methacrylates having a carbon atom number of not more than 20, acrylamides, methacrylamides, acrylic acid, methacrylic acid, acrylonitriles, maleic imides or vinyl monomers having a ureido group are preferably used.

The weight average molecular weight Mw of the acryl resin or the modified acryl resin in the invention is preferably not less than 2000, more preferably from 5000 to 100000, and still more preferably from 10000 to 50000. The above molecular weight range makes it possible to adjust layer strength, alkali solubility, or chemical resistance of the layer, whereby the advantageous effects of the invention are easily obtained.

The acryl resin may be in the form of random polymer, blocked polymer, or graft polymer, and is preferably a blocked polymer capable of separating a hydrophilic group from a hydrophobic group, in that it can adjust solubility to a developer.

The acryl resin may be used singly or as a mixture of two or more kinds thereof.

### (Acetal Resin)

The polyvinyl acetal resins can be synthesized by acetalyzing polyvinyl alcohol with aldehydes and reacting the residual hydroxyl group with acid anhydrides.

Examples of the aldehydes include formaldehyde, acetaldehyde, propionaldehyde, butylaldehyde, pentylaldehyde, hexylaldehyde, glyoxalic aicd, N,N-dimethylformamide, di-n-butylacetal, bromoacetaldehyde, chloroaldehyde, 3-hydroxy-n-butylaldehyde, 3-methoxy-n-butylaldehyde, 3-dimethylamino-2,2-dimethylpropionaldehyde, and cyanoacetaldehyde. In the invention, the aldehydes are not limited thereto.

The acetal resin is preferably a polyvinyl acetal resin represented by the following formula (PVAC):

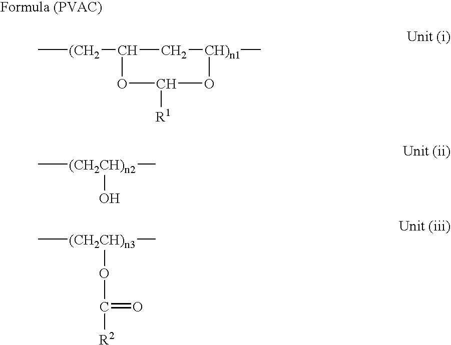

In formula (PVAC), n1 represents 5 to 85 mol % by mole, n2 represents 0 to 60 mol % by mole, and n3 represents 0 to 60 mol %.

The unit (i) is a group derived from vinyl acetal, the unit (ii) is a group derived from vinyl alcohol, and the unit (iii) is a group derived from vinyl ester.

In unit (i), R¹ represents a hydrogen atom, a substituted or unsubstituted alkyl group, an aryl group, a carboxyl group or a dimethylamino group. Examples of the substituent include a carboxyl group, a hydroxyl group, a chlorine atom, a bromine atom, a urethane group, a ureido group, a tertiary amino group, an alkoxy group, a cyano group, a nitro group, an amido group, and an ester group. Examples of R¹ include a hydrogen atom, a methyl group, an ethyl group, a propyl group, a butyl group, a pentyl group, a carboxyl group, a halogen atom (—Br or Cl), a cyanomethyl group, 3-hydroxybutyl group, 3-methoxybutyl group and a phenyl group.

In unit (i), N1 represents 5 to 85% by mole, and preferably 25 to 75% by mole. The above range of n1 is advantageous in layer strength, printing durability or solubility to a solvent for coating.

In unit (2), n2 represents 0 to 60% by mole, and preferably from 10 to 45% by mole. The unit (ii) is a unit having great affinity to water. The above range of n2 is advantageous in printing durability.

In unit (iii), R² represents an unsubstituted alkyl group, an aliphatic hydrocarbon group having a carboxyl group, an alicyclic group, or an aromatic hydrocarbon group. The hydrocarbon groups have a carbon atom number of from 1 to 20. R² is preferably an alkyl group having a carbon atom number of from 1 to 10, and more preferably a methyl group or an ethyl group. In unit (3), n3 represents 0 to 20% by mole, and preferably from 1 to 10% by mole. The above range of n3 is advantageous in printing durability.

The acid content of the polyvinyl acetal resin in the invention is preferably from 0.5 to 5.0 meq/g (from 84 to 280 in terms of acid value), and more preferably from 0.1 to 3.0 meq/g.

The weight average molecular weight of the polyvinyl acetal resin in the invention is preferably from about 5000 to 400,000, and more preferably from about 20,000 to 300,000, being measured according to gel permeation chromatography. The above molecular weight range makes it possible to adjust layer strength, alkali solubility, or chemical resistance of the layer, whereby the advantageous effects of the invention are easily obtained.

These polyvinyl acetal resins may be used singly or as a mixture of two or more kinds thereof.

The acetalyzation of polyvinyl alcohol can be carried out according to conventional methods disclosed in for example, U.S. Pat. Nos. 4,665,124, 4,940,646, 5,169,898, 5,700,619, and 5,792,823, and Japanese Patent No. 09328519.

### (Fluoroalkyl Group-Containing Acryl Resin)

The fluoroalkyl group-containing acryl resin is a homopolymer or copolymer having a monomer unit having a fluoroalkyl group.

The fluoroalkyl group-containing acryl resin is preferably a resin which is obtained by polymerization of a monomer represented by formula (FACP) below, and more preferably a copolymer comprising as a comonomer unit a monomer unit derived from that monomer

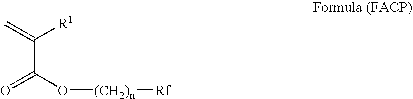

In formula (FACP), Rf represents a fluoroalkyl group (for example, a perfluoroalkyl group) having a fluorine atom number of not less than 3 or a substituent with a fluoroalkyl group (for example, a perfluoroalkyl group) having a fluorine atom number of not less than 3; n is 1 or 2; and R¹ represents a hydrogen atom or an alkyl group having a carbon atom number of from 1 to 4. Rf is, for example, —CₘF₂ₘ₊₁ or —(CF₂)ₘH (in which m is an integer of from 4 to 12).

The fluoroalkyl group having a fluorine atom number of not less than 3 or perfluoroalkyl group lowers the heat transfer coefficient of the layer and minimizes exposure unevenness resulting from kinds of an exposure device, resulting in high productivity.

The fluorine atom number per the monomer unit is preferably not less than 3, more preferably not less than 6, and still more preferably not less than 9.

The above-described fluorine atom number range locates the fluoroalkyl group-containing acryl resin on the surface of the layer, resulting in excellent ink receptivity.

The fluorine atom content of the fluoroalkyl group-containing acryl resin is preferably from 5 to 30 mmol/g, and more preferably from 8 to 25 mmol/g, in view of surface orientation of the resin, and balance between the developability and ink receptivity.

The comonomer unit in the copolymer having a fluoroalkyl group is derived from the comonomer used in preparation of the acryl resin as described above. Examples of the comonomer include acrylate, methacrylate, acrylamide, methacrylamide, styrene and a vinyl monomer. Acrylate, methacrylate, acrylamide, or methacrylamide is especially preferred.

The average molecular weight of the fluoroalkyl group-containing acryl resin is preferably from 3000 to 200000, and more preferably from 6000 to 100000.

The content of the fluoroalkyl group-containing acryl resin in the upper or lower layer is preferably from 0.01 to 50% by weight, more preferably from 0.1 to 30% by weight, and still more preferably from 1 to 15% by weight, in view of image uniformity, sensitivity and development latitude.

When two light sensitive layers upper and lower light sensitive layers are provided, it is preferred that the upper light sensitive layer contains the fluoroalkyl group-containing acryl resin, in view of development restraint property and dissolution resistance to chemicals used during printing.

Typical examples of the fluoroalkyl group-containing acryl resin will be listed below. The numerical numbers in the following formulae represent mol % of the monomer units.

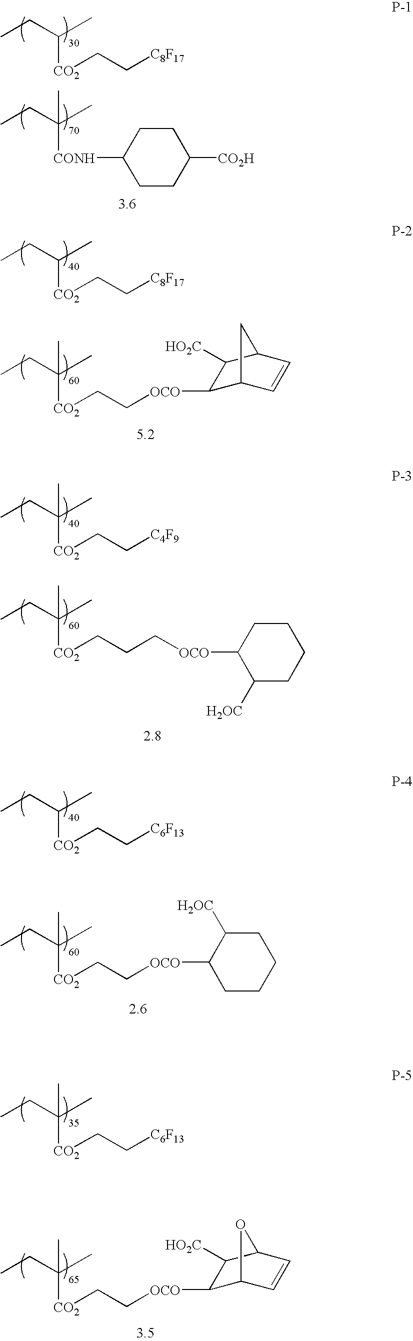

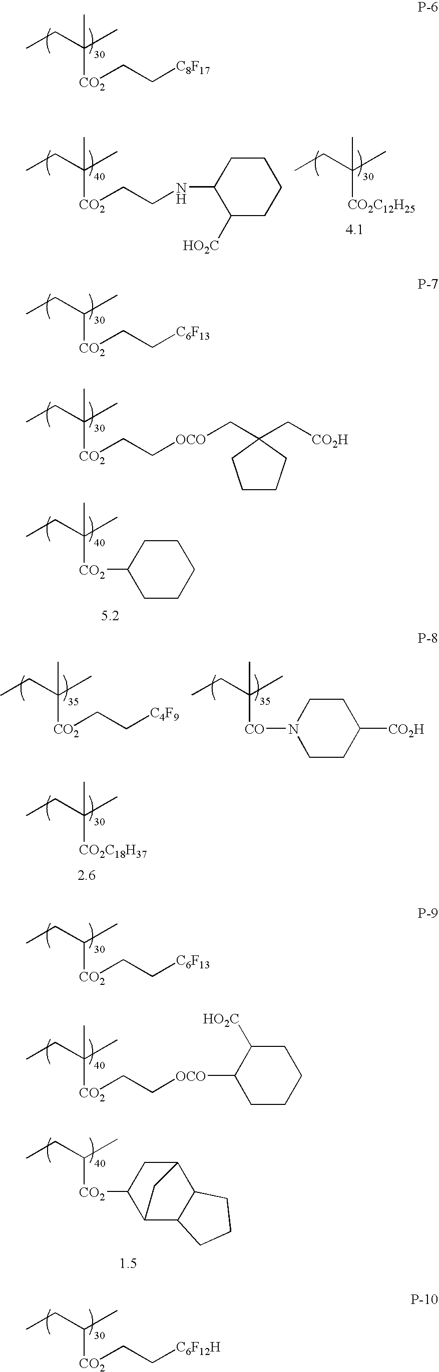

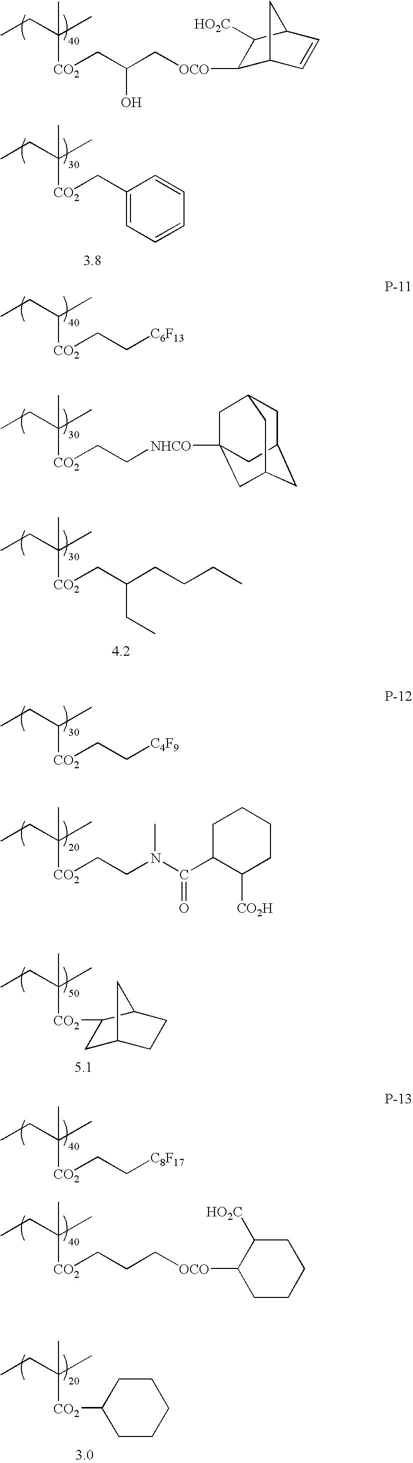

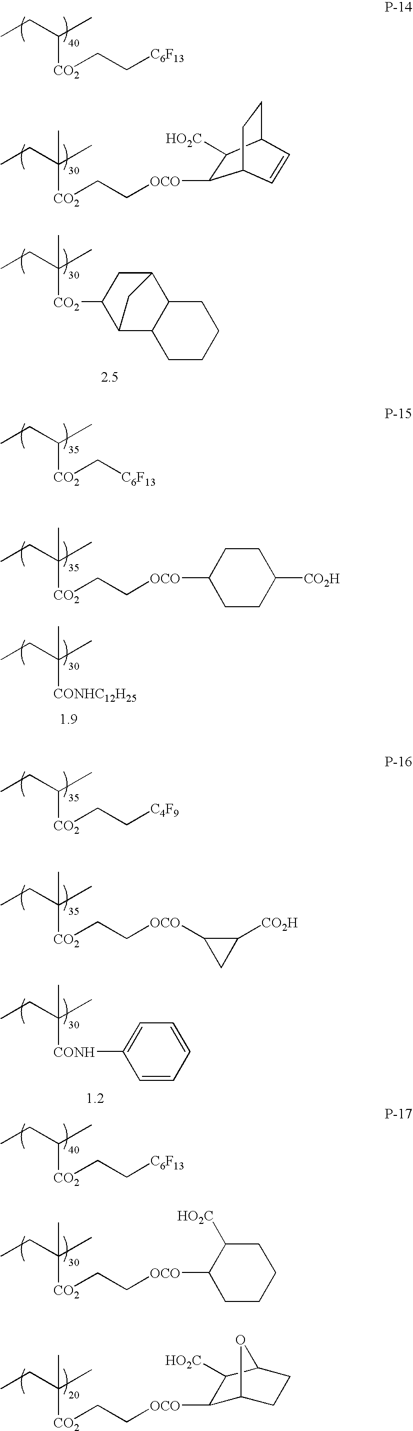

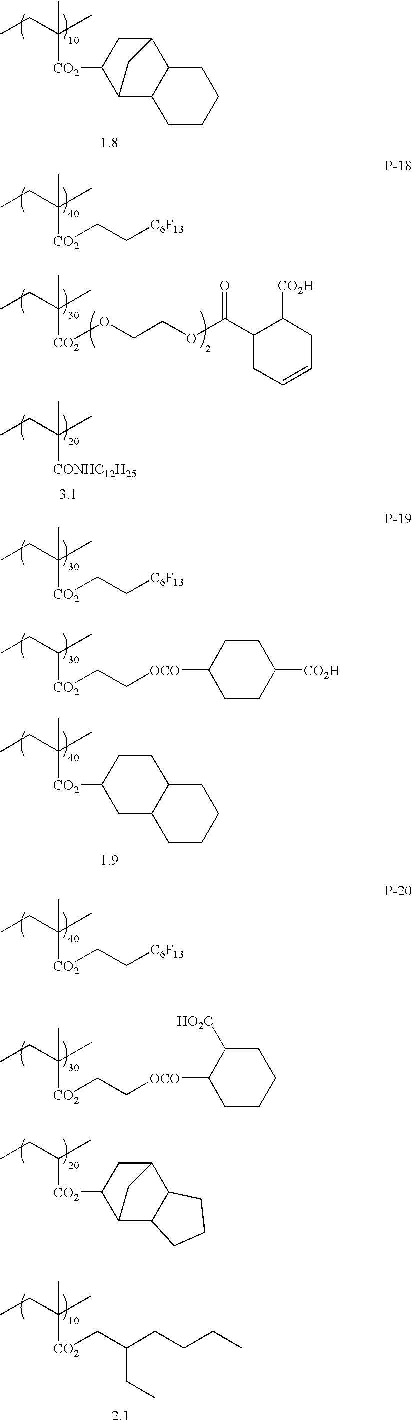

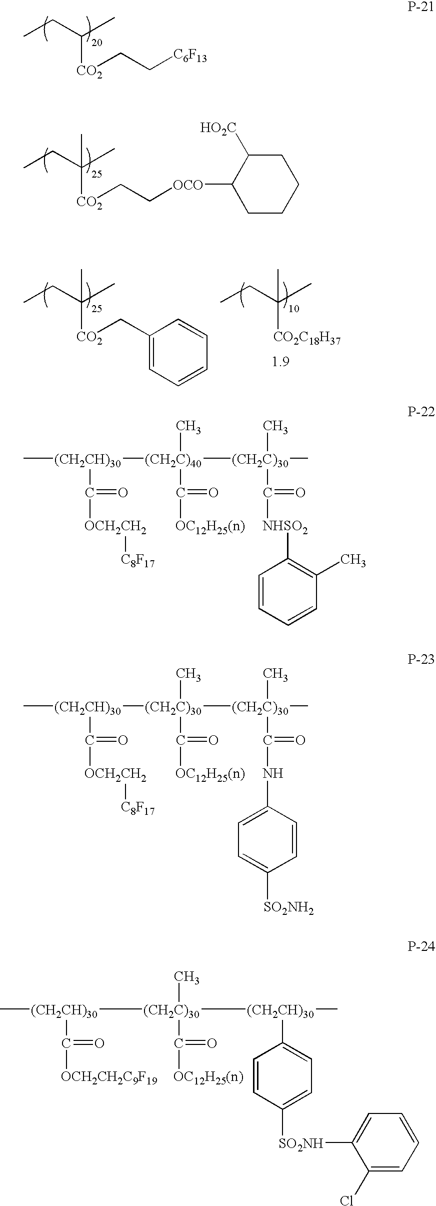

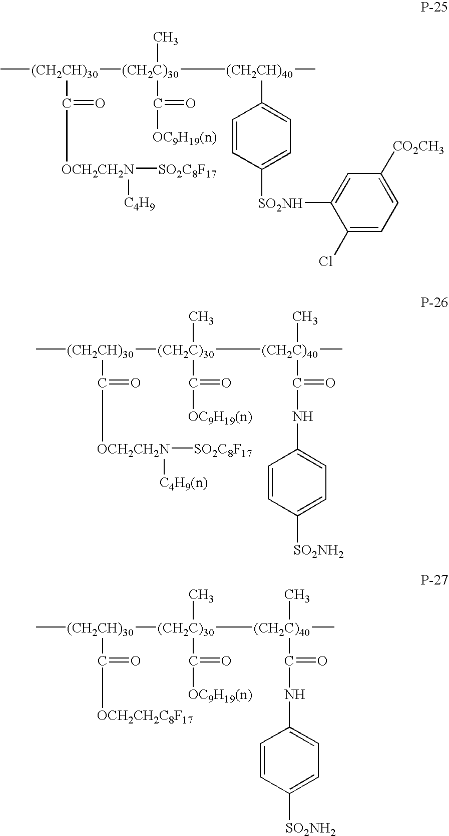

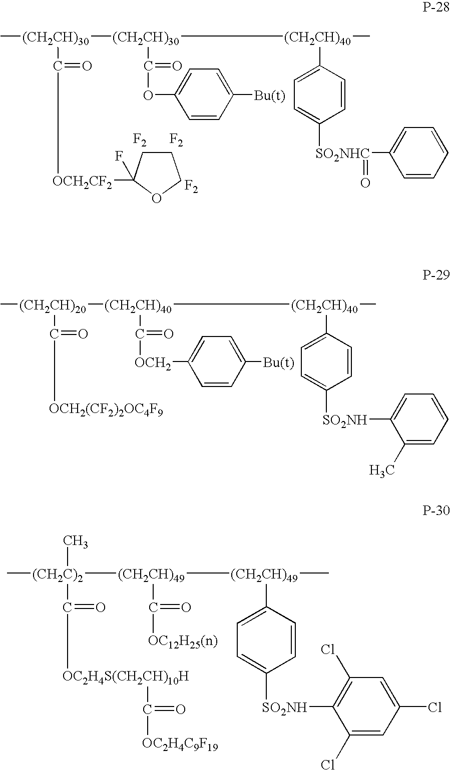

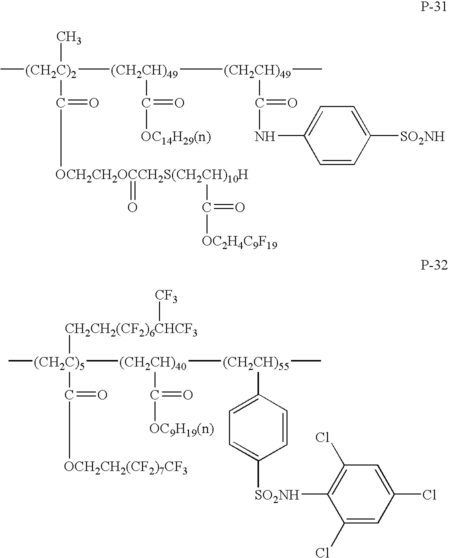

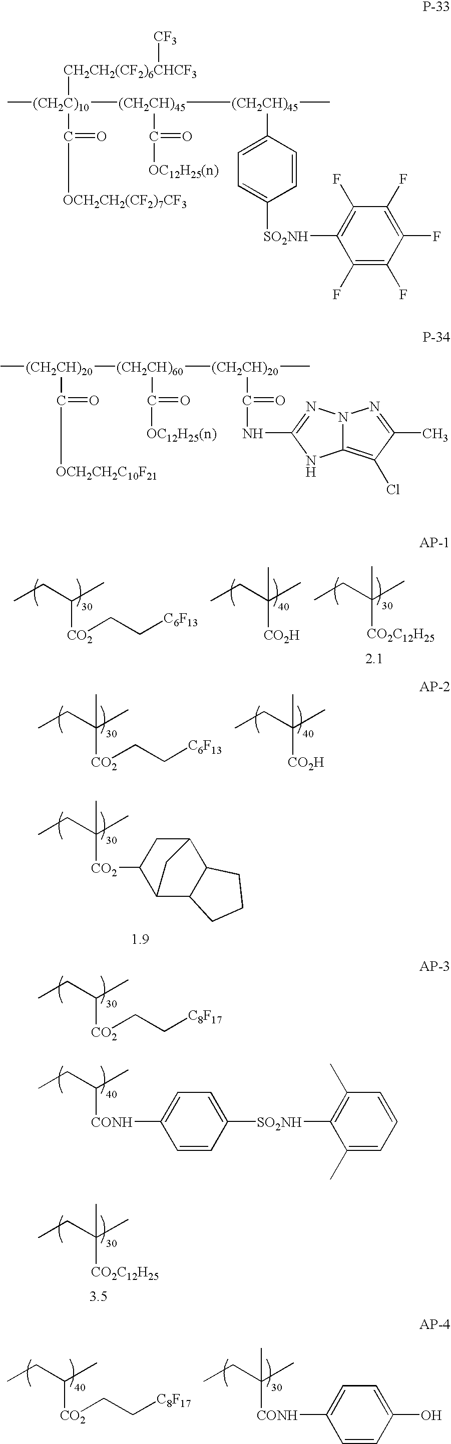

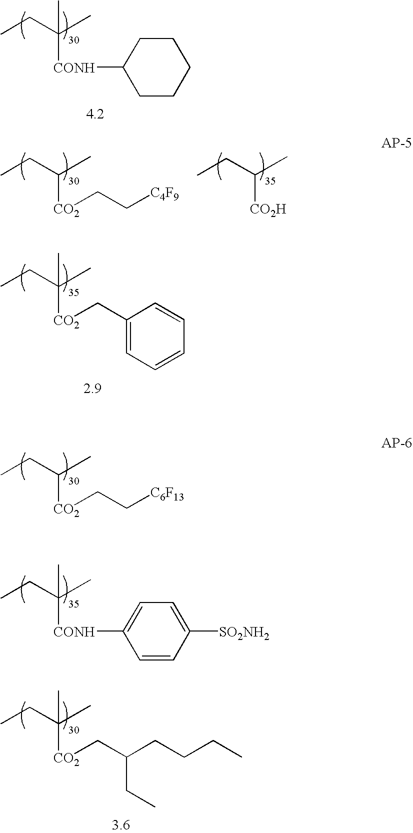

The action of the fluoroalkyl group-containing acryl resin in the invention is not clear, but it is assumed that in a planographic printing plate material comprising a support and provided thereon a lower layer and an upper layer in the order, each layer containing an alkali soluble resin, incorporation an acid decomposable compound or an acid generating agent in the lower layer improves sensitivity and development latitude. Further, it is assumed that incorporation of a fluoroalkyl group-containing acryl resin in at least one of the upper and lower layers lowers the heat transfer coefficient and a combined use of the fluoroalkyl group-containing acryl resin and an acid decomposable compound or an acid generating agent lowers heat transfer at portions at the vicinity of exposed portions, which results in high productivity and an image with high precision and uniformity. Thus, the present invention provides a light sensitive planographic printing plate material which excels in all of image uniformity, sensitivity, development latitude and chemical resistance.

### (Infrared Absorbing Compound)

The infrared absorbing compound used in the invention refers to a compound having an absorption band in the infrared wavelength regions of from not shorter than 700 nm, and preferably from 750 to 1200 nm, and converting light with those wavelength regions to heat, and the typical examples thereof include a dye or pigment generating heat on absorption of light with those wavelength regions.

The infrared absorbing compound may be used as an admixture of two or more kinds thereof. When there are two light sensitive layers, upper and lower light sensitive layers, the infrared absorbing compound can be contained in one or both of the upper and lower light sensitive layers. The infrared absorbing compound is preferably contained in both of the upper and lower light sensitive layers, in view of sensitivity and development latitude.

### (Pigment)

As pigment commercially available pigments and pigments described in Color Index (C.I.) Binran, “Saishin Ganryo Binran” (ed. by Nihon Ganryo Gijutsu Kyokai, 1977), “Saishin Ganryo Oyo Gijutsu” (CMC Publishing Co., Ltd., 1986), and “Insatsu Inki Gijutsu” (CMC Publishing Co., Ltd., 1984) can be used.

Kinds of the pigment include black pigment, yellow pigment, orange pigment, brown pigment, red pigment, violet pigment, blue pigment, green pigment, fluorescent pigment, metal powder pigment, and metal-containing colorants. Typical examples of the pigment include insoluble azo pigment, azo lake pigment, condensed azo pigment, chelate azo pigment, phthalocyanine pigment, anthraquinone pigment, perylene or perynone pigment, thioindigo pigment, quinacridone pigment, dioxazine pigment, isoindolinone pigment, quinophthalone pigment, lake pigment, azine pigment, nitroso pigment, nitro pigment, natural pigment, fluorescent pigment, inorganic pigment, and carbon black.

The particle size of the pigment is preferably from 0.01 to 10 μm, more preferably from 0.05 to 1 μm, and still more preferably from 0.1 to 1 μm.

As a dispersion method of pigments, a conventional dispersion method used in manufacture of printing ink or toners can be used. Dispersion devices include an ultrasonic disperser, a sand mill, an atliter, a pearl mill, a super mill, a ball mill, an impeller, a disperser, a KD mill, a colloid mill, a dynatron, a three-roll mill, and a pressure kneader. The details are described in “Saishin Ganryo Oyou Gijutsu” (CMC Publishing Co., Ltd., 1986).

The pigment content of the upper layer in the invention is preferably from 0.01 to 10% by weight, and more preferably from 0.1 to 5% by weight, in view of uniformity and durability of the layer, and sensitivity.

### (Dyes)

As the dyes, well-known dyes, i.e., commercially available dyes or dyes described in literatures (for example, “Senryo Binran”, edited by Yuki Gosei Kagaku Kyokai, published in 1970) can be used. Examples thereof include azo dyes, metal complex azo dyes, pyrazoline azo dyes, anthraquinone dyes, phthalocyanine dyes, carbonium dyes, quinonimine dyes, methine dyes, and cyanine dyes. Among these dyes or pigments, dyes absorbing an infrared light or a near-infrared light are preferred in that a laser emitting an infrared light or a near-infrared light can be employed.

Examples of the dyes absorbing an infrared light or a near-infrared light include cyanine dyes disclosed in Japanese Patent O.P.I. Publication Nos. 58-125246, 59-84356, and 60-78787, methine dyes disclosed in Japanese Patent O.P.I. Publication Nos. 58-173696, 58-181690, and 58-194595, naphthoquinone dyes disclosed in Japanese Patent O.P.I. Publication Nos. 58-112793, 58-224793, 59-48187, 59-73996, 60-52940, and 60-63744, squarylium dyes disclosed in Japanese Patent O.P.I. Publication Nos. 58-112792, and cyanine dyes disclosed in British Patent No. 434,875. Further, near infrared absorbing sensitizing dyes described in U.S. Pat. No. 5,156,938 are suitably employed as the dyes. In addition, preferably employed are substituted arylbenzo(thio)pyrylium salts described in U.S. Pat. No. 3,881,924; trimethine-thiapyrylium salts described in Japanese Patent O.P.I. Publication No. 57-142645 (U.S. Pat. No. 4,327,169); pyrylium based compounds described in Japanese Patent O.P.I. Publication Nos. 58-181051, 58-220143, 59-41363, 59-84248, 59-84249, 59-146063, and 59-146061; cyanine dyes described in Japanese Patent O.P.I. Publication No. 59-216146; pentamethinethiopyrylium salts described in U.S. Pat. No. 4,283,475; pyrylium compounds described in Japanese Patent Publication No. 5-13514 and 5-19702, and Epolight III-178, Epolight III-130 or Epolight III-125.

Of these dyes, particularly preferred dyes are cyanine dyes, phthalocyanine dyes, oxonol dyes, squarylium dyes, pyrylium dyes, thiopyrylium dyes, and nickel thiolato complexes. A cyanine dye represented by formula (CD) is most preferred in providing high interaction with the alkali soluble resin, excellent stability and excellent economical performance.

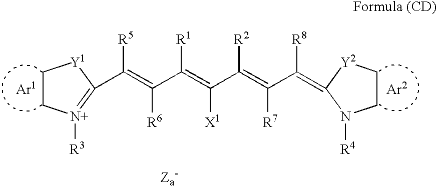

In formula (CD), X¹ represents a hydrogen atom, a halogen atom, —NPh₂, X²-L¹, in which X² represents an oxygen atom or a sulfur atom, and L¹ represents a hydrocarbon group having a carbon atom number of from 1 to 12, a heteroatom-containing aromatic ring group or a heteroatom-containing hydrocarbon group having a carbon atom number of from 1 to 12, or a group represented by formula (a):

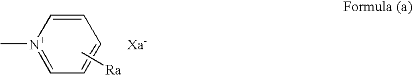

wherein Xa⁻ represents the same as Za⁻ described later; Ra represents a hydrogen atom, an alkyl group, an aryl group, a substituted or unsubstituted amino group, or a halogen atom.

In the above, the heteroatom refers to N, S, O, a halogen atom, or Se.

R¹ and R² independently represent a hydrocarbon group having a carbon atom number of from 1 to 12, provided that R¹ and R² may combine with each other to form a 5- or 6-membered ring.

Ar¹ and Ar² independently represent a substituted or unsubstituted aromatic hydrocarbon group, and may be the same or different. Preferred examples of the (unsubstituted) aromatic hydrocarbon groups include a phenyl group or a naphthyl group, and preferred examples of the substituent include a hydrocarbon group having a carbon atom number of not more than 12, a halogen atom or an alkoxy group having a carbon atom number of not more than 12. Y¹ and Y² independently represent a sulfur atom or a diaklylmethylene group having a carbon atom number of not more than 12, and may be the same or different. R³ and R⁴ independently represent a substituted or unsubstituted hydrocarbon group having a carbon atom number of not more than 20, and may be the same or different. Examples of the substituent include an alkoxy group having a carbon atom number of not more than 12, a carboxyl group or a sulfo group. R⁵, R⁶, R⁷ and R⁸ independently represent a hydrogen atom or a hydrocarbon group having a carbon atom number of not more than 12, and may be the same or different. R⁵, R⁶, R⁷ and R⁸ represent preferably a hydrogen atom in view of availability. Za⁻ represents an anionic group, provided that when the cyanine dye represented by formula (CD) forms an intramolecular salt, Za⁻ is not necessary. Preferred examples of Za⁻ include a halogen ion, a perchlorate ion, a tetrafluoroborate ion, a hexafluorophosphate ion, and a sulfonate ion. Especially preferred Za⁻ is a perchlorate ion, a hexafluorophosphate ion, or an arylsulfonate ion.

Typical examples of the cyanine dye represented by formula (CD) will be listed below.

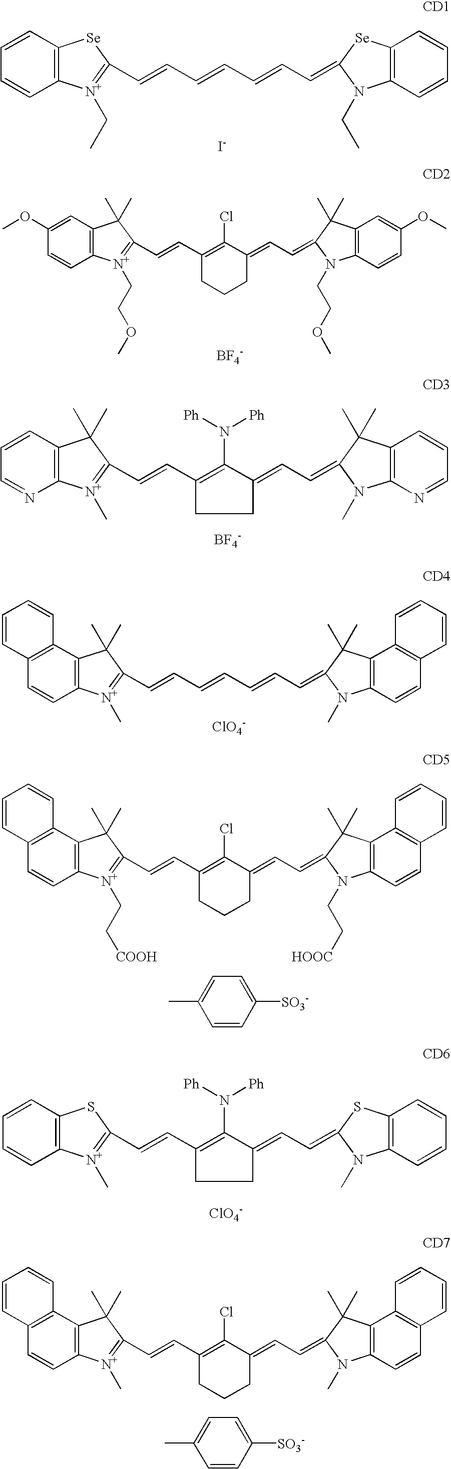

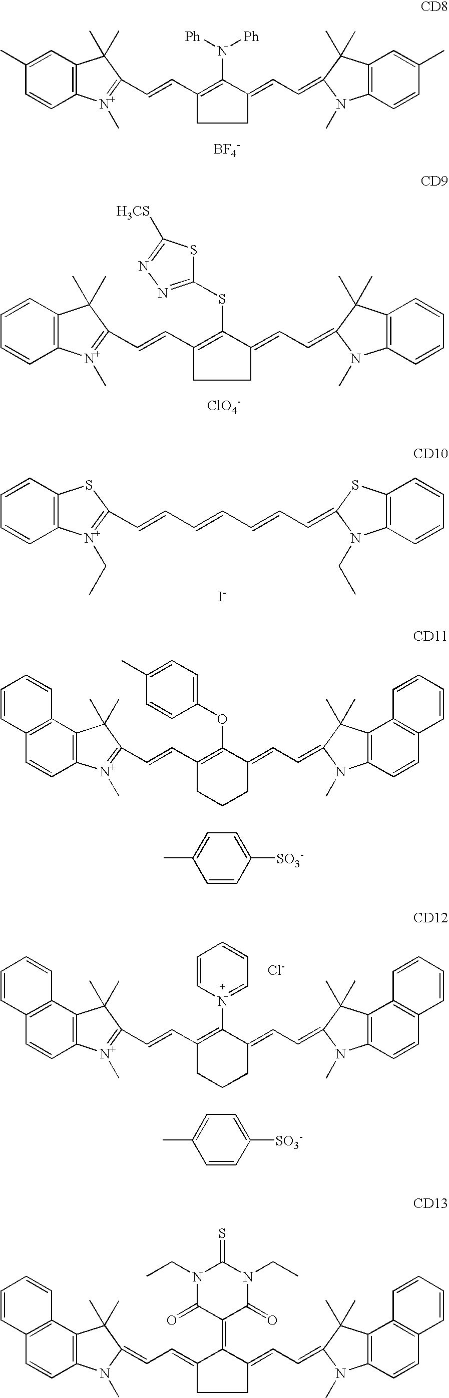

Other examples of the cyanine dye represented by formula (CD) include ones disclosed in Japanese Patent O.P.I. Publication No. 2001-133969, paragraphs [0017]-[0019], Japanese Patent O.P.I. Publication No. 2002-40638, paragraphs [0012]-[0038], and Japanese Patent O.P.I. Publication No. 2002-23360, paragraphs [0012]-[0023].

The infrared absorbing dye content of the light sensitive layer is preferably from 0.01 to 30% by weight, more preferably from 0.1 to 10% by weight, and still more preferably from 0.1 to 7% by weight, in view of sensitivity, chemical resistance and printing durability.

### (Acid Decomposable Compound)

The light sensitive layer in the invention preferably contains an acid decomposable compound. The acid decomposable compound is preferably a compound represented by formula (ADC) above.

When there are two or more light sensitive layers, it is preferred that the acid decomposable compound represented by formula (ADC) is contained in at least one of the two or more light sensitive layers. For example, when there are two light sensitive layers, upper and lower light sensitive layers, it is preferred in sensitivity and development latitude that the acid decomposable compound is contained in the lower layer.

In formula (ADC), n represents an integer of 1 or more; m represents an integer of 0 or more; X represents a carbon atom or a silicon atom; and R₄ represents an ethyleneoxy group or a propyleneoxy group. R₂ and R₅ independently represent a hydrogen atom, an alkyl group or an aryl group; R₃ and R₆ independently represent an alkyl group or an aryl group, provided that R₂ and R₃ may combine with each other to form a ring or R₅ and R₆ may combine with each other to form a ring; R₇ represents an alkylene group; R₁ represents a hydrogen atom, an alkyl group, an aryl group, an alkoxy group, an aryloxy group or a halogen atom; and R₈ represents a hydrogen atom, —XR₂R₃R₁ or —XR₅R₆R₁.

Of the acid decomposable compounds represented by formula (ADC) above, an acetal is preferred. It is preferred in view of good yield that such an acetal is synthesized by polycondensation of dimethylacetal or diethylacetal derivatives of aldehydes or ketones with diol compounds such as ethylene glycol, diethylene glycol, triethylene glycol, tetraethylene glycol, pentaethylene glycol, polyethylene glycol, propylene glycol, dipropylene glycol, tripropylene glycol, tetrapropylene glycol, pentapropylene glycol, polypropylene glycol, and polyethylene glycol-polypropylene glycol copolymer.

Examples of the aldehydes for preparation of the acetals include acetoaldehyde, chloral, ethoxyacetoaldehyde, benzyloxyacetoaldehyde, phenylacetoaldehyde, diphenylacetoaldehyde, phenoxyacetoaldehyde, propionaldehyde, 2-phenyl or 3-phenylaldehyde, isobutoxypivalic aldehyde, benzyloxypivalic aldehyde, 3-ethoxypropanal, 3-cyanopropanal, n-butanal, isobutanal, 3-chloro-butanal, 3-methoxy-butanal, 2,2-dimethyl-4-cyano-butanal, 2 or 3-ethylbutanal, n-pentanal, 2 or 3-methylpentanal, 2-bromo-3-methylpentanal, 2-hexanal, cyclopentanecarbaldehyde, n-heptanal, cyclohexanecarbaldehyde, 1,2,3,6-tetrahydrobenzaldehyde, 3-ethylpentanal, 3- or 4-methyl-hexanal, n-octanal, 2- or 4-ethylhexanal, 3,5,5-trimethylhexanal, 4-methylheptanal, 3-ethyl-n-heptanal, decanal, dodecanal, crotonaldehyde, benzaldehyde, 2-, 3- or 4-bromobenzaldehyde, 2,4-, or 3,4-dichlorobenzaldehyde, 4-methoxybenzaldehyde, 2,3- or 2,4-dimethoxybenzaldehyde, 2-, 3- or 4-fluorobenzaldehyde, 2-, 3- or 4-methylbenzaldehyde, 4-isopropylbenzaldehyde, 3- or 4-tetrafluoroethoxybenzaldehyde, 1-, or 2-naphthoaldehyde, furfural, thiophene-2-aldehyde, terephthalaldehyde, piperonal, 2-pyridinecarbaldehyde, p-hydroxy-benzaldehyde, 3,4-dihydroxy-benzaldehyde, 5-methyl-furaldehyde and vanillin. Ketones for preparation of the ketals include phenylacetone, 1,3-diphenylacetone, 2,2-diphenylacetone, chloro, or bromoacetone, benzylacetone, methyl ethyl ketone, benzyl propyl ketone, ethylbenzyl ketone, isobutyl ketone, 5-methyl-hexane-2-one, 2-methyl-pentane-2-one, 2-methyl-pentane-3-one, hexane-2-one, pentane-3-one, 2-methyl-butane-3-one, 2,2-dimethyl-butane-3-one, 5-methyl-heptane-3-one, octane-2-one, octane-3-one, nonane-2-one, nonane-3-one, nonane-5-one, heptane-2-one, heptane-3-one, heptane-4-one, undecane-2-one, undecane-4-one, undecane-5-one, undecane-6-one, dodecane-2-one, dodecane-3-one, triecane-2-one, tridecane-3-one, triecane-7-one, dinonyl ketone, dioctyl ketone, 2-methyl-octane-3-one, cyclopropyl methyl ketone, decane-2-one, decane-3-one, decane-4-one, methyl-α-naphthyl ketone, didecyl ketone, diheptyl ketone, dihexyl ketone, acetophenone, 4-methoxy-acetophenone, 4-chloro-acetophenone, 2,4-dimethyl-acetophenone, 2-, 3- or 4-fluoroacetophenone, 2-3- or 4-methylacetophenone, 2-, 3- or 4-methoxyacetophenone, propiophenone, 4-methoxy-propiophenone, butyrophenone, valerophenone, benzophenone, 3,4-dihydroxybenzophenone, 2,5-dimethoxybenzophenone, 3,4-dimethoxybenzophenone, 3,4-dimethylbenzophenone, cyclohexanone, 2-phenyl-cyclohexanone, 2-, 3- or 4-methyl-cyclohexanone, 4-t-butyl-cyclohexanone, 2,6-dimethyl-cyclohexanone, 2-chloro-cyclohexanone, cyclopentanone, cycloheptanone, cyclooctanone, cyclononanone, 2-cyclohexene-1-one, cyclohexylpropanone, flavanone, cyclohexane-1,4-dione, cyclohexane-1,3-dione, tropone, and isophorone.

The preferable are aldehydes or ketones which have a solubility in 25° C. water of 1 to 100 g/liter, in view of reduction of sludge produced during continuous processing, and prevention resolving power of formed images from lowering.

Examples thereof include benzaldehyde, 4-hydroxybenzaldehyde, 3, 4-dihydroxybenzaldehyde, 2-pyridinecarbaldehyde, piperonal, phthalaldehyde, terephthalaldehyde, 5-methyl-2-phthalaldehyde, phenoxyacetoaldehyde, phenylacetoaldehyde, cyclohexanecarbaldehyde, vanillin, cyclohexanone, cyclohexene-1-one, isobutylaldehyde, and pentanal. Of these, cyclohexanone is more preferable in view of processing stability.

The silyl ether compound in the invention is synthesized by polycondensation of a silyl compound with the above diol compound.

In the invention, a silyl compound, which forms on decomposition of the silylether compound by an acid, has preferably a solubility in 25° C. water of 1 to 100 g/liter.

Examples of the silyl compound include dichlorodimethyl silane, dichlorodiethyl silane, methylphenyldichloro silane, diphenyldichloro silane, and methylbenzyldichloro silane.

The above described acetal compounds or silylether compounds can be synthesized also by copolycondensation using the above diol compounds and alcohol components other than the diol compounds. Examples of the alcohol components include substituted or unsubstituted monoalkyl alcohols such as methanol, ethanol, n-propanol, isopropanol, butanol, pentanol, hexanol, cyclohexanol, and benzyl alcohol; glycol ethers such as ethylene glycol monomethylether, ethylene glycol monoethylether, ethylene glycol monomphenylether, diethylene glycol monomethylether, diethylene glycol monoethylether, diethylene glycol monophenylether, and substituted or unsubstituted polyethylene glycol alkylethers or polyethylene glycol phenylethers. Examples of dihydric alcohols include pentane-1,5-diol, n-hexane-1,6-diol, 2-ethylhexane-1,6-diol, 2,3-dimethylhexane-1,6-diol, heptane-1,7-diol, cyclohexane-1,4-diol, nonane-1,7-diol, nonane-1,9-diol, 3,6-dimethyl-nonane-1,9-diol, decane-1,10-diol, dodecane-1,12-diol, 1,4-bis(hydroxymethyl)-cyclohexane, 2-ethyl-1,4-bis(hydroxymethyl)-cyclohexane, 2-methyl-cyclohexane-1,4-diethanol, 2-methyl-cyclohexane-1,4-dipropanol, thio-dipropylene glycol, 3-methyl-pentane-1,5-diol, dibutylene glycol, 4,8-bis(hydroxymethyl)-tricyclodecane, 2-butene-1,4-diol, p-xylylene glycol, 2,5-dimethyl-hexane-3-yne-2,5-diol, bis(2-hydroxyethyl)-sulfide, and 2,2,4,4-tetramethylcyclobutane-1,3-diol. In this embodiment, the content ratio (by mole) of the diol compound containing an ethylene glycol component or a propylene glycol component to the alcohol component in the acetal compounds or silyl ether compounds is preferably from 70:30 to 100:0, and more preferably from 85:15 to 100:0.

The acid decomposable compound in the invention has a weight average molecular weight of preferably 500 to 10000, and more preferably 1000 to 3000 in terms of standard polystyrene measured according to gel permeation chromatography (GPC).

As other acid decomposable compound, a compound having a Si-N bond disclosed in Japanese Patent O.P.I. Publication No. 62-222246, a carbonic acid ester disclosed in Japanese Patent O.P.I. Publication No. 62-251743, an orthotitanic acid ester disclosed in Japanese Patent O.P.I. Publication No. 62-280841, an orthosilicic acid ester disclosed in Japanese Patent O.P.I. Publication No. 62-280842, a compound having a C-S bond disclosed in Japanese Patent O.P.I. Publication No. 62-244038, or a compound having a —O—C(═O)— bond disclosed in Japanese Patent O.P.I. Publication No. 63-231442 can be used in combination.

Synthetic examples of the acid decomposable compound used in the invention will be described below.

### (Synthesis of Acid Decomposable Compound A-1)

A mixture of 1.0 mol of 1,1-dimethoxycyclohexane, 1.0 mol of ethylene glycol, 0.003 mol of p-toluene sulfonic acid hydrate and 500 ml of toluene was reacted at 100° C. for 1 hour with stirring, gradually elevated to 150° C. and reacted at 150° C. for additional 4 hours while methanol produced during reaction was removed. The reaction mixture solution was cooled, washed with water, an aqueous 1% sodium hydroxide solution, and an aqueous 1 N sodium hydroxide solution in that order. The resulting mixture was further washed with an aqueous saturated sodium chloride solution, and dried over anhydrous potassium carbonate. The solvent (toluene) of the resulting solution was removed by evaporation under reduced pressure to obtain a residue. The residue was further dried 80° C. for 10 hours under vacuum to obtain a wax compound. Thus, an acid decomposable compound A-1 in a waxy form was obtained. The weight average molecular weight Mw of compound A-1 was 1200 in terms of standard polystyrene measured according to GPC.

### (Synthesis of Acid Decomposable Compound A-2)

An acid decomposable compound A-2 in a waxy form was prepared in the same manner as in acid decomposable compound A-1, except that diethylene glycol was used instead of ethylene glycol. The weight average molecular weight Mw of compound A-2 was 2000.

### (Synthesis of Acid Decomposable Compound A-3)

An acid decomposable compound A-3 in a waxy form was prepared in the same manner as in acid decomposable compound A-1, except that triethylene glycol was used instead of ethylene glycol. The weight average molecular weight Mw of compound A-3 was 1500.

### (Synthesis of Acid Decomposable Compound A-4)

An acid decomposable compound A-4 in a waxy form was prepared in the same manner as in acid decomposable compound A-1, except that tetraethylene glycol was used instead of ethylene glycol. The weight average molecular weight Mw of compound A-4 was 1500.

### (Synthesis of Acid Decomposable Compound A-5)

An acid decomposable compound A-5 in a waxy form was prepared in the same manner as in acid decomposable compound A-1, except that dipropylene glycol was used instead of ethylene glycol. The weight average molecular weight Mw of compound A-5 was 2000.

### (Synthesis of Acid Decomposable Compound A-6)

An acid decomposable compound A-6 in a waxy form was prepared in the same manner as in acid decomposable compound A-2, except that benzaldehyde dimethylacetal was used instead of 1,1-dimethoxycyclohexane. The weight average molecular weight Mw of compound A-6 was 2000.

### (Synthesis of Acid Decomposable Compound A-7)

An acid decomposable compound A-7 in a waxy form was prepared in the same manner as in acid decomposable compound A-2, except that furaldehyde dimethylacetal was used instead of 1,1-dimethoxycyclohexane. The weight average molecular weight Mw of compound A-7 was 2000.

The content of the acid decomposable compound in the lower layer is preferably from 0.5 to 50% by weight, and more preferably from 1 to 30% by weight, in view of sensitivity, development latitude, and safelight property.

The acid decomposable compound in the invention may be used singly or as an admixture of two or more kinds thereof.

When two light sensitive layers, the upper and lower layers are used, the acid decomposable compound in the invention is preferably contained in the lower layer as described above, in view of sensitivity and development latitude.

### (Acid Generating Agent)

The light sensitive layer of the planographic printing plate material in the invention preferably contains an acid generating agent. The acid generating agent is preferably a photo acid generating agent. The photo acid generating agent is a compound generating an acid on actinic light exposure. For example, a salt of diazonium, phosphonium, sulfonium or iodonium ion with BF₄⁻, PF₆⁻, SbF₆⁻ SiF₆²⁻ or ClO₄⁻, an organic halogen containing compound, o-quinonediazide sulfonylchloride or a mixture of an organic metal and an organic halogen-containing compound can be used as the photo acid generating agent in the invention.

An organic halogen-containing compound capable of generating a free radical, which is well known as a photoinitiator, is a compound capable of generating a hydrogen chloride, and can be also used as the acid generating agent. Further, there are compounds represented by iminosulfonates disclosed in Japanese Patent O.P.I. Publication No. 4-365048, which are photolytically decomposed to generate an acid, disulfone compounds disclosed in Japanese Patent O.P.I. Publication No. 61-166544, o-naphthoquinonediazide-4-sulfonic acid halides disclosed in Japanese Patent O.P.I. Publication No. 50-36209 (U.S. Pat. No. 3,969,118), and o-naphthoquinonediazides disclosed in Japanese Patent O.P.I. Publication No. 55-62444 (British patent No. 2038801) and Japanese Patent Publication No. 1-11935. As other examples of acid generating agent there are cyclohexyl citrate; sulfonic acid alkyl esters such as cyclohexyl p-benzene sulfonate and cyclohexyl p-acetoaminobenzene sulfonate; and alkyl sulfonates as disclosed in Japanese Patent Application No. 9-26878.

Examples of the organic halogen-containing compound capable of forming a hydrogen halide include those disclosed in U.S. Pat. Nos. 3,515,552, 3,536,489 and 3,779,778 and West German Patent No. 2,243,621, and compounds generating an acid by photodegradation disclosed in West German Patent No. 2,610,842. As the photolytically acid generating agent, o-naphthoquinone diazide-4-sulfonylhalogenides disclosed in Japanese Patent O.P.I. Publication No. 50-36209 can be also used.

The acid generating agent is preferably an organic halogen-containing compound in view of sensitivity to infrared rays and storage stability of an image forming material using it. The organic halogen-containing compound is preferably a halogenated alkyl-containing triazines or a halogenated alkyl-containing oxadiazoles. Of these, halogenated alkyl-containing s-triazines are especially preferable. Examples of the halogenated alkyl-containing oxadiazoles include 2-halomethyl-1,3,4-oxadiazole compounds disclosed in Japanese Patent O.P.I. Publication Nos. 54-74728, 55-24113, 55-77742, 60-3626 and 60-138539.

Among compounds generating an acid on radiation exposure or heat application, those especially effectively used will be listed below.

As those effectively used, there are mentioned oxazole derivatives represented by formula (PAG1) or s-triazine derivatives represented by formula (PAG2) each having a trihalomethyl group, Iodonium salts represented by formula (PAG3), sulfonium salts represented by formula (PAG4), diazonium salts, disulfone derivatives represented by formula (PAG5) or iminosulfonate derivatives represented by formula (PAG6).

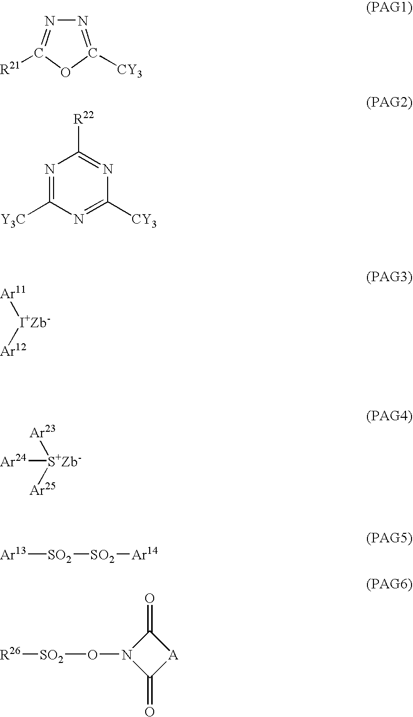

In formulae (PAG1) and (PAG2) above, R²¹ represents a substituted or unsubstituted aryl group or a substituted or unsubstituted alkenyl group; R²² represents a substituted or unsubstituted aryl group, a substituted or unsubstituted alkenyl group, a substituted or unsubstituted alkyl group, or —C(Y₁)₃ in which Y₁ represents a chlorine atom or a bromine atom; and Y represents a chlorine atom or a bromine atom. In formulae (PAG3) and (PAG4) above, Ar¹¹ and Ar¹² independently a substituted or unsubstituted aryl group; Ar²³, Ar²⁴ and Ar²⁵ independently a substituted or unsubstituted alkyl group or a substituted or unsubstituted aryl group, provided that Ar¹¹ and Ar¹², or two of Ar²³, Ar²⁴ and Ar²⁵ may combine with each other through a chemical bond or a divalent linkage group; and Zb⁻ represents an anion. In formulae (PAG5) and (PAG6) above, Ar¹³ and Ar¹⁴ independently a substituted or unsubstituted aryl group; R²⁶ represents a substituted or unsubstituted alkyl group or a substituted or unsubstituted aryl group; and A represents a substituted or unsubstituted alkylene, alkenylene or arylene group.

Examples thereof will be listed below, but the invention is not limited thereto.

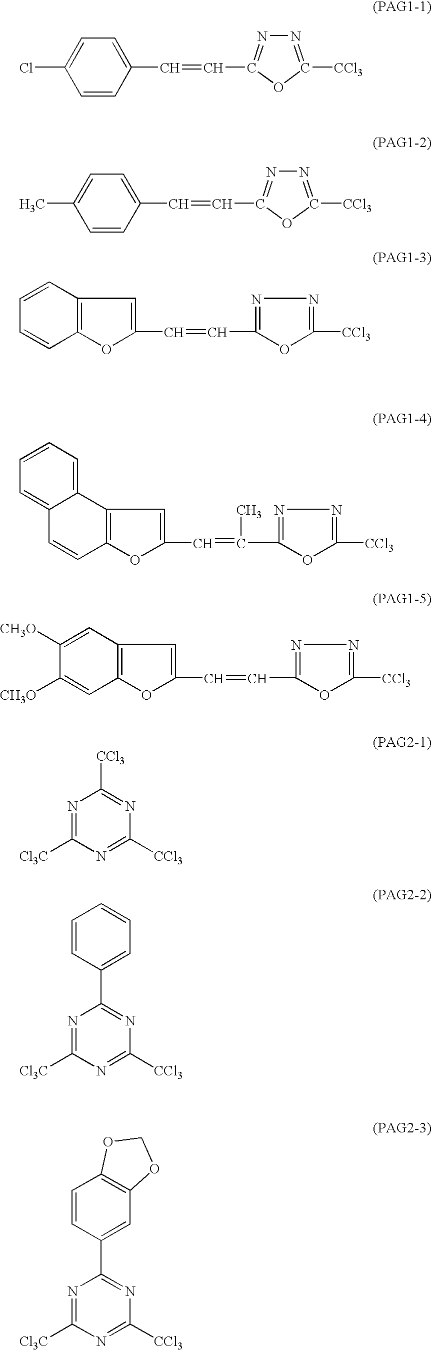

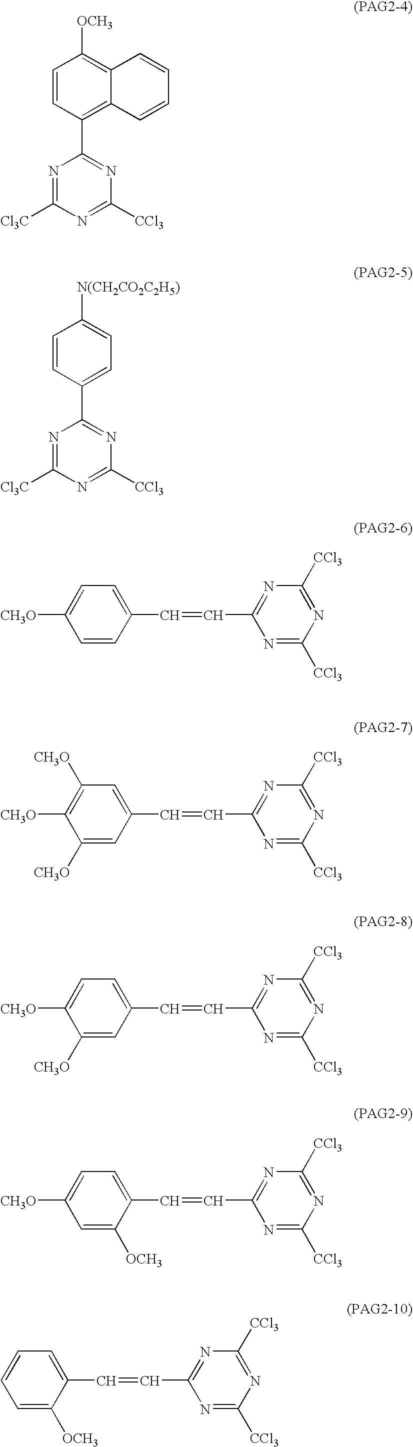

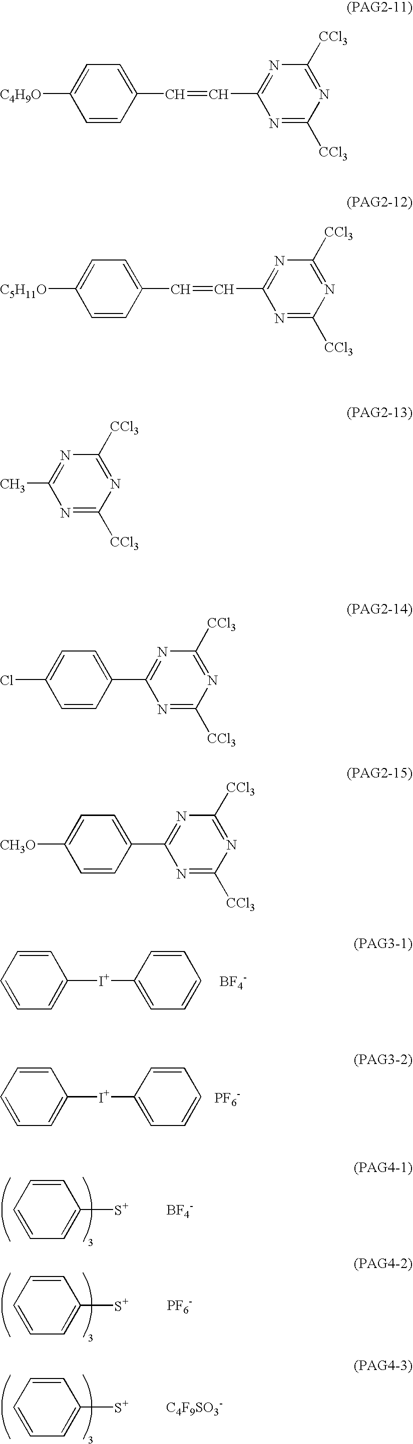

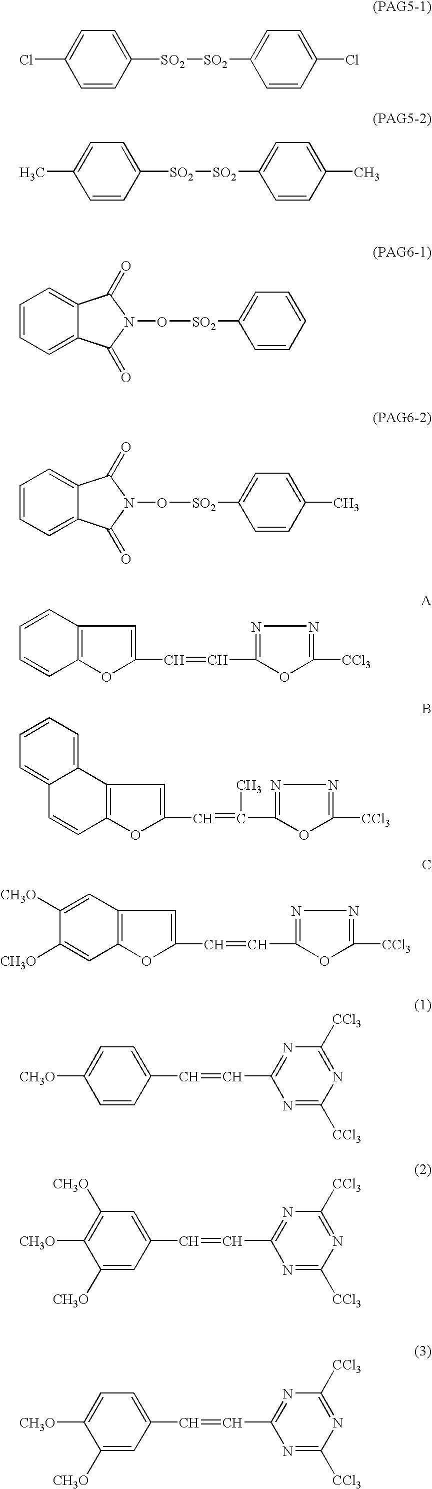

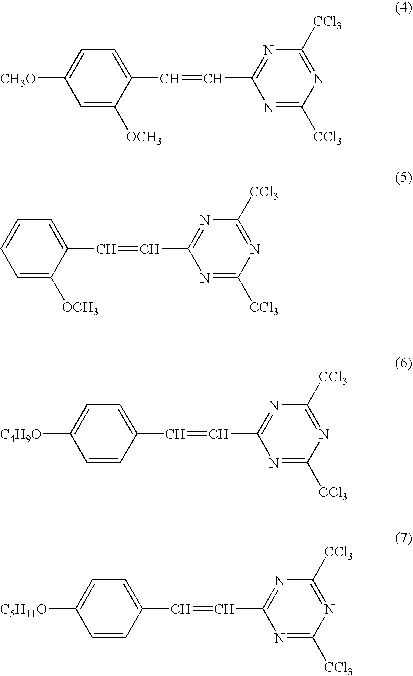

In the invention, acid generating agents described below can be employed.

For example, polymerization initiators disclosed in Japanese Patent O.P.I. Publication No. 2005-70211, radical generating compounds disclosed in Japanese Patent Publication No. 2002-537419, polymerization initiators disclosed in Japanese Patent O.P.I. Publication Nos. 2001-175006, 2002-278057, and 2003-5363, onium salts having two or more cation portions in the molecule disclosed in Japanese Patent O.P.I. Publication No. 2003-76010, N-nitroso amine compounds disclosed in Japanese Patent O.P.I. Publication No. 2001-133966, thermally radical generating compounds disclosed in Japanese Patent O.P.I. Publication No. 2001-343742, compounds of generating a radical or an acid by heat disclosed in Japanese Patent O.P.I. Publication No. 2002-6482, borate compounds disclosed in Japanese Patent O.P.I. Publication No. 2002-116539, compounds of generating a radical or an acid by heat disclosed in Japanese Patent O.P.I. Publication No. 2002-148790, photopolymerization initiators or thermal polymerization initiators each having a polymerizable unsaturated group disclosed in Japanese Patent O.P.I. Publication No. 2002-207293, onium salts having, as a counter ion, a divalent or more valent anion disclosed in Japanese Patent O.P.I. Publication No. 2002-268217, sulfonylsulfone compounds having a specific structure disclosed in Japanese Patent O.P.I. Publication No. 2002-328465, and thermally radical generating compounds disclosed in Japanese Patent O.P.I. Publication No. 2002-341519 can be used as necessary.

As the acid generating agent, a compound represented by the following formula (APA) is also preferred, in view of safelight property.

R¹—C(X)₂—C═O)—R² Formula (APA)

wherein R¹ represents a hydrogen atom, a bromine atom, a chlorine atom, an alkyl group, an aryl group, an acyl group, an alkylsulfonyl group, an arylsulfonyl group, an iminosulfonyl group or a cyano group; R² represents a hydrogen atom or a monovalent organic substituent, provided that R¹ and R² may combine with each other to form a ring; and X represents a bromine atom or a chlorine atom.

Among compounds represented by formula (APA), those wherein R¹ is a hydrogen atom, a bromine atom, a chlorine atom are preferred in view of sensitivity. The monovalent organic substituent of R² is not limited, as long as the compounds represented by formula (2) generate a radical on light exposure. Those compounds in which in formula (2), R² represents —O—R³ or —NR⁴—R³ (R³ represents a hydrogen atom or a monovalent organic substituent, and R⁴ represents a hydrogen atom or an alkyl group) are preferably employed. Among these, those compounds in which R¹ is a bromine atom or a chlorine atom are more preferably employed in view of sensitivity.

Of these compounds, a compound having at least one haloacetyl group selected from a tribromoacetyl group, a dibromoacetyl group, a trichloroacetyl group, and a dichloroacetyl group is preferred.

In view of synthesis, a compound having at least one haloacetoxy group selected from a tribromoacetoxy group, a dibromoacetoxy group, a trichloroacetoxy group, and a dichloroacetoxy group, which is obtained by reacting a monohydric or polyhydric alcohol with a corresponding acid chloride, or a compound having at least one haloacetylamino group selected from a tribromoacetylamino group, a dibromoacetylamino group, a trichloroacetylamino group, and a dichloroacetylamino group, which is obtained by reacting a primary monoamine or primary polyamine with a corresponding acid chloride is especially preferred. Compounds having two or more of each of the haloacetyl group, haloacetoxy group, and haloacetylamino group are preferably used. These compounds can be easily synthesized by conventional esterification or amidation.

Typical synthesis method of the compound represented by formula (APA) is one in which alcohols, phenols or amines are esterified or amidated with acid chlorides such as tribromoacetic acid chloride, diibromoacetic acid chloride, trichlorooacetic acid chloride, or dichloroacetic acid chloride.

The alcohols, phenols or amines used above are arbitrary, and examples thereof include monohydric alcohols such as ethanol, 2-butanol, and 1-adamantanol; polyhydric alcohols such as diethylene glycol, trimethylol propane, and dipentaerythritol; phenols such as phenol, pyrogallol, and naphthol; monoamines such as morpholine, aniline, and 1-aminodecane; and polyamines such as 2,2-dimethylpropylene-diamine, and 1,12-dodecanediamine.

Preferred examples of the compounds represented by formula (APA) will be listed below.

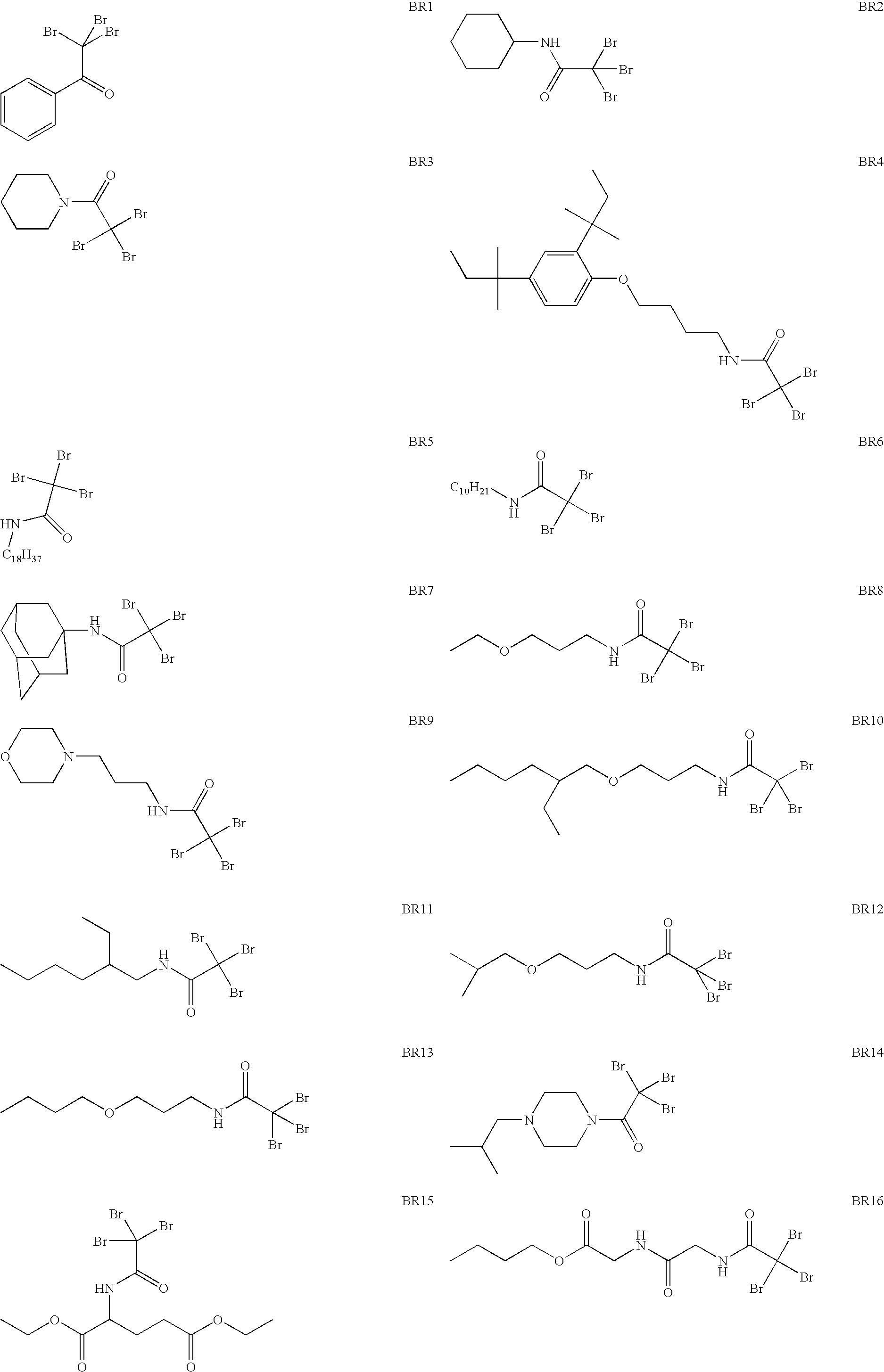

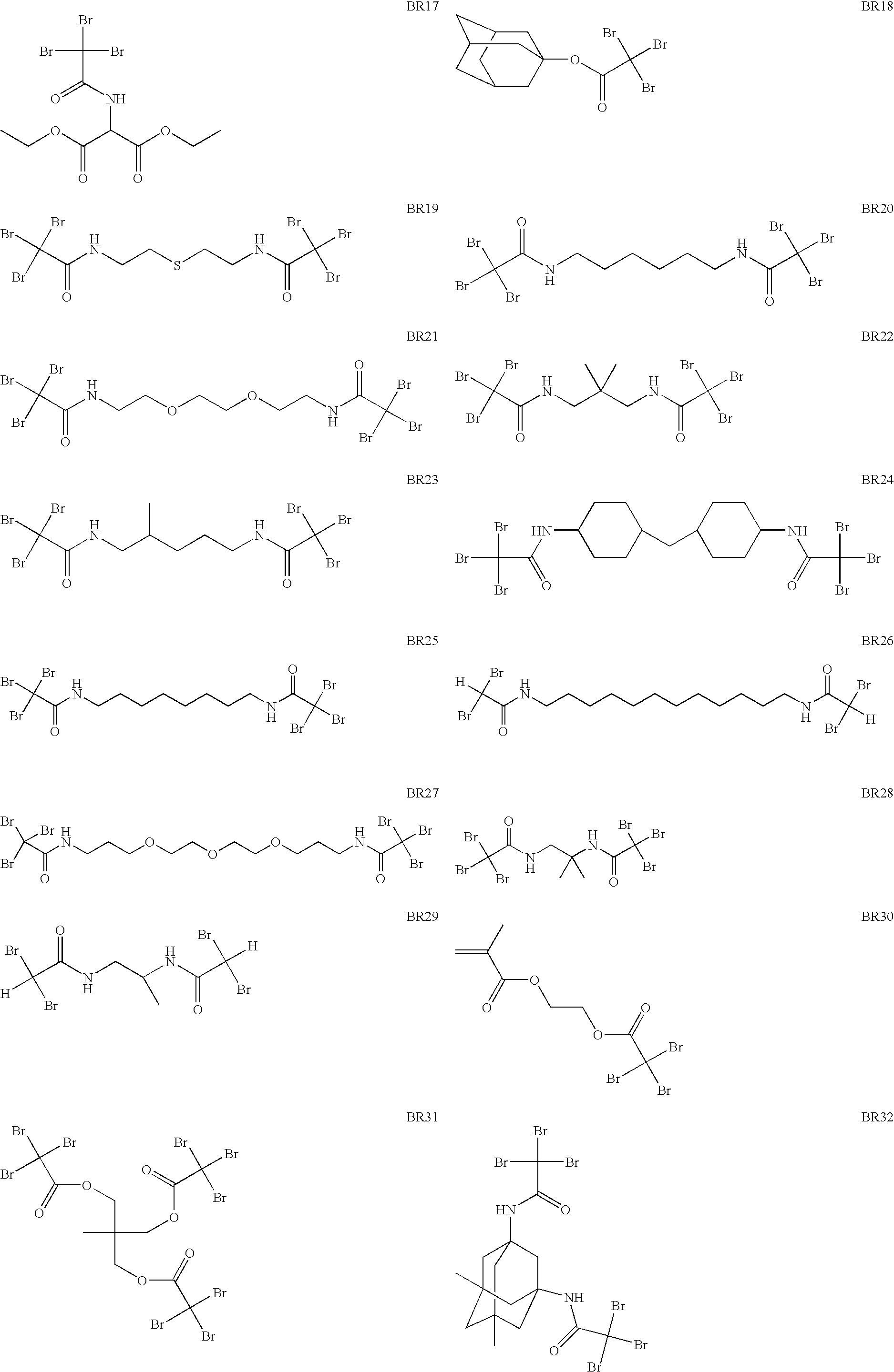

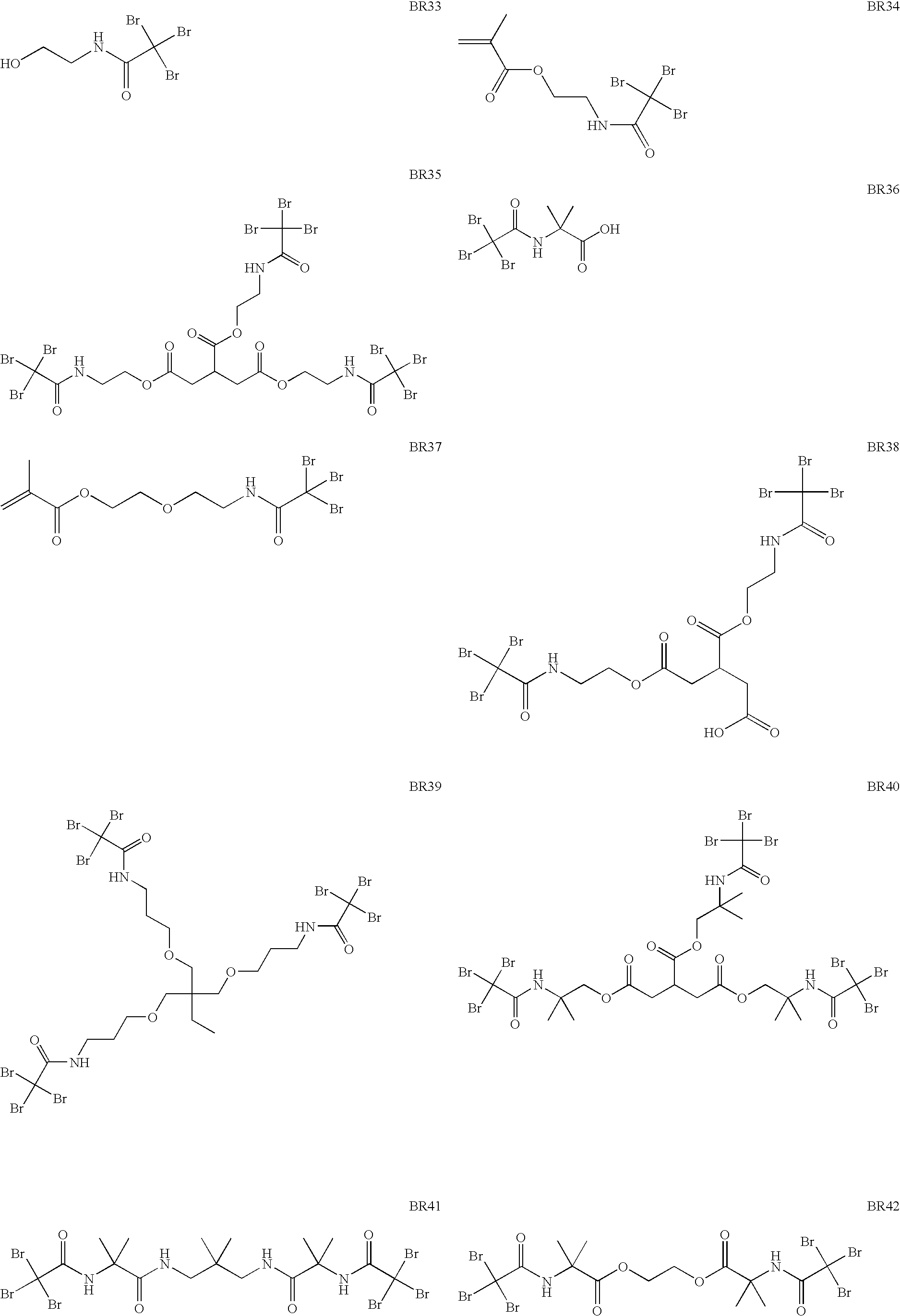

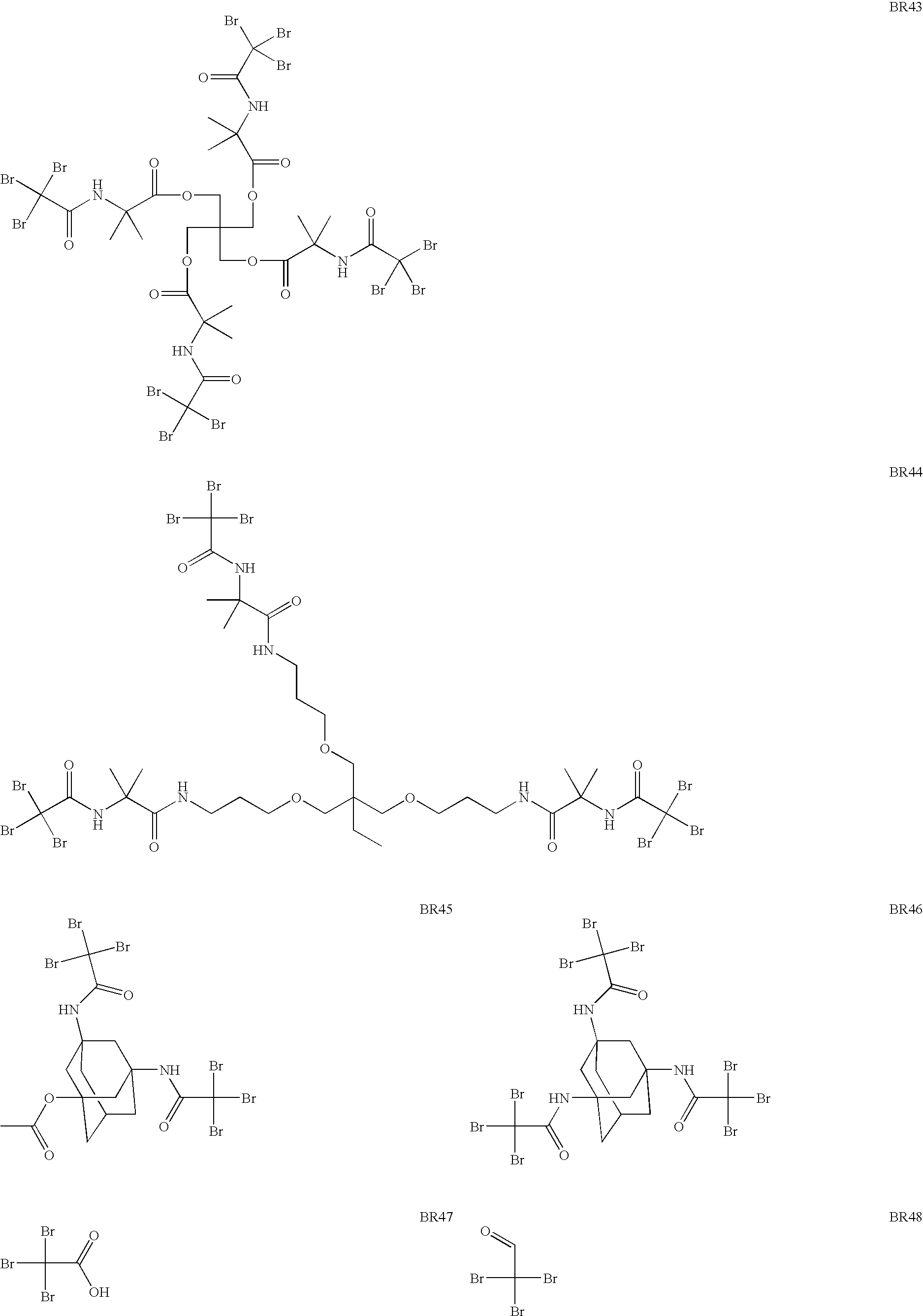

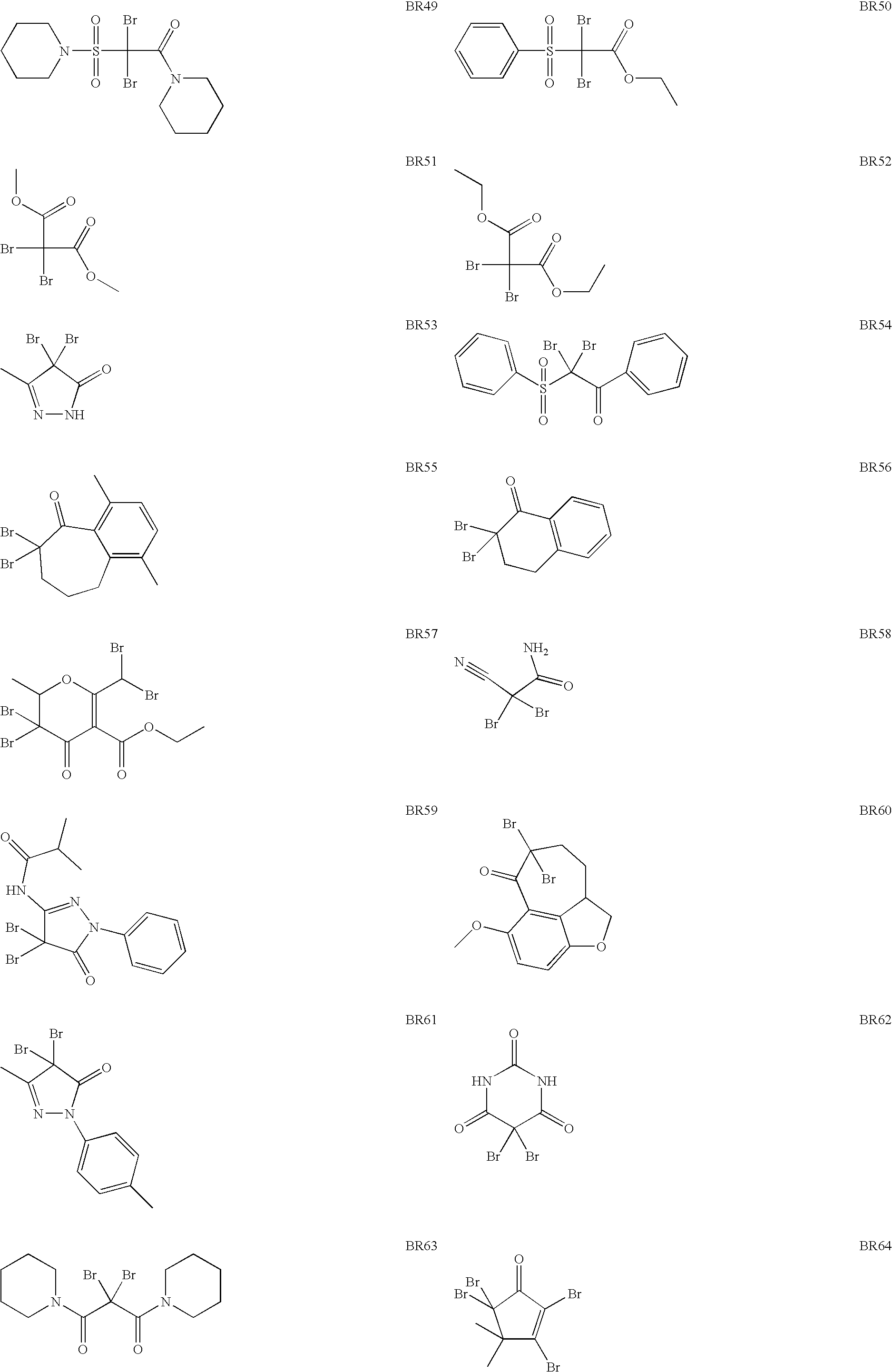

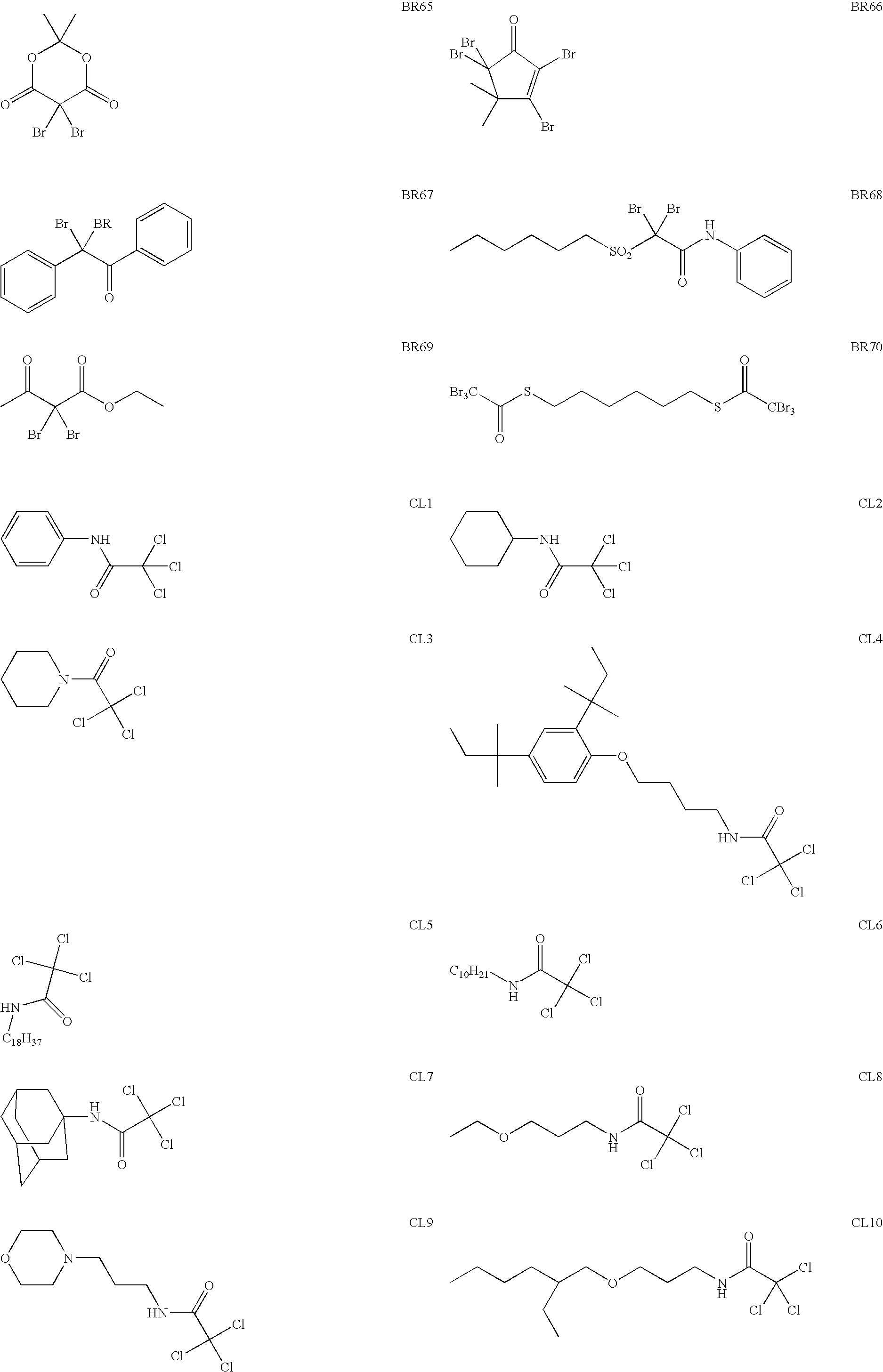

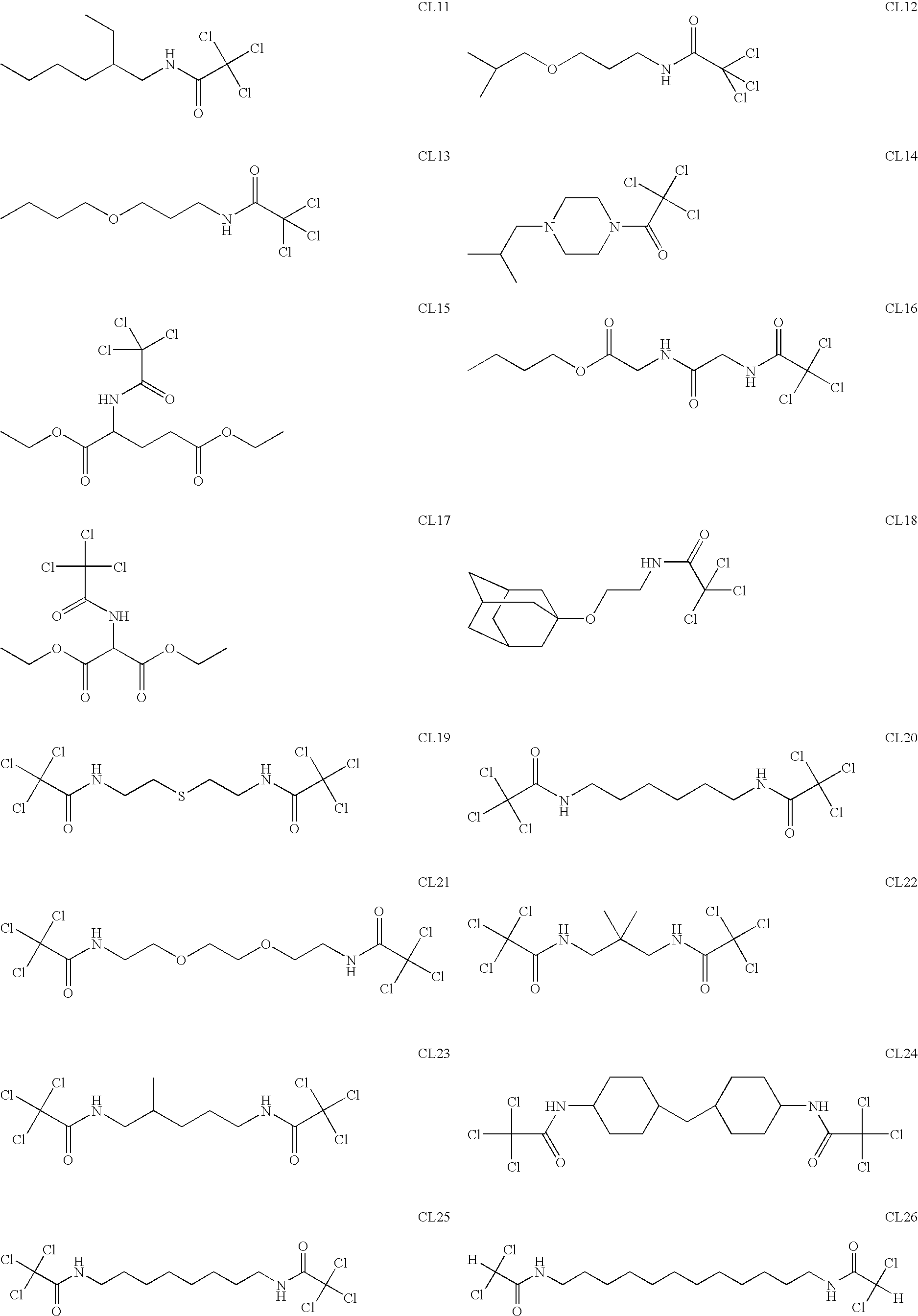

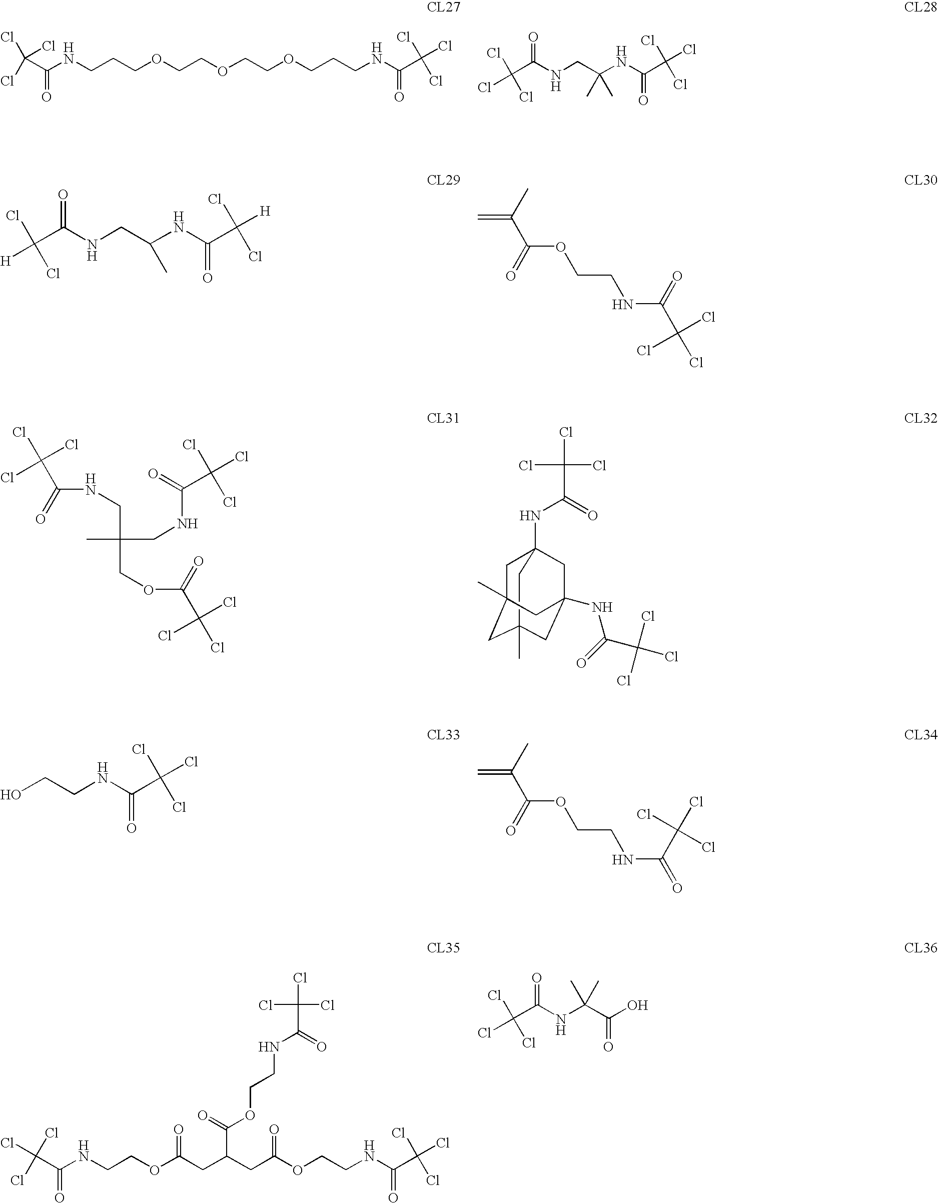

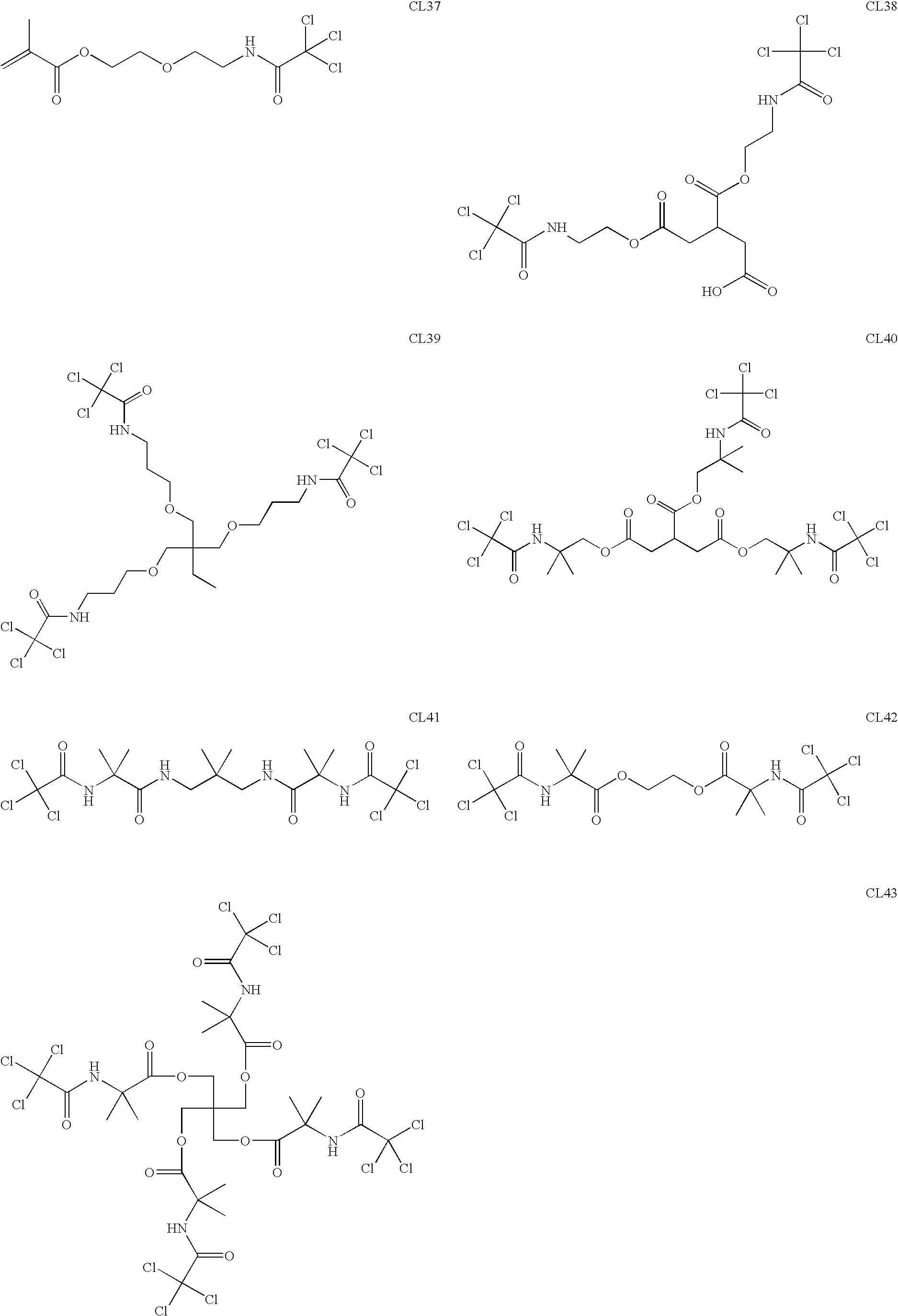

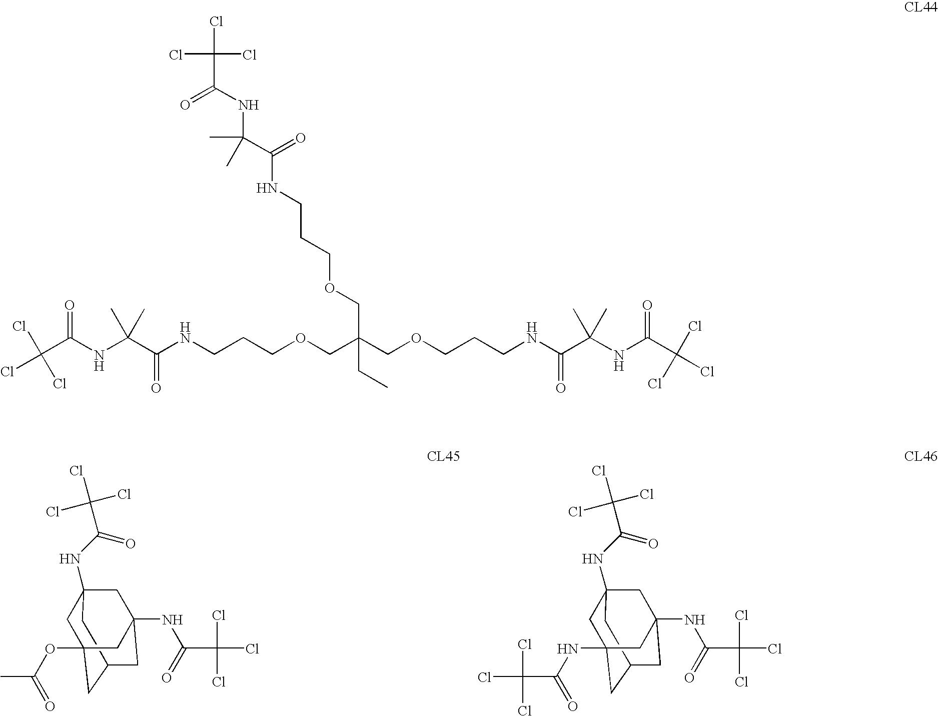

The acid generating agent content of the light sensitive layer is ordinarily from 0.1 to 30% by weight, and preferably from 1 to 15% by weight, based on the total solid content of the lower layer, in view of development latitude and safelight property.

When two layers, upper and lower light sensitive layers are used, the compound represented by formula (ADC) or the compound represented by formula (APA) is preferably contained in the lower light sensitive layer, in view of sensitivity and development latitude. It is preferred that the lower light sensitive layer contains at least one of the compound represented by formula (ADC) and the compound represented by formula (APA).

The sulfonium salt represented by formula (SAPA) above is used as an acid generating agent, providing good scratch resistance. When two layers, upper and lower light sensitive layers are used, the compound represented by formula (SAPA) is preferably contained in the upper light sensitive layer, in view of good dissolution resistance.

In formula (SAPA), R₁ through R₃ independently represent a hydrogen atom or a substituent, provided that R₁ through R₃ are not simultaneously hydrogens; and X⁻ represents an anion.

The substituent represented by R₁ through R₃ is preferably an alkyl group such as a methyl group, an ethyl group, a propyl group, an isopropyl group, a butyl group, an isobutyl group, a t-butyl group, a pentyl group or a hexyl group; an alkoxy group such as a methoxy group, an ethoxy group, a propoxy group, a butoxy group, a hexyloxy group, a decyloxy group or a dodecyloxy group; a carbonyl group such as an acetoxy group, propionyloxy group, a decylcarbonyloxy group, a dodecylcarbonyloxy group, a methoxycarbonyl group, an ethoxycarbonyl group or a benzoyloxy group; a phenylthio group; a halogen atom such as fluorine, chlorine, bromine or iodine; a cyano group, a nitro group or a hydroxy group.

Examples of the anion represented by X⁻ include a halogen ion such as F⁻, Cl⁻, Br⁻ or I⁻; and an anion such as B(C₆F₅)₄⁻, R₁₄COO⁻, R₁₅SO₃⁻, SbF₆⁻, AsF₆⁻, PF₆⁻ or BF₄⁻, in which R₁₄ and R₁₅ independently represent an alkyl group such as a methyl group, an ethyl group, a propyl group or a butyl group; an alkyl group having, as a substituent, a halogen atom such as fluorine, chlorine, bromine or iodine, a nitro group, a cyano group, or an alkoxy group such as a methoxy group or an ethoxy group; or a phenyl group. Among these, B(C₆F₅)₄⁻ or PF₆⁻ is preferred in view of safety.

Typical examples of the sulfonium salt represented by formula (SAPA) will be listed below, but the invention is not limited thereto.

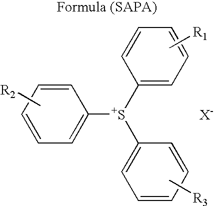

| Exemplified | | | | |
|---|---|---|---|---|
| Compound | R₁ | R₂ | R₃ | X⁻ |
| 1 | —OCH₃ | —OCH₃ | —CF₃ | B(C₆F₅)₄⁻ |
| 2 | —OCH₃ | —OCH₃ | —CF₃ | SbF₆⁻ |
| 3 | —OCH₃ | —OCH₃ | —CF₃ | PF₆⁻ |
| 4 | —OCH₃ | —OCH₃ | —COF₃ | B(C₆F₅)₄⁻ |
| 5 | —OCH₃ | —OCH₃ | —COF₃ | SbF₆⁻ |
| 6 | —OCH₃ | —OCH₃ | —COF₃ | PF₆⁻ |
| 7 | —CH═CH— | —CH═CH— | —COF₃ | B(C₆F₅)₄⁻ |
| 8 | —CH═CH— | —CH═CH— | —COF₃ | SbF₆⁻ |
| 9 | —CH═CH— | —CH═CH— | —COF₃ | PF₆⁻ |
| 10 | —OCH₃ | —CF₃ | —CF₃ | B(C₆F₅)₄⁻ |
| 11 | —OCH₃ | —CF₃ | —CF₃ | SbF₆⁻ |
| 12 | —OCH₃ | —CF₃ | —CF₃ | PF₆⁻ |
| 13 | —CF₃ | —CF₃ | —CF₃ | B(C₆F₅)₄⁻ |
| 14 | —CF₃ | —CF₃ | —CF₃ | SbF₆⁻ |
| 15 | —CF₃ | —CF₃ | —CF₃ | PF₆⁻ |
| 16 | -t-Butyl | -t-Butyl | —CF₃ | B(C₆F₅)₄⁻ |
| 17 | -t-Butyl | -t-Butyl | —CF₃ | SbF₆⁻ |
| 18 | -t-Butyl | -t-Butyl | —CF₃ | PF₆⁻ |
| 19 | -i-Propyl | -i-Propyl | —CF₃ | B(C₆F₅)₄⁻ |
| 20 | -i-Propyl | -i-Propyl | —CF₃ | SbF₆⁻ |
| 21 | -i-Propyl | -i-Propyl | —CF₃ | PF₆⁻ |

The content of the sulfonium salt represented by formula (SAPA) in the light sensitive layer is preferably from 0.1 to 30% by weight, and more preferably from 1 to 15% by weight, in view of development latitude and scratch resistance.

The acid generating agent may be used singly or as an admixture of two or more kinds thereof. The acid generating agent may be used in the upper light sensitive layer as long as safelight property is not lowered.

When there are two light sensitive layers upper and lower light sensitive layers, it is preferred that the upper light sensitive layer contains at least one of the compound represented by formula (APA), the compound represented by formula (ASAP), and the acryl resin having a fluoroalkyl group.

### (Visualizing Agent)

The light sensitive layer in the invention preferably contains colorants as a visualizing agent. As the colorants, there are mentioned oil-soluble dyes and basic dyes, including the salt-forming organic dyes.

Those changing the color by reaction with a free radical or an acid are preferably used. The term “changing the color” means changing from colorless to color, from color to colorless, or from the color to different color. Preferred dyes are those changing the color by forming salts with an acid.

Examples of the dyes changing from color to colorless or from the color to different color include triphenyl methane, diphenyl methane, oxazine, xanthene, iminonaphthoquinone, azomethine or anthraquinone dyes represented by Victoria pure blue BOH (product of Hodogaya Kagaku), Oil blue #603 (product of Orient Kagaku kogyo), Patent pure blue (product of Sumitomo Mikuni Kagaku Co., Ltd.), Crystal violet, Brilliant green, Ethyl violet, Methyl violet, Methyl green, Erythrosine B, Basic fuchsine, Marachite green, Oil red, m-cresol purple, Rhodamine B, Auramine, 4-p-diethylaminophenyliminonaphthoquinone or cyano-p-diethylaminophenylacetoanilide.

Examples of the dyes changing from colorless to color include leuco dyes and primary or secondary amines represented by triphenylamine, diphenylamine, o-chloroaniline, 1,2,3-triphenylguanidine, diaminodiphenylmethane, p,p′-bis-dimethylaminodiphenylamine, 1,2-dianilinoethylene, p,p′,p″-tris-dimethylaminotriphenylmethane, p,p′-bis-dimethylaminodiphenylmethylimine, p,p′,p″-triamino-o-methyltriphenylmethane, p,p′-bis-dimethylaminodiphenyl-4-anilinonaphthylmethane, and p,p′,p″-triaminotriphenylmethane. These dyes may be used alone or as an admixture of two or more kinds thereof. Especially preferred dyes are Victoria pure blue BOH (product of Hodogaya Kagaku) and Oil blue #603.

When two light sensitive layers, upper and lower light sensitive layers are used, the colorant used in the upper layer is preferably a dye having maximum absorption in the wavelength regions of less than 800 nm, and preferably less than 600 nm. When the acid generating agent is used in the lower layer, the dye in the upper layer minimizes transmission of visible light, resulting in preferable results of improving safelight property. Such a dye makes it possible to use the acid generating agent unfavorable to safelight property in the lower layer.

The content of the dye is preferably 0.01 to 10% by weight, and more preferably from 0.1 to 3% by weight, based on the solid weight of layer (the upper or lower light sensitive layer) containing the dye.

### (Development Restrainer)

The light sensitive layer in the invention can contain various dissolution restrainers in order to adjust solubility. As the dissolution restrainers, there are disulfone compounds or sulfone compounds disclosed in Japanese Patent O.P.I. Publication No. 11-119418. As the development restrainers, 4,4′-bishydroxyphenylsulfone is preferably used. The content of the dissolution restrainers is preferably from 0.05 to 20% by weight, and more preferably from 0.5 to 10% by weight, based on the weight of layer containing them.

In the invention, development restrainers can be used in order to increase dissolution restraint function. The development restrainers are not specifically limited as long as they are ones which are capable of lowering the solubility at exposed portions by their interaction with the alkali soluble resin described above and of being dissolved in a developer at exposed portions due to weak interaction with the alkali soluble resin. As the restrainers, quaternary ammonium salts or polyethylene glycol derivatives are preferably used.

Examples of the quaternary ammonium salts include tetraalkylammonium salts, trialkylarylammonium salts, dialkyldiarylammonium salts, alkyltriarylammonium salts, tetraarylammonium salts, cyclic ammonium salts and bicyclic ammonium salts, but are not specifically limited thereto.

The content of the quaternary ammonium salts in the upper layer is preferably from 0.1 to 50% by weight, and more preferably from 1 to 30% by weight, based on the weight of the layer. The content range above is preferred in view of development restraint and layer forming property.

### (Sensitivity Improving Agent)

The light sensitive layer in the invention can contain a sensitivity improving agent such as cyclic acid anhydrides, phenols, or organic acids in order to improve sensitivity. When two light sensitive layers upper and lower light sensitive layers are used, the sensitivity improving agent is preferably contained in the lower light sensitive layer, which provides good dissolution of the light sensitive layer, resulting in no residual layer, no contamination at no-image portions and good developability at shadow portions.

As the cyclic acid anhydrides, there are phthalic anhydride, tetrahydrophthalic anhydride, hexahydrophthalic anhydride, 3,6-endoxy-Δ4-tetrahydrophthalic anhydride, tetrachlorophthalic anhydride, maleic anhydride, chloromaleic anhydride, α-phenylmaleic anhydride, succinic anhydride, pyromellitic anhydride disclosed in U.S. Pat. No. 4,115,128.

As the phenols, there are bisphenol A, p-nitrophenol, p-ethoxyphenol, 2,4,4′-trihydroxybenzophenone, 2,3,4-trihydroxybenzophenone, 4-hydroxybenzophenone, 4,4′,4″-trihydroxytriphenylmethane, and 4,4′,3″,4″-tetrahydroxy-3,5,3′,5′-tetramethylphenylmethane.

As the organic acids, there are sulfonic acids, sulfinic acids, alkyl sulfates, phosphonic acids, phosphates and carboxylic acids disclosed in Japanese Patent O.P.I. Publication Nos. 60-88942 and 2-96744. Examples thereof include p-toluene sulfonic acid, dodecylbenzene sulfonic acid, naphthalene sulfonic acid, p-toluene sulfinic acid, ethyl sulfuric acid, phenyl phosphonic acid, phenyl phosphinic acid, phenyl phosphate, diphenyl phosphate, benzoic acid, isophthalic acid, adipic acid, p-toluic acid, 3,4-dimethoxybenzoic acid, phthalic acid, telephthalic acid, 4-cyclohexene-1,2-dicarboxylic acid, erucic acid, lauric acid, n-undecylic acid, and ascorbic acid.

The content of the cyclic acid anhydrides, phenols or organic acids is preferably from 0.05 to 20% by weight, more preferably from 0.1 to 15% by weight, and still more preferably from 0.1 to 10% by weight, based on the weight of the layer containing them.

Alcohols having in the α-position at least one trifluoromethyl group disclosed in Japanese Patent O.P.I. Publication No. 2005-99298 can be used. This compound increases alkali solubility since acidity of the hydroxy group in the α-position is increased due to electron drawing effect of the trifluoromethyl group.

### (Surfactants)

In the invention, the upper and/or lower layer can contain non-ionic surfactants as disclosed in Japanese Patent O.P.I. Publication Nos. 62-251740 and 3-208514, amphoteric surfactants as disclosed in Japanese Patent O.P.I. Publication Nos. 59-121044 and 4-13149, siloxane compounds disclosed in EP 950517, or fluorine-containing copolymers disclosed in Japanese Patent O.P.I. Publication Nos. 62-170950, 11-288093, and 2003-57820, in order to improve the coatability and increase stability under various developing conditions.

Examples of the non-ionic surfactants include sorbitan tristearate, sorbitan monopalmitate, sorbitan trioleate, stearic acid monoglyceride, polyoxyethylene sorbitan monooleate, and polyoxyethylene nonylphenyl ether. Examples of the amphoteric surfactants include alkyldi(aminoethyl)-glycine, alkylpoly(aminoethyl)glycine hydrochloride, 2-alkyl-N-carboxyethyl-N-hydroxyethylimidazolinium betaine, and N-tetradecyl-N,N-betaine type compounds (for example, trade name: AMOGEN K produced by DAIICHI KOGYO CO., LTD.).

Examples of the siloxane compounds include a block copolymer of dimethyl polysiloxane and polyalkylene oxide, for example, polyalkylene oxide-modified silicons such as DBE-224, DBE-621, DBE-712, DBE-732, and DBE-534, each produced by Chisso Co., Ltd., and Tego Glide 100 produced by Tego Co., Ltd.

The surfactant content of the upper or lower layer is preferably from 0.01 to 15% by weight, and more preferably from 0.1 to 5% by weight.

### (Aluminum Support)

In the invention, a support comprised of metals or resins can be employed. As the support, an aluminum plate is preferred. The aluminum plate may be a pure aluminum plate or an aluminum alloy plate.

As the aluminum alloy, there can be used various ones including an alloy of aluminum and a metal such as silicon, copper, manganese, magnesium, chromium, zinc, lead, bismuth, nickel, titanium, sodium or iron. An aluminum plate can be used which is manufactured according to various calender procedures. A regenerated aluminum plate can also used which is obtained by calendering ingot of aluminum material such as aluminum scrap or recycled aluminum.

It is preferable that the aluminum plate is subjected to degreasing treatment for removing rolling oil prior to surface roughening (graining). The degreasing treatments include degreasing treatment employing solvents such as trichlene and thinner, and an emulsion degreasing treatment employing an emulsion such as kerosene or triethanol. It is also possible to use an aqueous alkali solution such as caustic soda for the degreasing treatment. When an aqueous alkali solution such as caustic soda is used for the degreasing treatment, it is possible to remove soils and an oxidized film which can not be removed by the above-mentioned degreasing treatment alone. When an aqueous alkali solution such as caustic soda is used for the degreasing treatment, the resulting support is preferably subjected to desmut treatment in an aqueous solution of an acid such as phosphoric acid, nitric acid, sulfuric acid, chromic acid, or a mixture thereof, since smut is produced on the surface of the support.

Subsequently, surface roughening is carried out. The surface roughening methods include a mechanical surface roughening method and an electrolytic surface roughening method electrolytically etching the support surface. In the invention, electrolytic surface roughening is preferably carried out in an acidic electrolyte solution containing hydrochloric acid. Prior to the electrolytic surface roughening, the aluminum plate may be subjected to mechanical surface roughening or electrolytic surface roughening in an acidic electrolyte solution containing nitric acid.

Though there is no restriction for the mechanical surface roughening method, a brushing roughening method and a honing roughening method are preferable. The brushing roughening method is carried out by rubbing the surface of the support with a rotating brush with a brush hair with a diameter of 0.2 to 0.8 mm, while supplying slurry in which volcanic ash particles with a particle size of 10 to 100 μm are dispersed in water to the surface of the support. The honing roughening method is carried out by ejecting obliquely slurry with pressure applied from nozzles to the surface of the support, the slurry containing volcanic ash particles with a particle size of 10 to 100 μm dispersed in water. A surface roughening can be also carried out by laminating a support surface with a sheet on the surface of which abrading particles with a particle size of from 10 to 100 μm was coated at intervals of 100 to 200 μm and at a density of 2.5×10³ to 10×10³/cm², and applying pressure to the sheet to transfer the roughened pattern of the sheet and roughen the surface of the support.

After the support has been roughened mechanically, it is preferably dipped in an acid or an aqueous alkali solution in order to remove abrasives and aluminum dust, etc. which have been embedded in the surface of the support. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, an aqueous alkali solution of for example, sodium hydroxide is preferably used. The dissolution amount of aluminum in the support surface is preferably 0.5 to 5 g/m². After the support has been dipped in the aqueous alkali solution, it is preferable for the support to be dipped in an acid such as phosphoric acid, nitric acid, sulfuric acid and chromic acid, or in a mixed acid thereof, for neutralization.

When the plate is electrolytically surface roughened by using an electrolytic solution of nitric acid, voltage applied is generally from 1 to 50 V, and preferably from 5 to 30 V. The current density used can be selected from the range from 10 to 200 A/dm², and is preferably from 20 to 100 A/dm². The quantity of electricity can be selected from the range of from 100 to 5000 C/dm², and is preferably 100 to 2000 C/dm². The temperature during the electrolytically surface roughening may be in the range of from 10 to 50° C., and is preferably from 15 to 45° C. The nitric acid concentration in the electrolytic solution is preferably from 0.1% by weight to 5% by weight. The electrolytic solution can contain nitrates, chlorides, amines, aldehydes, phosphoric acid, chromic acid, boric acid, acetic acid, oxalic acid or an aluminum ion, as necessary.

After the electrolytically surface roughening using an electrolytic solution of nitric acid, the plate is preferably dipped in an acid or an aqueous alkali solution in order to remove aluminum dust, etc. produced in the surface of the plate. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, the aqueous alkali solution is preferably used. The dissolution amount of aluminum in the plate surface is preferably 0.5 to 5 g/m². After the support has been dipped in the aqueous alkali solution, it is preferable for the plate to be dipped in an acid such as phosphoric acid, nitric acid, sulfuric acid and chromic acid, or in a mixed acid thereof, for neutralization.

When the plate is electrolytically surface roughened by using an electrolytic solution of hydrochloric acid, the hydrochloric acid concentration of the electrolytic solution is from 5 to 20 g/liter, and preferably from 6 to 15 g/liter. The current density used is from 15 to 120 A/dm², and is preferably from 20 to 90 A/dm². The quantity of electricity is from 400 to 2000 C/dm², and is preferably 500 to 1200 C/dm². The frequency is preferably from 40 to 150 Hz. The temperature during the electrolytically surface roughening may be in the range of from 10 to 50° C., and is preferably from 15 to 45° C. The electrolytic solution can contain nitrates, chlorides, amines, aldehydes, phosphoric acid, chromic acid, boric acid, acetic acid, oxalic acid or an aluminum ion, as necessary.

After the electrolytically surface roughening using an electrolytic solution of hydrochloric acid, the plate is preferably dipped in an acid or an aqueous alkali solution in order to remove aluminum dust, etc. produced in the surface of the support. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, the aqueous alkali solution is preferably used. The dissolution amount of aluminum in the support surface is preferably 0.5 to 5 g/m². After the support has been dipped in the aqueous alkali solution, it is preferable for the support to be dipped in an acid such as phosphoric acid, nitric acid, sulfuric acid and chromic acid, or in a mixed acid thereof, for neutralization.

The average (arithmetic mean) surface roughness Ra on the light sensitive layer side of the resulting aluminum plate is preferably from 0.4 to 0.6 μm. The surface roughness can be adjusted according to a hydrochloric acid concentration, current density or quantity of electricity during electrolytic surface roughening.

After the surface roughening, anodizing treatment is carried out to form an anodization film on the aluminum plate. In the anodizing treatment, an electrolytic solution containing sulfuric acid or phosphoric acid is preferably used. The sulfuric acid concentration in the electrolytic solution is preferably from 5 to 50% by weight, and more preferably from 10 to 35% by weight. The temperature is preferably from 10 to 50° C. the voltage used is preferably not less than 18V, and more preferably not less than 20V. The current density is preferably from 1 to 30 A/dm². The quantity of electricity is preferably from 200 to 600 C/dm².

The amount of the formed anodization film is preferably from 2 to 6 g/m², and more preferably from 3 to 5 g/m². The amount of the formed anodization film can be obtained from the weight difference between the aluminum plates before and after dissolution of the anodization film. The anodization film of the aluminum plate is dissolved employing for example, an aqueous phosphoric acid chromic acid solution which is prepared by dissolving 35 ml of 85% by weight phosphoric acid and 20 g of chromium (IV) oxide in 1 liter of water. Micro pores are formed in the anodization film, and the density of the micro pores is preferably from 400 to 700/μm², and more preferably from 400 to 600/μm².

The aluminum plate, which has been subjected to anodizing treatment, is optionally subjected to sealing treatment. For the sealing treatment, it is possible to use known methods using hot water, boiling water, steam, a sodium silicate solution, an aqueous dichromate solution, a nitrite solution and an ammonium acetate solution.

### <Hydrophilization Processing>

After the above treatments, the resulting aluminum plate is preferably subjected to hydrophilization processing, in view of chemical resistance or sensitivity.

The hydrophilization processing method is not specifically limited, but there is a method of undercoating, on the resulting aluminum plate, a water soluble resin such as polyvinyl phosphonic acid, polyvinyl alcohol or its derivatives, carboxymethylcellulose, dextrin or gum arabic; phosphonic acids with an amino group such as 2-aminoethylphosphonic acid; a polymer or copolymer having a sulfonic acid in the side chain; polyacrylic acid; a water soluble metal salt such as zinc borate; a yellow dye; an amine salt; and so on.

The sol-gel treatment support disclosed in Japanese Patent O.P.I. Publication No. 5-304358, whose surface is covalent-bonded to a functional group capable of causing addition reaction by radicals, is suitably used. It is preferred that the support is subjected to hydrophilization processing employing polyvinyl phosphonic acid.

As the hydrophilization processing method, there is for example, a coating method, a spraying method or a dipping method. The solution used in the dipping method is preferably an aqueous 0.05 to 3% polyvinyl phosphonic acid solution. The dipping method is preferred in that the facility is cheap. The temperature is preferably from 20 to 90° C., and the processing time is preferably from 10 to 180 seconds. After the processing, excessive polyvinyl phosphonic acid is removed from the support surface preferably through washing or squeegeeing. After that, drying is preferably carried out.

The drying temperature is preferably from 40 to 180° C., and more preferably from 50 to 150° C. The drying is preferred in increasing adhesion of the hydrophilization processing layer to an under layer, improving insulating function of the hydrophilization processing layer, and increasing chemical resistance and sensitivity.

The dry thickness of the hydrophilization processing layer is preferably from 0.002 to 0.1 μm, and more preferably from 0.005 to 0.05 μm, in view of adhesion to an under layer support, heat insulating property, and sensitivity.

Thus, an aluminum support is obtained.

### (Back Coat Layer)

The aluminum support of the planographic printing plate material of the invention preferably has an anodization film on the surface. A back coat layer may be provided on a rear surface of the aluminum support (the surface of the aluminum support opposite light sensitive layer) in order to minimize dissolution of the anodization film during alkali development of the planographic printing plate material. The back coat layer is preferred, since it minimizes sludge produced during development, shorten developer exchange period, and lessens supply amount of developer replenisher. The back coat layer preferably contains (a) metal oxides obtained from hydrolysis or polycondensation of organic or inorganic metal compounds, (b) colloidal silica sol and (c) an organic polymeric compound.

Examples of the metal oxides used in the back coat layer include silica (silicon oxide), titanium oxide, boron oxide, aluminum oxide, zirconium oxide, and their composites. The metal oxides used in the back coat layer is formed by coating a sol-gel reaction solution on the rear surface of the aluminum support and drying it, the sol-gel reaction solution being obtained by hydrolyzing and condensing organic or inorganic metal compounds in water and an organic solvent in the presence of a catalyst such as an acid or an alkali. As the organic or inorganic metal compounds used herein, there are metal alkoxide, metal acetylacetonate, metal acetate, metal oxalate, metal nitrate, metal sulfate, metal carbonate, metal oxychloride, metal chloride, and their oligomers obtained by partially hydrolyzing and condensing these metal compounds.

### (Coating and Drying)

The light sensitive layer of the planographic printing plate material of the invention are ordinarily formed by dissolving the components described above in an appropriate coating solvent to obtain a respective coating solution and coating the coating solution on an appropriate support in order. Coating solvents will be shown below. These solvents may be used singly or as an admixture of two or more kinds thereof.

### (Coating Solvents)

As the coating solvents, there are, for example, n-propanol, isopropyl alcohol, n-butanol, sec-butanol, isobutanol, 2-methyl-1-butanol, 3-methyl-1-butanol, 2-methyl-2-butanol, 2-ethyl-1-butanol, 1-pentanol, 2-pentanol, 3-pentanol, n-hexanol, 2-hexanol, cyclohexanol, methylcyclohexanol, 1-heptanol, 2-heptanol, 3-heptanol, 1-octanol, 4-methl-2-pentanol, 2-hexylalcohol, benzyl alcohol, ethylene glycol, diethylene glycol, triethylene glycol, tetraethylene glycol, 1,3-propane diol, 1,5-pentane glycol, dimethyl triglycol, furfuryl alcohol, hexylene glycol, hexyl ether, 3-methoxy-1-methylbutanol, butyl phenyl ether, ethylene glycol monoacetate, propylene glycol monomethylether, propylene glycol monoethylether, propylene glycol monopropylether, propylene glycol monobutylether, propylene glycol phenylether, dipropylene glycol monomethylether, dipropylene glycol monoethylether, dipropylene glycol monopropylether, dipropylene glycol monombutylether, tripropylene glycol monomethylether, methyl carbitol, ethyl carbitol, ethyl carbitol acetate, butyl carbitol, triethylene glycol monomethylether, triethylene glycol monoethylether, tetraethylene glycol dimethylether, diacetone alcohol, acetophenone, cyclohexanone, methyl cyclohexanone, acetonylacetone, isophorone, methyl lactate, ethyl lactate, butyl lactate, propylene carbonate, phenyl acetate, sec-butyl acetate, cyclohexyl acetate, diethyl oxalate, methyl benzoate, ethyl benzoate, γ-butyrolactone, 3-methoxy-1-butanol, 4-methoxy-1-butanol, 3-ethoxy-1-butanol, 3-methoxy-3-methyl-1-butanol, 3-methoxy-3-ethyl-1-pentanol, 4-ethoxy-1-pentanol, 5-methoxy-1-hexanol, 3-hydroxy-2-butanone, 4-hydroxy-2-butanone, 4-hydroxy -2-pentanone, 5-hydroxy-2-pentanone, 4-hydroxy-3-pentanone, 6-hydroxy-2-pentanone, 6-hydroxy-2-hexanone, 3-methyl-3-hydroxy-2-pentanone, methyl cellosolve (MC), and ethyl cellosolve (EC).

Regarding a coating solvent for the upper or lower layer, the coating solvent for the upper layer is preferably different in solvency to an alkali soluble resin from that for the lower layer. When an upper layer coating solution is coated on a lower layer surface, employing, as a coating solvent for the upper layer, a solvent dissolving the alkali soluble resin of the lower layer, the upper layer is mixed with the lower layer at the interface of the two layers, and the extreme cases of the mixing form a uniform single layer. Accordingly, such mixing is undesirable, since it may not show the effects of the invention that the two separate layers in the invention, i.e., the upper and lower layers provide. A solvent used in the upper thermosensitive layer coating solution is preferably a poor solvent of the alkali soluble resin contained in the lower layer.

In order to prevent mixing of the upper and lower layers, there are a method in which air is blown onto the coated surface with high pressure from slit nozzles arranged at right angle to the running direction of web, a method in which heat is supplied as conductive heat onto the rear surface through a heat roll inside which a heated medium such as vapor is supplied, and their combination, whereby a second coated layer coated on a first coated layer is rapidly dried.

As a method for mixing the two layers to the degree that the effects of the invention is produced, there is a method employing the solvency difference as described above of the coating solvents or a method rapidly drying the second coated layer coated on the first coated layer, both of which can adjust the degree.

The coating solution for the upper or lower light sensitive layer (hereinafter also referred to as light sensitive layer coating solution) has a total solid content (including additives) of preferably from 1 to 50% by weight. The dry coating amount of each layer, which has been formed on the support, is preferably from 0.05 to 3.0 g/m², although different due to usage. The dry coating amount of the lower layer is preferably from 0.3 to 3.0 g/m². The total dry coating amount of the upper and lower layers is preferably from 0.5 to 3.0 g/m². The above total dry coating amount range of the upper and lower layers is preferred in view of layer properties and sensitivity.

The light sensitive layer coating solution is coated on a support according to a conventional method and dried to obtain a planographic printing plate material. As the coating methods, there are an air doctor coating method, a blade coating method, a wire bar coating method, a knife coating method, a dip coating method, a reverse roll coating method, a gravure coating method, a cast coating method, a curtain coating method, and an extrusion coating method. The drying temperature is preferably from 60 to 160° C., more preferably from 80 to 140° C., and still more from 90 to 120° C. An infrared radiation device can be used as a drying device to improve drying efficiency.

The planographic printing plate material obtained as above may be further subjected to aging treatment to stabilize the performance thereof. The aging treatment may be carried out in an aging device provided following a drying device or in an aging device provided separately. As disclosed in Japanese Patent O.P.I. Publication No. 2005-17599, the aging treatment may be used as a step in which OH groups on the layer surface are brought into contact with each other. In the aging treatment, a compound having a polar group represented by water permeates and diffuses from the layer surface to the inside of the layer whereby interaction in the layer is enhanced through water, cohesion is enhanced by heating, and performance of the layer is improved. Temperature at the aging treatment is preferably set so that a specific amount of a compound to diffuse is evaporated. Typical examples of the compound to diffuse and permeate include water, and a compound having a polar group such as a hydroxyl group, a carboxyl group, a ketone group, an aldehydes group or an ester group. The boiling point of these compounds is preferably not more than 200° C., more preferably not more than 150° C., and preferably not less than 50° C., more preferably not less than 70° C. The molecular weight is preferably not more than 150, and more preferably not more than 100.

### <Exposure and Development>>

The above-obtained planographic printing plate material is ordinarily imagewise exposed and developed to prepare a planographic printing plate for printing. A light source employed for imagewise exposure is preferably one having an emission wavelength in the wavelength regions of from near infrared to infrared, and more preferably a solid laser or a semiconductor laser. Imagewise exposure is carried out through an infrared laser (830 nm) based on digital converted data, employing a setter for CTP available on the market, followed by development, whereby a planographic printing plate with an image on the aluminum support used for printing is obtained.

An exposure device used in a plate making process in the invention is not specifically limited, as long as it is a laser method. Any of a method of laser scanning on an outer surface of a drum (an outer drum scanning method), a method of laser scanning on an inner surface of a drum (an inner drum scanning method), and a method of laser scanning on a plane (a flat head scanning method) can be used. The outer drum scanning method is preferably used which can easily provide multi-beams for improving productivity of low exposure intensity and long time exposure. An exposure device with a GLV modulation element employing the outer drum scanning method is especially preferred.

It is preferred that imagewise exposure is carried out employing an exposure device with a GLV modulation element whereby laser beams are multi-channeled, which improves productivity of planographic printing plates. The GLV modulation element is preferably one capable of dividing laser beams into not less than 200 channels, and more preferably one capable of dividing laser beams into not less than 500 channels. The laser beam spot diameter is preferably not more than 15 μm, and more preferably not more than 10 μm. The laser output power is preferably from 10 to 100 W, and more preferably from 20 to 80 W. The drum rotation number is preferably from 20 to 300 rpm, and more preferably from 30 to 200 rpm.

### (Developer)

A developer or developer replenisher applicable to the planographic printing plate material of the invention is one having a pH of from 9.0 to 14.0, and preferably from 12.0 to 13.5.

A developer including a developer replenisher (hereinafter also referred to as simply a developer) in the invention is a well known aqueous alkaline solution containing, as an alkali agent, sodium hydroxide, ammonium hydroxide, potassium hydroxide or lithium hydroxide. These alkali agents may be used singly or as an admixture of two or more kinds thereof. Other alkali agents include potassium silicate, sodium silicate, lithium silicate, ammonium silicate, potassium metasilicate, sodium metasilicate, lithium metasilicate, ammonium metasilicate, potassium phosphate, sodium phosphate, lithium phosphate, ammonium phosphate, potassium hydrogenphosphate, sodium hydrogenphosphate, lithium hydrogenphosphate, ammonium hydrogenphosphate, potassium carbonate, sodium carbonate, lithium carbonate, ammonium carbonate, potassium hydrogencarbonate, sodium hydrogencarbonate, lithium hydrogencarbonate, ammonium hydrogencarbonate, potassium borate, sodium borate, lithium borate and ammonium borate. Sodium hydroxide, ammonium hydroxide, potassium hydroxide or lithium hydroxide may be added to developer in order to adjust the pH of developer. An organic alkali agent such as monomethhylamine, dimethylamine, trimethylamine, monoethylamine, diethylamine, triethylamine, monoisobutylamine, diisobutylamine, triisobutylamine, n-butylamine, monoethanolamine, diethanolamine, triethanolamine, monoisopropanolamine, diisopropanolamine, ethyleneimine, ethylenediamine or pyridine can be used in combination.

Among these, potassium silicate or sodium silicate is preferred. The concentration of silicate in the developer is preferably from 2 to 4% by weight in terms of SiO₂ concentration. The ratio by mole (SiO₂/M) of SiO₂ to alkali metal M is preferably from 0.25 to 2.

The developer in the invention refers to a developer (so-called working developer) replenished with developer replenisher in order to maintain activity of the developer which lowers during development of light sensitive planographic printing plate material, as well as fresh developer used at the beginning of development.

The developer or developer replenisher in the invention can contain various surfactants or organic solvents as necessary, in order to accelerate development, disperse smuts occurring during development, or enhance ink receptivity at the image portions of printing plate.

The developer or developer replenisher may contain the following additives in order to increase development performance. Examples of the additives include a neutral salt such as sodium chloride, potassium chloride, potassium bromide, as disclosed in Japanese Patent O.P.I. Publication No. 58-75152, a complex such as [Co(NH₃)₆]Cl₃ as disclosed in Japanese Patent O.P.I. Publication No. 59-121336, an amphoteric polymer such as a copolymer of vinylbenzyl-trimethylammonium chloride and sodium acrylate as disclosed in Japanese Patent O.P.I. Publication No. 56-142258, the organic metal containing surfactant containing Si or Ti as disclosed in Japanese Patent O.P.I. Publication No. 59-75255, and the organic boron containing compound disclosed in Japanese Patent O.P.I. Publication No. 59-84241.

The developer or developer replenisher in the invention can further contain an antiseptic agent, a coloring agent, a viscosity increasing agent, an antifoaming agent, or a water softener.

The developer or developer replenisher is an aqueous concentrated solution with a low water content, which is diluted with water and used for development. The aqueous concentrated solution is advantageous in view of its transport. The degree of concentration of the concentrated solution is such that the components contained in the solution are not separated nor precipitated. The concentrated solution may contain a solubilizing agent. As the solubilizing agent is preferred so-called a hydrotrope such as toluene sulfonic acid, xylene sulfonic acid, or their alkali metal salt, which is disclosed in Japanese Patent O.P.I. Publication Nos. 6-32081.

### (Non-Silicate Developer)

Development of the planographic printing plate material of the invention can be also carried out employing a so-called “non-silicate developer” containing a non-reducing saccharide and a base but containing no alkali silicate. Development of the planographic printing plate material employing this developer provides a recording layer with good ink receptivity at the image portions without deteriorating the recording layer surface. Generally, development latitude of a planographic printing plate material is narrow, and the line width of line images of a developed planographic printing plate material is greatly changed due to pH of developer. Since the non-silicate developer contains a non-reducing saccharide with buffering property restraining a pH change, it is more advantageous than a developer containing a silicate. The non-silicate developer is also advantageous, since the non-reducing saccharide makes it difficult to contaminate an electrical conductivity sensor, a pH sensor, and the like controlling the activity of a developer, compared with a silicate. Further, the non-silicate developer greatly improves discrimination between the image and non-image portions.

The non-reducing saccharide is one having neither aldehyde group nor ketone group and exhibiting no reducing power. The saccharide is classified into trehalose type oligosaccharide, in which the reducing groups are bonded to each other; glycoside, in which a reducing group of a saccharide is bonded to a non-saccharide; and saccharide alcohol obtained by reducing a saccharide by hydrogenation. In the invention, any one of these saccharides is preferably used. In the invention, non-reducing saccharides disclosed in Japanese Patent O.P.I. Publication No. 8-305039 can be suitably used.

These no-reducing saccharides may be used singly or as an admixture of two or more kinds thereof. The no-reducing saccharide content of the non-silicate developer is preferably from 0.1 to 30% by weight, and more preferably from 1 to 20% by weight, in view of availability and easiness of concentration.

It is preferred that an automatic developing machine is used in order to prepare a planographic printing plate.

It is preferred that the automatic developing machine is equipped with a means for replenishing a developer replenisher in a necessary amount, a means for discharging any excessive developer and a means for automatically replenishing water in necessary amounts which is attached to the development section. It is preferred that the automatic developing machine comprises a means for detecting a transported planographic printing plate precursor, a means for calculating the area of the planographic printing plate precursor based on the detection, or a means for controlling the replenishing amount of a developer replenisher, the replenishing amount of water to be replenished, or the replenishing timing. It is also preferred that the automatic developing machine comprises a means for detecting a pH, temperature and/or electric conductivity of a developer, or a means for controlling the replenishing amount of the developer replenisher, the replenishing amount of water to be replenished or the replenishing timing, based on the detection.

The automatic developing machine used in the invention may be provided with a pre-processing section to allow the plate to be immersed in a pre-processing solution prior to development. The pre-processing section is provided preferably with a mechanism of spraying a pre-processing solution onto the plate surface, preferably with a mechanism of controlling the pre-processing solution at a temperature within the range of 25 to 55° C., and preferably with a mechanism of rubbing the plate surface with a roller-type brush. Common water and the like are employed as the pre-processing solution.

The planographic printing plate material exposed and developed with the developer is preferably subjected to post-processing. The post-processing comprises the step of processing the developed planographic printing plate material with a post-processing solution such as washing water, a rinsing solution containing a surfactant, a finisher or a protective gumming solution containing gum arabic or starch derivatives as a main component. The post-processing is carried out employing an appropriate combination of the post-processing solutions described above. For example, a method is preferred in which the developed planographic printing plate material is post-washed with washing water, and then processed with a rinsing solution containing a surfactant, or a developed planographic printing plate precursor is post-washed with washing water, and then processed with a finisher, since it reduces fatigue of the rinsing solution or the finisher.

It is preferred that a multi-step countercurrent processing is carried out employing a rinsing solution or a finisher. The post-processing is carried out employing an automatic developing machine having a development section and a post-processing section. In the post-processing step, the developed printing plate is sprayed with the post-processing solution from a spray nozzle or is immersed into the post-processing solution in a post-processing tank. A method is known in which supplies a small amount of water onto the developed printing plate precursor to wash the precursor, and reuses the water used for washing as dilution water for developer concentrate. In the automatic developing machine, a method is applied in which each processing solution is replenished with the respective processing replenisher according to the area of the printing plate precursor to have been processed or the operating time of the machine. A method (use-and-discard method) can be applied in which the developed printing plate material is processed with fresh processing solution and discarded. The thus obtained planographic printing plate is mounted on a printing press, and printing is carried out.

### (Burning Treatment)

The planographic printing plate obtained above is subjected to burning treatment in order to obtain a printing plate with high printing durability.

When the planographic printing plate is subjected to burning treatment, it is preferred that prior to the burning treatment, the printing plate is surface-processed with a cleaning solution disclosed in Japanese Patent Publication Nos. 61-2518 and 55-28062, and Japanese Patent O.P.I. Publication Nos. 62-31859 and 61-159655.

As the surface-processing method, there is a method coating the cleaning solution on the planographic printing plate, employing a sponge or absorbent cotton impregnated with the cleaning solution, a method immersing the planographic printing plate in the vessel charged with the cleaning solution or a method coating the cleaning solution on the planographic printing plate employing an automatic coater. It is preferred that the coated cleaning solution is squeegeed with for example, a squeegee roller to give uniform coating.

The coating amount of the cleaning solution is ordinarily from 0.03 to 0.8 g/m², in terms of dry coating amount. If necessary, a planographic printing plate coated with the cleaning solution is dried and heated to high temperature, employing a burning processor (for example, a burning processor BP-1300, available from Fuji Photo Film Co., Ltd.). The heating temperature is preferably from 180 to 300° C., and the heating period is preferably from 1 to 20 minutes, although they are different due to kinds of components forming an image.

A planographic printing plate subjected to burning treatment can be subjected to conventional processing such as water washing or gumming, if necessary, but when the cleaning solution containing a water-soluble polymer is used, desensitizing treatment such as gumming can be eliminated. The thus obtained planographic printing plate is mounted on a printing press, followed by printing, whereby many prints are obtained.

### (Packaging Material)

### [Interleaf]

An interleaf is preferably inserted between the two of the planographic printing plate materials of the invention, in order to prevent physical impact to the planographic printing plate material during storage or to minimize undesired impact during transportation. The interleaf is selected from many kinds thereof.

As an interleaf, one, which is manufactured employing inexpensive materials, is often used in order to reduce material cost. Examples thereof include a paper sheet comprised of 100% wood pulp, a paper sheet comprised of wood pulp and synthetic pulp, and a paper sheet in which a low or high density polyethylene film is provided on the paper sheet comprised of 100% wood pulp or the paper sheet comprised of wood pulp and synthetic pulp. A paper sheet, which does not employ synthetic pulp or polyethylene film can be manufactured at low cost, since the material cot is low.

A preferred interleaf is one having a basis weight of from 30 to 60 g/m², a smoothness of from 10 to 100 seconds, the smoothness measured according to a Bekk smoothness measuring method described in JIS 8119, a moisture content of from 4 to 8%, the moisture content measured according to a moisture content measuring method described in JIS 8127, and a density of from 0.7 to 0.9 g/cm³. An interleaf is preferably one in which a polymer film is not laminated on the surface facing the light sensitive layer, in order to absorb the residual solvents.

Printing is carried out employing a conventional printing press.

In recent years, printing ink containing no petroleum volatile organic compound (VOC) has been developed and used in view of environmental concern. The present invention provides excellent effects in employing such a printing ink. Examples of such a printing ink include soybean oil ink “Naturalith 100” produced by Dainippon Ink Kagaku Kogyo Co., Ltd., VOC zero ink “TK HIGH ECO NV” produced by Toyo Ink Manufacturing Co., Ltd., and process ink “Soycelvo” produced by Tokyo Ink Co., Ltd.

### EXAMPLES

The present invention will be explained in detail below employing examples, but is not limited thereto. In the examples, “parts” is “parts by weight”, unless otherwise specified.

The resin in the invention was prepared according to the following procedures.

### (Modified Novolak Resin N-1)

Dry N,N-dimethylacetoamide of 29.8 g and 5.0 g (0.035 mol) of 4-aminouracil were placed in a 50 ml reaction vessel equipped with a drying tube and a thermometer, and 7.8 g (0.035 mol) of isophorone diisocyanate were dropwise added in ten minutes thereto. Subsequently, 0.05 g of dibutyl tin dilaurate were added as a catalyst to the resulting solution, and then stirred for 5 days at 60° C. to obtain a solution containing a urethane intermediate with a free isocyanate group. Herein, reaction as shown in the following reaction formula (III) proceeds. The reaction process was confirmed according to a high speed liquid chromatography. After the unreacted isophorone diisocyanate peak was not observed, the resulting urethane intermediate solution was tightly sealed under nitrogen gas atmosphere and stored.

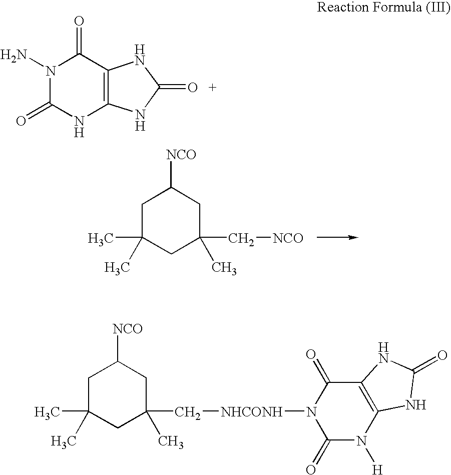

Subsequently, 72 g of dry N,N-dimethylacetoamide and 20.0 g of cresol novolak resin (m-cresol/p-cresol=6/4) with a molecular weight of 4,000 (hereinafter referred to as CNR) were placed in a 200 ml reaction vessel under a dry nitrogen gas atmosphere to obtain a novolak resin solution. The novolak resin solution was heated to 80° C. Then, 5.1 g of the urethane intermediate solution as obtained above and 0.05 g of dibutyl tin dilaurate as a catalyst were added thereto, and reacted at 80° C. until the residual free isocyanate group was not observed. The residual free isocyanate group was observed according to a back titration method, employing dimethylamine. After the free residual isocyanate group was not observed, the resulting reaction solution was cooled to room temperature, and added with 1 liter of deionized water while stirring to obtain precipitate. The resulting precipitate was filtered off, washed with water and dried at 40° C. under reduced pressure. Thus, 19.3 g of modified novolak resin N-1 (hereinafter also referred to simply as Resin N-1) was obtained, which had in the side chain a uric acid residue as shown in the following chemical structure (IV). The incorporation rate of the uric acid to the novolak resin 1 was 2.5 mol %.

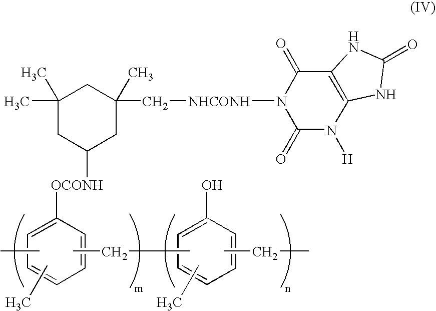

### (Modified Novolak Resin N-2)

Modified Novolak Resin N-2 (hereinafter also referred to simply as Resin N-2) was prepared in the same manner as in Resin N-2, except that 8-chlorotheophylline was used instead of uric acid

### (Modified Acryl Resin AR-1)

Acryloyl chloride of 19.00 g and 24.42 g of 4-hydroxybenzaldehyde were dissolved in a 100 g tetrahydrofuran while stirring. Subsequently, the resulting solution was dropwise added with 22.22 g of triethylamine in 30 minutes with stirring while cooling on a water bath and then reacted with stirring for 3 hours to obtain a reaction solution containing Compound (a) as shown below. The resulting reaction solution was added with 25.62 g of uric acid and 100 g of hot water, and then stirred at 60° C. for additional 3 hours. The resulting solution was poured into 1000 ml of water to obtain precipitate. The resulting precipitate was filtered off, washed with water and dried under reduced pressure. Thus, 57 g of Compound (b) (hereinafter also referred to as AHB) as shown below were obtained.

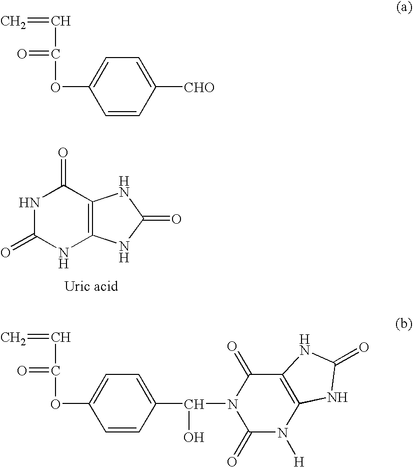

One hundred and thirty two parts by weight of N,N-dimethylacetoamide were placed in a flask equipped with a cooling tube, a nitrogen gas incorporating tube, a thermometer, a funnel and a thermometer, and heated to 80° C. with stirring while incorporating a nitrogen gas. A mixture of AHB, AN, and MAA (AHB: AN: MAA=30:30:40 by mol) of 40 parts by weight (in total), and 2.4 parts by weight of azobisisobutyronitrile were dissolved in 132 parts by weight of N,N-dimethylacetoamide to obtain a monomer solution. The resulting monomer solution was dropwise added in one hour while stirring to the N,N-dimethylacetoamide in the flask, and reacted with stirring at 80° C. for additional 3 hours. The resulting reaction solution was poured into water to obtain precipitate. The resulting precipitate was filtered off, and dried under reduced pressure. Thus, an acryl resin having in the side chain a uric acid residue was obtained.

### (Modified Acryl Resin AR-2)

Modified Acryl Resin AR-2 (hereinafter also referred to simply as Resin AR-2) was prepared in the same manner as in Resin AR-1, except that 8-chlorotheophylline was used instead of uric acid

### (Preparation of Aluminum Support)

A 0.24 mm thick aluminum plate (material 1050, refining H16) was immersed in an aqueous 5% by weight sodium hydroxide solution at 50° C. to give an aluminum dissolution amount of 2 g/m², washed with water, immersed in an aqueous 10% by weight nitric acid solution at 25° C. for 30 seconds to neutralize, and then washed with water.

Subsequently, the aluminum plate was subjected to electrolytic surface-roughening treatment in an electrolytic solution containing 10 g/liter of hydrochloric acid and 0.5 g/liter of aluminum at a current density of 60 A/dm² employing an alternating current with a sine waveform, in which the distance between the plate surface and the electrode was 10 mm. The electrolytic surface-roughening treatment was divided into 12 treatments, in which the quantity of electricity used in one treatment (at anodic time) was 80 C/dm², and the total quantity of electricity used (at anodic time) was 960 C/dm². Standby time of 1 second, during which no surface-roughening treatment was carried out, was provided after each of the separate electrolytic surface-roughening treatments.

Subsequently, the resulting aluminum plate was immersed in an aqueous 10% by weight phosphoric acid solution at 50° C. and etched to give an aluminum etching amount (including smut produced on the surface) of 1.2 g/m², and washed with water.

Subsequently, the aluminum plate was subjected to anodizing treatment in an aqueous 20% by weight sulfuric acid solution at a quantity of electricity of 250 C/dm² under a constant voltage of 20V, and washed with water. The aluminum plate surface was squeegeed to remove the residual water on the surface, and the plate was immersed in an aqueous 2% by weight sodium silicate No. 3 solution at 85° C. for 30 seconds, washed with water, then immersed in an aqueous 0.4% by weight polyvinyl phosphonic acid solution at 60° C. for 30 seconds, and washed with water. The aluminum plate surface being squeegeed, the aluminum plate was subjected to heating treatment at 130° C. for 50 seconds. Thus, an aluminum support was obtained.

The surface roughness Ra of the aluminum support was 0.55 μm, measured through SE 1700a (available from Kosaka Kenkyusho Co., Ltd.). The support surface being observed through an SEM by a factor of 100,000, the pore diameter of the anodization film was 40 nm. The polyvinyl phosphonic acid layer had a thickness of 0.01μ.

### (Preparation of Light Sensitive Planographic Printing Plate Material Sample Comprising a Single Light Sensitive Layer)

The following light sensitive layer coating solution was coated on the aluminum support obtained above, employing a three-roll coater, and dried at 120° C. for 1 minute to give a single light sensitive layer with a dry coating amount of 1.40 g/m². The resulting coating material was cut into a size of 600×400 mm, and 200 sheets thereof were stacked, an interleaf P inserted between the two nearest sheets, and was subjected to aging treatment for 24 hours at 50° C. and at absolute humidity of 0.037 kg/kg. Thus, planographic printing plate material samples 1 through 10 were prepared which contained the resin and acid decomposable compound as shown in Table 1.

### (Interleaf P)

A rosin sizing agent was added to the paper stock solution having a 4% concentration of bleached kraft pulp to have a rosin sizing agent content of 0.4%, and aluminum sulfate was added thereto to give a pH of 5. Thereafter, a reinforcing agent comprised mainly of starch was added to give a reinforcing agent content of 5.0% by weight. Interleaf P with a basis weight of 40 g/m² and a moisture content of 0.5% was prepared from the resulting solution.

(Light Sensitive Layer Coating Solution)

| | |
|---|---|
| Acryl resin 1 | 10 parts |
| Resin (as shown in Table 1) | amount as shown in Table 1 |
| Dye: Victoria Pure Blue | 3.0 parts |
| Acid decomposable compound | amount as shown in Table 1 |
| (as shown in Table 1) | |
| Acid generating agent BR22 | 5.0 parts |
| (Described previously) | |
| Infrared absorbing dye Dye 1 | 5.0 parts |
| Fluorine-containing surfactant | 0.8 parts |
| Megafac F178K (produced by Dainippon | |
| Ink & Chemicals Inc.) | |
| Solvent | amount giving |
| (Methyl ethyl ketone/1-methoxy- | 1000 parts in total |
| 2-propanol (1/2)) | |

### (Preparation of Light Sensitive Planographic Printing Plate Material Sample Comprising Two Light Sensitive Layers)

The following lower light sensitive layer coating solution was coated on the aluminum support obtained above, employing a three-roll coater, and dried at 120° C. for 1 minute to give a lower light sensitive layer with a dry coating amount of 0.85 g/m².

The following upper layer coating solution was coated on the resulting lower layer, employing a double-roll coater, and dried at 120° C. for 1.5 minutes to give an upper light sensitive layer with a dry coating amount of 0.25 g/m². The resulting coating material was cut into a size of 600×400 mm, and 200 sheets thereof were stacked, an interleaf P inserted between the two nearest sheets, and was subjected to aging treatment for 24 hours at 50° C. and at absolute humidity of 0.037 kg/kg.

Thus, planographic printing plate material samples 101 through 113 were prepared which contained the resin, acid decomposable compound, acid generating agent or fluoroalkyl group-containing acryl resin as shown in Tables 2 and 3.

(Lower Light Sensitive Layer Coating Solution)

| Resin for lower layer | amount as shown in Table 2 |
|---|---|
| (as shown in Table 2) | |
| Dye: Victoria Pure Blue | 3.0 parts |
| Acid decomposable compound | amount as shown in Table 2 |
| (as shown in Table 2) | |
| Acid generating agent | amount as shown in Table 2 |
| for lower layer (as shown in Table 2) | |
| Infrared absorbing dye Dye 1 | 5.0 parts |
| Fluorine-containing surfactant | 0.8 parts |
| Megafac F178K (produced by Dainippon Ink & Chemicals Inc.) | |
| Solvent | amount giving 1000 parts in total |
| (γ-Butyrolactone/methyl ethyl ketone/1-methoxy-2-propanol | |
| (1/2/1)) | |

(Upper Light Sensitive Layer Coating Solution)

| | |
|---|---|
| Resin for upper layer | amount as shown in Table 3 |
| (as shown in Table 3) | |
| Acryl resin 1 | 4.0 parts |
| Infrared absorbing dye Dye 1 | 1.5 parts |
| Fluorine-containing surfactant | 0.5 parts |
| Megafac F178K (produced by Dainippon Ink & Chemicals Inc.) | |
| Acid generating agent | amount as shown in Table 3 |
| for upper layer (as shown in Table 3) | |
| Fluoroalkyl group-containing | amount as shown in Table 3 |
| acryl resin (as shown in Table 3) | |
| Solvent | amount giving 1000 parts in total |
| (Methyl ethyl ketone/1-methoxy-2-propanol (1/2)) | |

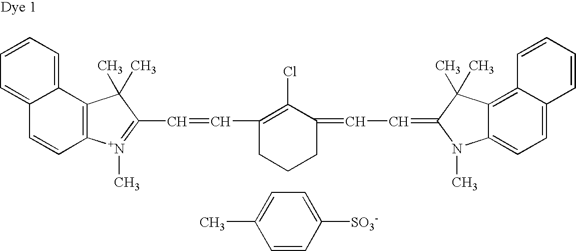

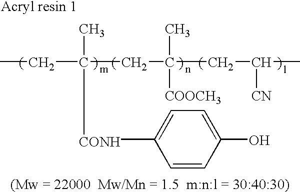

### (Exposure and Development)

Employing PTR-4300 (manufactured by Dainippon Screen Manufacturing Co., Ltd.), each of the resulting planographic printing plate material samples was imagewise exposed at a drum rotation number of 1000 rpm and at a resolution of 2400 dpi while the laser output power was changed from 30% to 100% to form a dot image with a screen line number of 175 lines. The exposed sample was developed with a developer PD1 (available from Kodak Polychrome Graphics Co., Ltd.) at 30° C. for 15 seconds, employing an automatic developing machine Raptor 85 Thermal (available from GLUNZ & JENSEN Co., Ltd.). Thus, a planographic printing plate sample was obtained.

### <Evaluation>

### (Sensitivity)

The printing plate material sample was exposed while varying laser light exposure energy, and developed in the same manner as above to obtain solid image portions and non-image portions. The optical density of the resulting non-image portions was measured through a densitometer D196 (produced by GRETAG Co., Ltd.). The exposure energy providing an optical density of the support (uncoated) surface optical density plus 0.01 was determined and defined as sensitivity.

### (Development Latitude)

Employing PTR-4300 (manufactured by Dainippon Screen Manufacturing Co., Ltd.), each of the resulting positive working planographic printing plate material samples was imagewise exposed at a drum rotation number of 1000 rpm and at a resolution of 2400 dpi while the laser output power was changed from 30% to 100% to form a dot image with a screen line number of 175 lines. Employing an automatic developing machine Raptor 85 Thermal (available from GLUNZ & JENSEN Co., Ltd.), the exposed sample was developed with a fatigue developer derived from a developer PD1 (available from Kodak Polychrome Graphics Co., Ltd.) having a pH at 30° C. of 12.95) at 30° C. for from 5 to 120 seconds (at an interval of 4 seconds). Herein, the fatigue developer was one obtained after the 10,000 sheets of an infrared positive working planographic printing plate material TP-W (available from Kodak Polychrome Co., Ltd.) were developed with the developer PD1 at 30° C. for 30 seconds.

The developed sample was observed through a magnifier at a magnification of 50, and the developing time range during which neither contamination at non-image portions nor layer thickness reduction was determined and defined as developing latitude.

### (Scratch Resistance)

The surface of the sample obtained above was scratched with a sapphire needle having a tip diameter of 0.1 mm through a scratch tester Heidon-18 produced by Heidon Co., Ltd., load, the weight changed from 1 to 40 g at an interval of 1 g, being applied to the sapphire needle. The scratched sample was developed with a developer prepared from TD-1 (available from Kodak Polychrome Co., Ltd.)/water (¼), and the scratched portions were observed. A minimum load (g) at which the layer was peeled from the support was observed. The more the minimum load is, the higher the scratch resistance.

The results are collectively shown in Tables 1 and 4.

As is apparent from Tables 1 and 4, inventive planographic printing plate material samples excel in sensitivity, developing latitude and scratch resistance, as compared with comparative planographic printing plate material samples.

TABLE 1

| | | Acid | | | | |
|---|---|---|---|---|---|---|
| | | decomposable | | | | |
| | Resin | compound | | Development | Scratch | |
| Sample | (Content | (Content by | Sensitivity | Latitude | Resistance | |
| No | by parts) | parts) | (mJ/cm²) | (seconds) | (g) | Remarks |
| 1 | CNR (80) | None | 260 | 5 | 1 | Comp. |
| 2 | CNR (80) | A4 (5) | 190 | 15 | 2 | Comp. |
| 3 | CNR/AR-2 | None | 160 | 30 | 3 | Inv. |
| | (50/30) | | | | | |
| 4 | CNR/AR-1 | None | 150 | 35 | 3 | Inv. |
| | (70/10) | | | | | |
| 5 | CNR/AR-1 | None | 125 | 60 | 4 | Inv. |
| | (20/60) | | | | | |
| 6 | N-1 (80) | None | 110 | 60 | 4 | Inv. |
| 7 | N-2 (80) | None | 150 | 35 | 3 | Inv. |
| 8 | N-1 (80) | A4 (5) | 100 | 75 | 4 | Inv. |
| 9 | CNR/N-1 | A4 (5) | 120 | 65 | 4 | Inv. |
| | (60/20) | | | | | |
| 10 | N-1/AR-1 | A4 (5) | 100 | 80 | 4 | Inv. |
| | (50/30) | | | | | |

Comp.: Comparative;
Inv.: Inventive

TABLE 2

| | Lower light sensitive layer | | | |
|---|---|---|---|---|
| | | Acid | Acid | |
| | | decomposable | generating | |
| | | compound | agent | |
| Sample | Resin | (Content by | (Content by | |
| No | (Content by parts) | parts) | parts) | Remarks |
| 101 | *ACR (80) | None | None | Comp. |
| 102 | ACR (80) | A4 (5) | BR22 (3) | Comp. |
| 103 | ACR (80) | None | None | Comp. |
| 104 | ACR (80) | None | **TAZ107 (3) | Comp. |
| 105 | ACR (80) | A4 (5) | None | Comp. |
| 106 | AR-2 (80) | A4 (5) | None | Inv. |
| 107 | ACR/AR-2 | A4 (5) | BR22 (3) | Inv. |
| | (60/20) | | | |
| 108 | ACR/AR-1 | A4 (5) | BR22 (3) | Inv. |
| | (60/20) | | | |
| 109 | ACR (80) | A4 (5) | BR22 (3) | Inv. |
| 110 | ACR (80) | A4 (5) | BR22 (3) | Inv. |
| 111 | ACR (80) | A4 (5) | BR22 (3) | Inv. |
| 112 | AR-1 (80) | A4 (5) | BR22 (3) | Inv. |
| 113 | AR-1 (80) | A4 (5) | TAZ107 (3) | Inv. |

Comp.: Comparative;
Inv.: Inventive
*ACR: Acryl resin 1
**TAZ107: Triazine type acid generating agent available from Midori Chemical Co., Ltd.)

TABLE 3

| | Upper light sensitive layer | | | |
|---|---|---|---|---|
| | | Acid | | |
| | | generating | Fluoroalkyl group- | |
| | Resin | agent | containing Acryl | |
| Sample | (Content by | (Content by | resin | Re- |
| No | parts) | parts) | (Content by parts) | marks |
| 101 | CNR (80) | None | None | Comp. |
| 102 | CNR (80) | None | None | Comp. |
| 103 | CNR (80) | *S1 (4) | None | Comp. |
| 104 | CNR (70) | S1 (4) | AP-1 (10) | Comp. |
| 105 | CNR (70) | S1 (4) | AP-1 (10) | Comp. |
| 106 | CNR (80) | None | None | Inv. |
| 107 | CNR (80) | None | None | Inv. |
| 108 | CNR (80) | None | None | Inv. |
| 109 | N-1 (80) | None | None | Inv. |
| 110 | N-1 (80) | S1 (4) | AP-1 (10) | Inv. |
| 111 | CNR/N-1 (60/20) | S1 (4) | AP-1 (10) | Inv. |
| 112 | N-1 (80) | S1 (4) | AP-1 (10) | Inv. |
| 113 | N-1 (80) | S1 (4) | AP-1 (10) | Inv. |

Comp.: Comparative; Inv.: Inventive
*S1: Compound having the following formula:

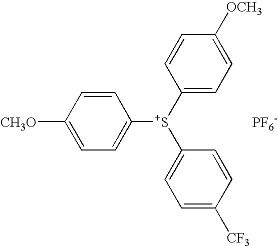

TABLE 4

| | | Development | Scratch | |
|---|---|---|---|---|
| Sample | Sensitivity | Latitude | Resistance | |
| No | (mJ/cm²) | (seconds) | (g) | Remarks |
| 101 | 160 | 20 | 1 | Comp. |
| 102 | 140 | 30 | 1 | Comp. |
| 103 | 155 | 20 | 1 | Comp. |
| 104 | 140 | 25 | 2 | Comp. |
| 105 | 150 | 25 | 2 | Comp. |
| 106 | 80 | 65 | 3 | Inv. |
| 107 | 100 | 45 | 3 | Inv. |
| 108 | 90 | 55 | 3 | Inv. |
| 109 | 90 | 70 | 3 | Inv. |
| 110 | 80 | 80 | 4 | Inv. |
| 111 | 100 | 60 | 3 | Inv. |
| 112 | 60 | 100 | 5 | Inv. |
| 113 | 60 | 90 | 5 | Inv. |

Comp.: Comparative;
Inv.: Inventive

What is claimed is:

1. A planographic printing plate material comprising a support and provided thereon, a light sensitive layer containing a resin comprising a residue of a bicyclic heterocyclic compound with a fused bicyclic ring, wherein the fused bicyclic ring contains two or more of —C(═O)— or two or more of —NH— in one ring thereof.

2. The planographic printing plate material of claim 1, wherein the fused bicyclic ring contains two or more of —C(═O)— and two or more of —NH— in one ring thereof.

3. The planographic printing plate material of claim 1, wherein the fused bicyclic ring includes a six-membered ring containing in the ring two or more of —C(═O)—.

4. The planographic printing plate material of claim 1, wherein the fused bicyclic ring includes a five-membered ring containing in the ring two or more of —NH—.

5. The planographic printing plate material of claim 1, wherein the bicyclic heterocyclic compound is theophylline or uric acid.

6. The planographic printing plate material of claim 1, wherein the fused bicyclic ring is capable of forming a hydrogen bond with two other fused bicyclic rings, simultaneously.

7. The planographic printing plate material of claim 1, wherein the resin is capable of forming a super molecule through hydrogen bonding.

8. The planographic printing plate material of claim 1, wherein the resin is one selected from a phenol resin, an acryl resin, and an acetal resin.

9. The planographic printing plate material of claim 1, wherein the resin is alkali soluble.

10. The planographic printing plate material of claim 1, wherein the light sensitive layer contains an acid decomposable compound represented by formula (ADC), 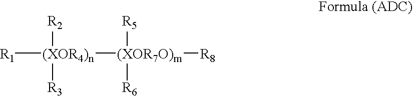
wherein n is an integer of 1 or more; m is an integer of 0 or more; X represents a carbon atom or a silicon atom; R₄ represents an ethyleneoxy group or a propyleneoxy group; R₂ and R₅ independently represent a hydrogen atom, an alkyl group or an aryl group; R₃ and R₆ independently represent an alkyl group or an aryl group, provided that R₂ and R₃ may combine with each other to form a ring or R₅ and R₆ may combine with each other to form a ring; R₇ represents an alkylene group; R₁ represents a hydrogen atom, an alkyl group, an aryl group, an alkoxy group, an aryloxy group or a halogen atom; and R₈ represents a hydrogen atom, —XR₂R₃R₁ or —XR₅R₆R₁.

11. The planographic printing plate material of claim 10, wherein the acid decomposable compound is an acetal.

12. The planographic printing plate material of claim 1, wherein the light sensitive layer is comprised of a lower light sensitive layer and an upper light sensitive layer provided on the lower light sensitive layer, and wherein at least one of the lower and upper light sensitive layers contains the resin.

13. The planographic printing plate material of claim 12, wherein the upper light sensitive layer contains an acryl resin having a fluoroalkyl group, and one of a compound represented by formula (APA) and a compound represented by formula (SAPA),
R¹—C(X)₂—(C═O)—R² Formula (APA)
wherein R¹ represents a hydrogen atom, a bromine atom, a chlorine atom, an alkyl group, an aryl group, an acyl group, an alkylsulfonyl group, an arylsulfonyl group, an iminosulfonyl group or a cyano group; R² represents a hydrogen atom or a monovalent organic substituent, provided that R¹ and R² may combine with each other to form a ring; and X represents a bromine atom or a chlorine atom, 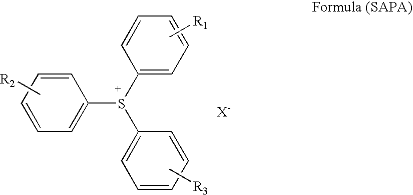
wherein R₁ through R₃ independently represent a hydrogen atom or a substituent, provided that R₁ through R₃ are not simultaneously hydrogens; and X⁻ represents an anion.

14. The planographic printing plate material of claim 12, wherein the lower light sensitive layer contains an acryl resin having a sulfonamide group or a hydroxylphenyl group.

15. The planographic printing plate material of claim 12, wherein the lower light sensitive layer contains a compound represented by formula (ADC) or a compound represented by formula (APA), 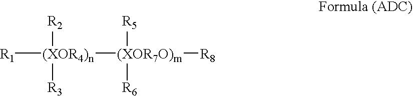
wherein n is an integer of 1 or more; m is an integer of 0 or more; X represents a carbon atom or a silicon atom; R₄ represents an ethyleneoxy group or a propyleneoxy group; R₂ and R₅ independently represent a hydrogen atom, an alkyl group or an aryl group; R₃ and R₆ independently represent an alkyl group or an aryl group, provided that R₂ and R₃ may combine with each other to form a ring or R₅ and R₆ may combine with each other to form a ring; R₇ represents an alkylene group; R₁ represents a hydrogen atom, an alkyl group, an aryl group, an alkoxy group, an aryloxy group or a halogen atom; and R₈ represents a hydrogen atom, —XR₂R₃R₁ or —XR₅R₆R₁,
R¹—C(X)₂—(C═O)—R² Formula (APA)
wherein R¹ represents a hydrogen atom, a bromine atom, a chlorine atom, an alkyl group, an aryl group, an acyl group, an alkylsulfonyl group, an arylsulfonyl group, an iminosulfonyl group or a cyano group; R² represents a hydrogen atom or a monovalent organic substituent, provided that R¹ and R² may combine with each other to form a ring; and X represents a bromine atom or a chlorine atom.

16. The planographic printing plate material of claim 1, which is positive working, wherein the light sensitive layer contains an infrared absorbing dye.
